(19) United States
(12) Patent Application Publication
(10) Pub. No.: US 2015/0255736 A1
(43) Pub. Date: Sep. 10, 2015

(54) COMPOUND AND ORGANIC LIGHT-EMITTING DEVICE INCLUDING THE SAME

(71) Applicant: Samsung Display Co., Ltd., Yongin-city (KR)

(72) Inventors: Young-Kook Kim, Yongin-city (KR); Soo-Yon Kim, Yongin-city (KR); Yoshi Naijotsu, Yongin-city (KR); Mi-Eun Jun, Yongin-city (KR); Hye-Jin Jung, Yongin-city (KR); Seok-Hwan Hwang, Yongin-city (KR)

(21) Appl. No.: 14/325,091

(22) Filed: Jul. 7, 2014

(30) Foreign Application Priority Data
Mar. 7, 2014 (KR) 10-2014-0027426

(51) Int. Cl. H01L 51/00; H01L 27/32; H01L 51/50

(52) U.S. Cl. CPC H01L 51/0094; H01L 51/006; H01L 51/0054; H01L 51/0058; H01L 51/0073; H01L 51/0074; H01L 51/5024; H01L 51/5092; H01L 51/5072; H01L 51/5056; H01L 27/3248

(57) ABSTRACT

An organic light-emitting device including a first electrode, a second electrode and an organic layer disposed between the first electrode and the second electrode is provided

### INCORPORATION BY REFERENCE TO ANY PRIORITY APPLICATIONS

Any and all priority claims identified in the Application Data Sheet, or any correction thereto, are hereby incorporated by reference under 37 CFR 1.57. For example, this application claims the benefit of Korean Patent Application No. 10-2014-0027426, filed on Mar. 7, 2014, in the Korean Intellectual Property Office, the disclosure of which is incorporated herein in its entirety by reference.

### BACKGROUND

1. Field

This disclosure relates to a compound and an organic light-emitting device including the same.

2. Description of the Related Technology

Organic light emitting devices are self-emission devices that have wide viewing angles, high contrast ratios, short response time, and excellent brightness, driving voltage, and response speed characteristics, and produce full-color images.

A typical organic light-emitting device has a structure including a substrate, and an anode, a hole transport layer, an emission layer, an electron transport layer, and a cathode which are sequentially stacked on the substrate. The hole transport layer, the emission layer, and the electron transport layer are organic thin films formed of organic compounds.

An organic light-emitting device operates by generating light.

When a voltage is applied between the anode and the cathode, holes injected from the anode pass the hole transport layer and migrate toward the emission layer, and electrons injected from the cathode pass the electron transport layer and migrate toward the emission layer. Carriers, such as holes and electrons, are recombined in the emission layer to produce excitons. These excitons change from an excited state to a ground state, thereby generating light.

A material that has excellent electric stability, high charge transport capability or luminescent capability, high glass transition temperature, and high crystallization prevention capability is desirable.

### SUMMARY

One or more embodiments include a compound that has excellent electric characteristics, a high charge transporting capability, a high light-emitting capability, a high glass transition temperature, and a crystallization-preventing capability, and is suitable for a full color, such as red, green, blue, or white, of fluorescent or phosphorescent devices, and an organic light-emitting device that has high efficiency, low voltage, high brightness, long lifespan due to the inclusion of the compound.

Additional aspects will be set forth in part in the description which follows and, in part, will be apparent from the description, or may be learned by practice of the presented embodiments.

According to an aspect, provided is a compound represented by Formula 1:

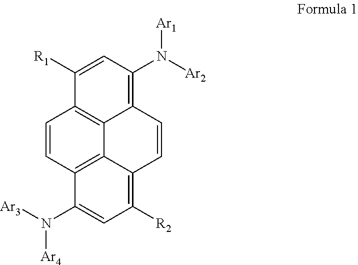

wherein in Formula 1,
Ar₁ to Ar₄ may be each independently a C₆ to C₆₀ substituted or unsubstituted aryl group, a C₁ to C₆₀ substituted or unsubstituted heteroaryl group, or a C₆ to C₆₀ substituted or unsubstituted condensed polycyclic group, and at least one of Ar₁ to Ar₄ is represented by Formula I-a:

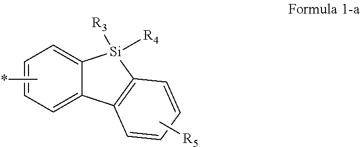

wherein in Formula 1 and 1-a, R₁ to R₅ may be each independently a hydrogen, a deuterium, a substituted or unsubstituted a C₁ to C₃₀ alkylsilyl group, a substituted or unsubstituted a C₆ to C₃₀ arylsilyl group, a substituted or unsubstituted a C₁ to C₃₀ alkyl group, a substituted or unsubstituted a C₆ to C₃₀ aryl group, a substituted or unsubstituted a C₁ to C₃₀ heteroaryl group, or a substituted or unsubstituted a C₆ to C₃₀ condensed polycyclic group, and *indicates an attachment point.

According to another aspect, provided is an organic light-emitting device including: a first electrode; a second electrode; and an organic layer disposed between the first electrode and the second electrode, wherein the organic layer includes the compound.

According to another aspect, provided is a flat panel display apparatus including the organic light-emitting device, wherein the first electrode of the organic light-emitting device is electrically connected to a source electrode or a drain electrode of a thin film transistor.

### BRIEF DESCRIPTION OF THE DRAWINGS

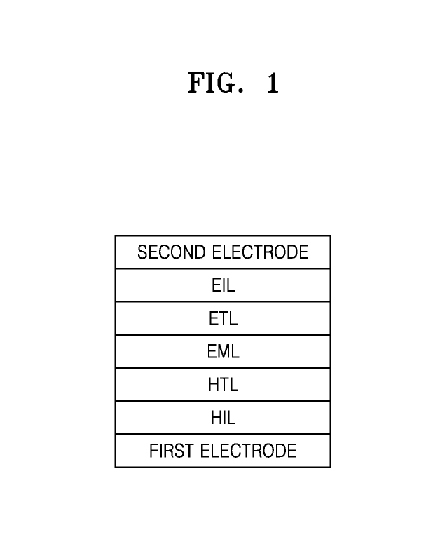

These and/or other aspects will become apparent and more readily appreciated from the following description of the embodiments, taken in conjunction with FIG. 1 which is a schematic view of an organic light-emitting device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

A compound according to an embodiment is represented by Formula 1:

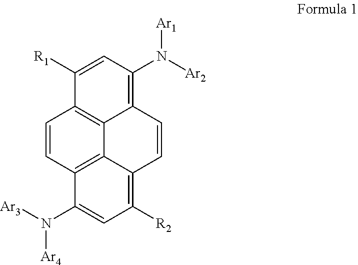

wherein in Formula 1,
Ar₁ to Ar₄ may be each independently a C₆ to C₆₀ substituted or unsubstituted aryl group, a C₁ to C₆₀ substituted or unsubstituted heteroaryl group, or a C₆ to C₆₀ substituted or unsubstituted condensed polycyclic group, and at least one or more of Ar₁ to Ar₄ may be represented by Formula I-a:

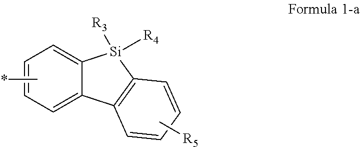

in Formulae 1 and 1-a, R₁ to R₅ may be each independently a hydrogen, a deuterium, a substituted or unsubstituted a C₁ to C₃₀ alkylsilyl group, a substituted or unsubstituted a C₆ to C₃₀ arylsilyl group, a substituted or unsubstituted a C₁ to C₃₀ alkyl group, a substituted or unsubstituted a C₆ to C₃₀ aryl group, a substituted or unsubstituted a C₁ to C₃₀ heteroaryl group, or a substituted or unsubstituted a C₆ to C₃₀ condensed polycyclic group, and * indicates an attachment point.

Formula 1a included in Formula 1 represents a condensed cyclic compound including a silicon atom, in which delocalization of electrons is increased by overlapping of σ orbital of the silicon atom and π orbital of a carbon atom, and when bound to a nitrogen atom of Formula 1, the structure of Formula 1a may contribute to delocalization of π electron of pyrene, which is the central structure of the molecule. Also, due to the σ-π overlapping through the silicon atom, the transition dipole moment of the molecule increases, thereby inducing an increase in absorption coefficient, and the increased absorption coefficient leads to improvement in luminescent efficiency of the molecule. Accordingly, the compound represented by Formula 1 may have higher luminescent efficiency than other known pyrene derivatives that do not include Formula 1a. Accordingly, when the compound of Formula 1 according to an embodiment is used as a dopant for an emission layer of an organic light-emitting device, high efficiency may be obtained.

Moreover, when the structure of Formula 2 is used as a host for an emission layer, much higher efficiency improvement effects may be obtained. An organic light-emitting device manufactured using the compound according to an embodiment may have high efficiency and long lifespan characteristics.

Substituents of Formula 1 will now be described in detail.

According to an embodiment, Ar₁ to Ar₄ may be each independently Formula 1-a, or any one of Formulae 2a to 2c:

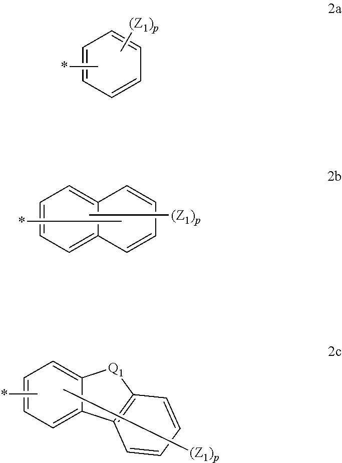

in Formulae 2a to 2c, Q₁ is —C(R₃₁)(R₃₂)—, —S—, or —O—; Z₁, R₃₁, and R₃₂ may be each independently a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, —SiR₄₁R₄₂R₄₃, a halogen group, a cyano group, a nitro group, a hydroxyl group, or a carboxyl group;
R₄₁, R₄₂, and R₄₃ may be each independently a substituted or unsubstituted C₁ to C₂₀ alkyl group, or a substituted or unsubstituted C₆ to C₂₀ aryl group;
p may be an integer of 1 to 7; and * indicates an attachment point.

According to another embodiment, R₁ to R₅ may be each independently a hydrogen, a deuterium, a methyl group, an isopropyl group, —SiR₄₁R₄₂R₄₃, or Formula 3a illustrated:

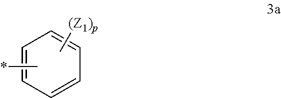

Z₁, R₄₁, R₄₂, and R₄₃ may be each independently a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ a condensed polycyclic group, a halogen group, a cyano group, a nitro group, a hydroxyl group, or a carboxyl group;
p may be an integer of 1 to 5; and * indicates an attachment point.

Hereinafter, substituents described with reference to the formulae will now be described in detail. In this regard, the numbers of carbons in substituents are presented only for illustrative purposes and do not limit the characteristics of the substituents. The substituents not defined herein are construed as the same meanings understood by one of ordinary skill in the art.

The term “C₁ to C₆₀ alkyl group” used herein may be a linear or branched alkyl group, and non-limiting examples thereof are a methyl group, an ethyl group, a propyl group, an isobutyl group, a sec-butyl group, a pentyl group, an iso-amyl group, a hexyl group, a heptyl group, an octyl group, a nonanyl group, and a dodecyl group. The C₃ to C₆₀ cycloalkyl group may be substituted or unsubstituted. In some embodiments, at least one hydrogen atom of the alkyl group may be substituted with a deuterium, a halogen atom, a hydroxyl group, a nitro group, a cyano group, an amino group, an amidino group, a hydrazine, a hydrazone, a carboxyl group or salt thereof, a sulfonic acid or salt thereof, a phosphoric acid or salt thereof, a C₁ to C₁₀ alkyl group, a C₁ to C₁₀ alkoxy group, a C₂ to C₁₀ alkenyl group, a C₂ to C₁₀ alkynyl group, a C₆ to C₁₆ aryl group, a C₄ to C₁₆ heteroaryl group, or an organosilyl group.

The term “C₂ to C₆₀ alkenyl group” used herein refers to an unsubstituted alkyl group having one or more carbon double bonds at a center or end thereof. Examples of the unsubstituted C₂-C₆₀ alkenyl group are an ethenyl group, a propenyl group, and a butenyl group. The C₂ to C₆₀ alkenyl group may be substituted or unsubstituted. In some embodiments, at least one hydrogen atom of the unsubstituted alkenyl group may be substituted with the same substituents as described in connection with the substituted alkyl group.

The term “C₂ to C₆₀ alkynyl group” used herein refers to an unsubstituted alkyl group having one or more carbon triple bonds at a center or end thereof. Examples thereof are acetylene, propylene, phenylacetylene, naphthylacetylene, isopropylacetylene, t-butylacetylene, and diphenylacetylene. The C₂ to C₆₀ alkynyl group may be substituted or unsubstituted. In some embodiments, at least one hydrogen atom of these alkynyl groups may be substituted with the same substituents as described in connection with the substituted alkyl group.

The term “C₃ to C₆₀ cycloalkyl group” used herein refers to a C₃ to C₆₀ cyclic hydrocarbon group. The C₃ to C₆₀ cycloalkyl group may be substituted or unsubstituted. In some embodiments, at least one hydrogen atom of the cycloalkyl group may be substituted with the same substituents as described in connection with the C₁ to C₆₀ alkyl group.

The term “C₁ to C₆₀ alkoxy group” used herein refers to a group having a structure of —OA wherein A is a C1 to C₆₀ alkyl group. The C₁ to C₆₀ alkoxy group may be substituted or unsubstituted. Non-limiting examples thereof are ethoxy, ethoxy, isopropyloxy, butoxy, and pentoxy. In some embodiments, at least one hydrogen atom of the unsubstituted alkoxy group may be substituted with the same substituents as described in connection with the alkyl group.

The term “C₆ to C₆₀ aryl group” or “C₆-C₆₀ arylene group” as used herein refers to a carbocyclic aromatic system having at least one aromatic ring, and when the number of rings is two or more, the rings may be fused to each other or may be linked to each other via, for example, a single bond. The C₆ to C₆₀ aryl group may be substituted or unsubstituted. In some embodiments, the aryl may be phenyl, naphthyl, or anthracenyl. In some embodiments, at least one hydrogen atom of the aryl group may be substituted with the same substituents described in connection with the C₁ to C₆₀ alkyl group.

Examples of a substituted or unsubstituted C₆ to C₆₀ aryl group are a phenyl group, a C₁ to C₁₀ alkylphenyl group (for example, an ethylphenyl group), a halophenyl group (for example, o-, m- and p-fluorophenyl groups, and a dichlorophenyl group), a cyanophenyl group, a dicyanophenyl group, a trifluoromethoxyphenyl group, a biphenyl group, a halobiphenyl group, a cyanobiphenyl group, a C₁ to C₁₀ alkylbiphenyl group, a C₁ to C₁₀ alkoxybiphenyl group, o-, m-, and p-tolyl groups, o-, m- and p-cumenyl groups, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, a fluoronaphthyl group), a C₁ to C₁₀ an alkylnaphthyl group (for example, a methylnaphthyl group), a C₁ to C₁₀ alkoxya naphthyl group (for example, a methoxynaphthyl group), a cyanonaphthyl group, an anthracenyl group, an azulenyl group, a heptalenyl group, an acenaphthylenyl group, a phenalenyl group, a fluorenyl group, an anthraquinolyl group, a methylanthryl group, a phenanthrile group, a triphenylene group, a pyrenyl group, a chrycenyl group, an ethyl-chrycenyl group, a pycenyl group, a perylenyl group, a chloropherylenyl group, a pentaphenyl group, a pentacenyl group, a tetraphenylenyl group, a hexaphenyl group, a hexacenyl group, a rubicenyl group, a coroneryl group, a trinaphthylenyl group, a heptaphenyl group, a heptacenyl group, a pyranthrenyl group, and an ovalenyl group.

The term “C₁-C₆₀ heteroaryl group” as used herein refers to an aromatic ring or ring system including at least one hetero atom selected from nitrogen (N), oxygen (O), phosphorous (P), and sulfur (S), and when the group has two or more rings, the rings may be fused to each other or may be linked to each other via, for example, a single bond. The C₁-C₆₀ heteroaryl group may be substituted or unsubstituted. Examples of the unsubstituted C₁-C₆₀ heteroaryl group are a pyrazolyl group, an imidazolyl group, a oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, and a dibenzothiophene group. Also, at least one hydrogen atom of the heteroaryl may be substituted with the same substituents described in connection with the C₁ to C₆₀ alkyl group.

The term “C₆ to C₆₀ aryloxy group” as used herein refers to a group represented by —OA₁, wherein A₁ is a C₆ to C₆₀ aryl group. The C₆ to C₆₀ aryloxy group may be substituted or unsubstituted. An example of the aryloxy group is a phenoxy group. In some embodiments, at least one hydrogen atom of the aryloxy group may be substituted with the same substituents described in connection with the C₁ to C₆₀ alkyl group.

The term “C₆ to C₆₀ arylthio group” as used herein refers to a group represented by —SA₁, wherein A₁ is a C₆ to C₆₀ aryl group. The C₆ to C₆₀ arylthio group may be substituted or unsubstituted. Examples of the arylthio group are a benzenethio group and a naphthylthio group. In some embodiments, at least one hydrogen atom of the arylthio group may be substituted with the same substituents described in connection with the C₁ to C₆₀ alkyl group.

The term “C₆ to C₆₀ condensed polycyclic group” as used herein refers to a substituent having two or more rings formed by fusing at least one aromatic ring and at least one non-aromatic ring or in which a unsaturated group is present in a ring but a fully conjugated system does not exist, and the condensed polycyclic group overall does not have a fully delocalized system of pi electrons including each atom of the ring system, which is in contrast to the aryl group or the heteroaryl group.

Non-limiting examples of compounds represented by Formula 1 are compounds illustrated below:

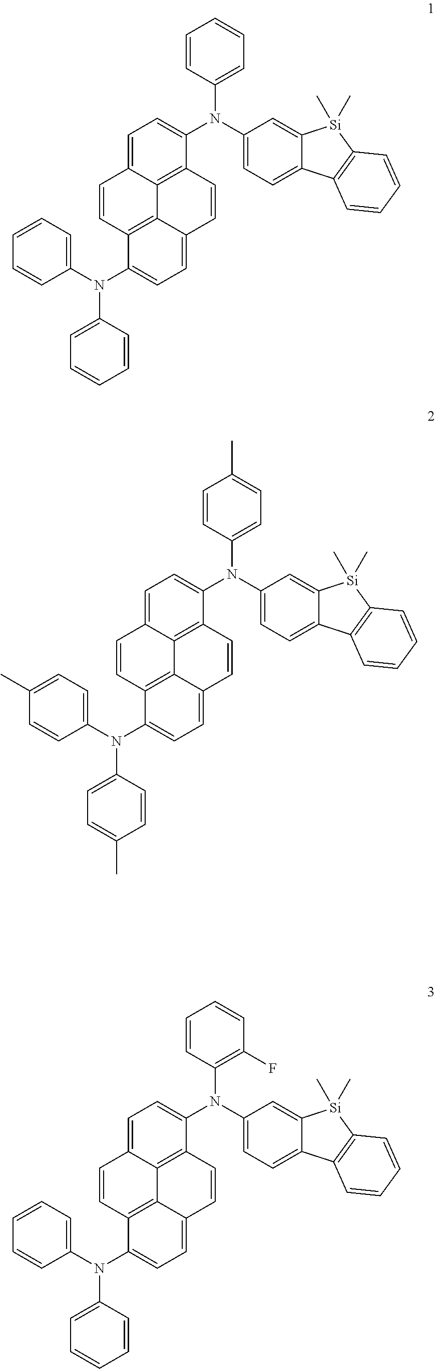 [SMILES: C[Si]1(C)c2ccccc2-c2ccc(N(c3ccccc3)c3ccc4ccc5c(N(c6ccccc6)c6ccccc6)ccc6ccc3c4c65)cc21 ; Cc1ccc(N(c2ccc(C)cc2)c2ccc3ccc4c(N(c5ccc(C)cc5)c5ccc6c(c5)[Si](C)(C)c5ccccc5-6)ccc5ccc2c3c54)cc1 ; C[Si]1(C)c2ccccc2-c2ccc(N(c3ccccc3F)c3ccc4ccc5c(N(c6ccccc6)c6ccccc6)ccc6ccc3c4c65)cc21]

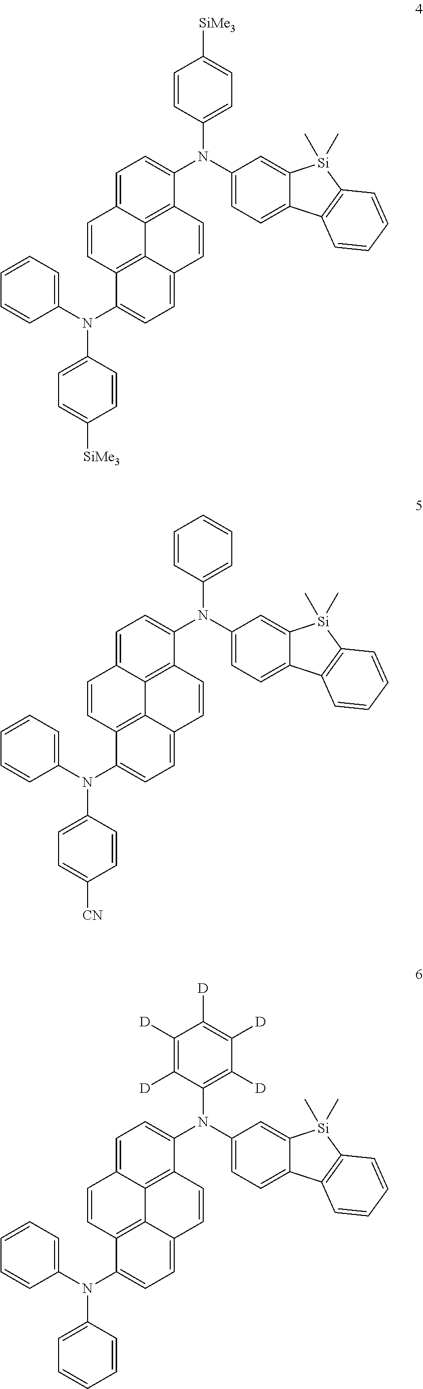 [SMILES: C[Si](C)(C)c1ccc(N(c2ccccc2)c2ccc3ccc4c(N(c5ccc([Si](C)(C)C)cc5)c5ccc6c(c5)[Si](C)(C)c5ccccc5-6)ccc5ccc2c3c54)cc1 ; C[Si]1(C)c2ccccc2-c2ccc(N(c3ccccc3)c3ccc4ccc5c(N(c6ccccc6)c6ccc(C#N)cc6)ccc6ccc3c4c65)cc21 ; [2H]c1c([2H])c([2H])c(N(c2ccc3c(c2)[Si](C)(C)c2ccccc2-3)c2ccc3ccc4c(N(c5ccccc5)c5ccccc5)ccc5ccc2c3c54)c([2H])c1[2H]]

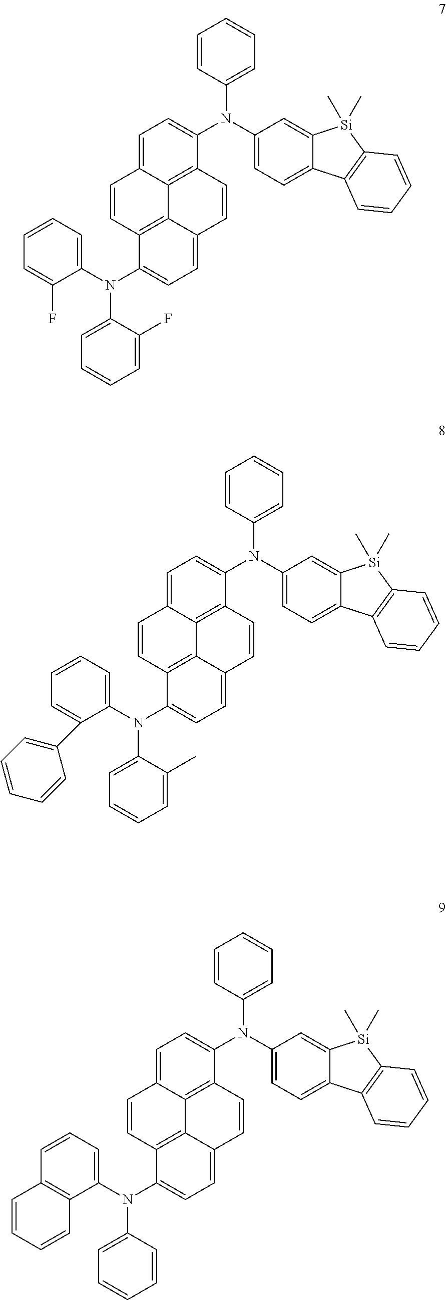 [SMILES: C[Si]1(C)c2ccccc2-c2ccc(N(c3ccccc3)c3ccc4ccc5c(N(c6ccccc6F)c6ccccc6F)ccc6ccc3c4c65)cc21 ; Cc1ccccc1N(c1ccccc1-c1ccccc1)c1ccc2ccc3c(N(c4ccccc4)c4ccc5c(c4)[Si](C)(C)c4ccccc4-5)ccc4ccc1c2c43 ; C[Si]1(C)c2ccccc2-c2ccc(N(c3ccccc3)c3ccc4ccc5c(N(c6ccccc6)c6cccc7ccccc67)ccc6ccc3c4c65)cc21]

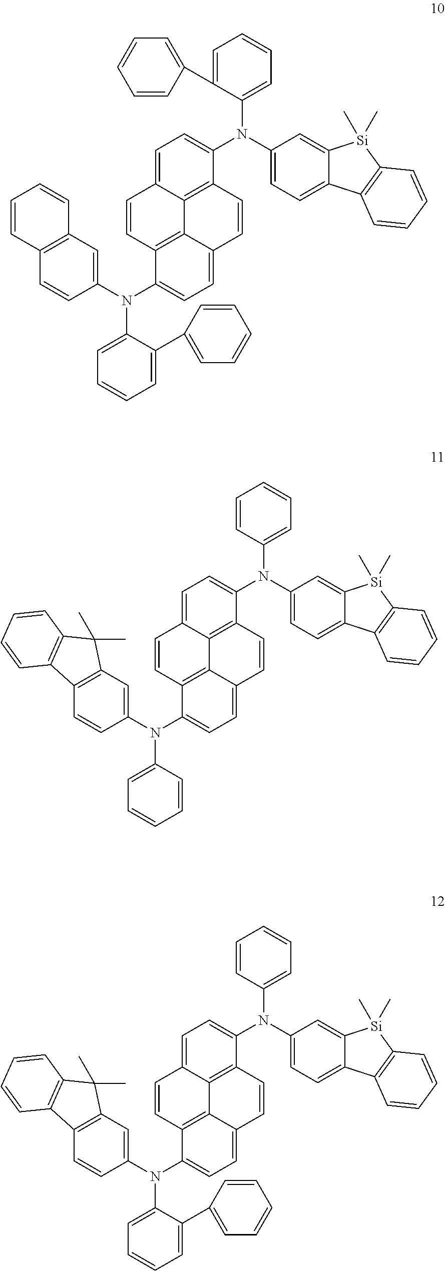 [SMILES: C[Si]1(C)c2ccccc2-c2ccc(N(c3ccccc3-c3ccccc3)c3ccc4ccc5c(N(c6ccc7ccccc7c6)c6ccccc6-c6ccccc6)ccc6ccc3c4c65)cc21 ; CC1(C)c2ccccc2-c2ccc(N(c3ccccc3)c3ccc4ccc5c(N(c6ccccc6)c6ccc7c(c6)[Si](C)(C)c6ccccc6-7)ccc6ccc3c4c65)cc21 ; CC1(C)c2ccccc2-c2ccc(N(c3ccccc3-c3ccccc3)c3ccc4ccc5c(N(c6ccccc6)c6ccc7c(c6)[Si](C)(C)c6ccccc6-7)ccc6ccc3c4c65)cc21]

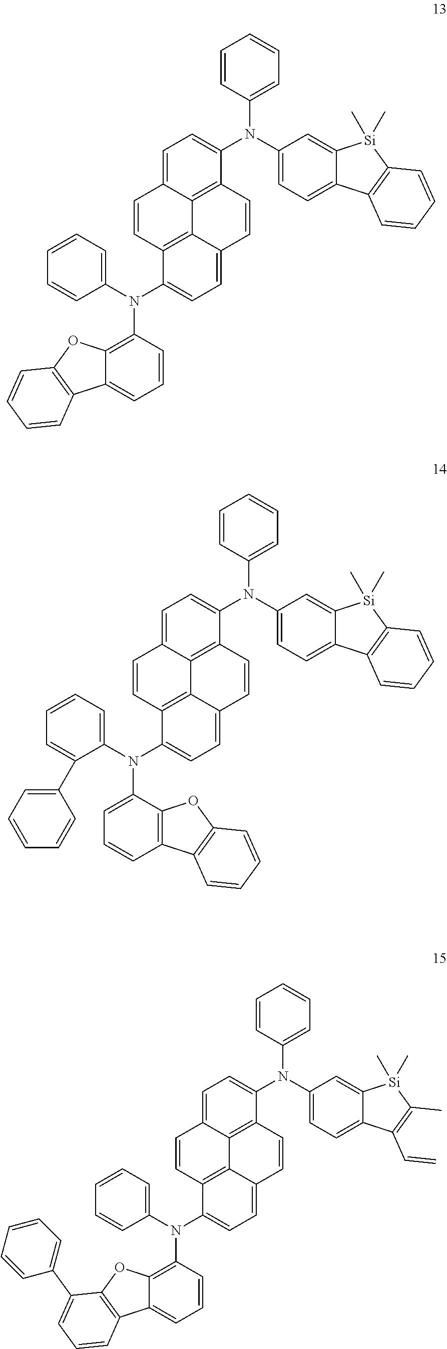 [SMILES: C[Si]1(C)c2ccccc2-c2ccc(N(c3ccccc3)c3ccc4ccc5c(N(c6ccccc6)c6cccc7c6oc6ccccc67)ccc6ccc3c4c65)cc21 ; C[Si]1(C)c2ccccc2-c2ccc(N(c3ccccc3)c3ccc4ccc5c(N(c6ccccc6-c6ccccc6)c6cccc7c6oc6ccccc67)ccc6ccc3c4c65)cc21 ; C=CC1=C(C)[Si](C)(C)c2cc(N(c3ccccc3)c3ccc4ccc5c(N(c6ccccc6)c6cccc7c6oc6c(-c8ccccc8)cccc67)ccc6ccc3c4c65)ccc21]

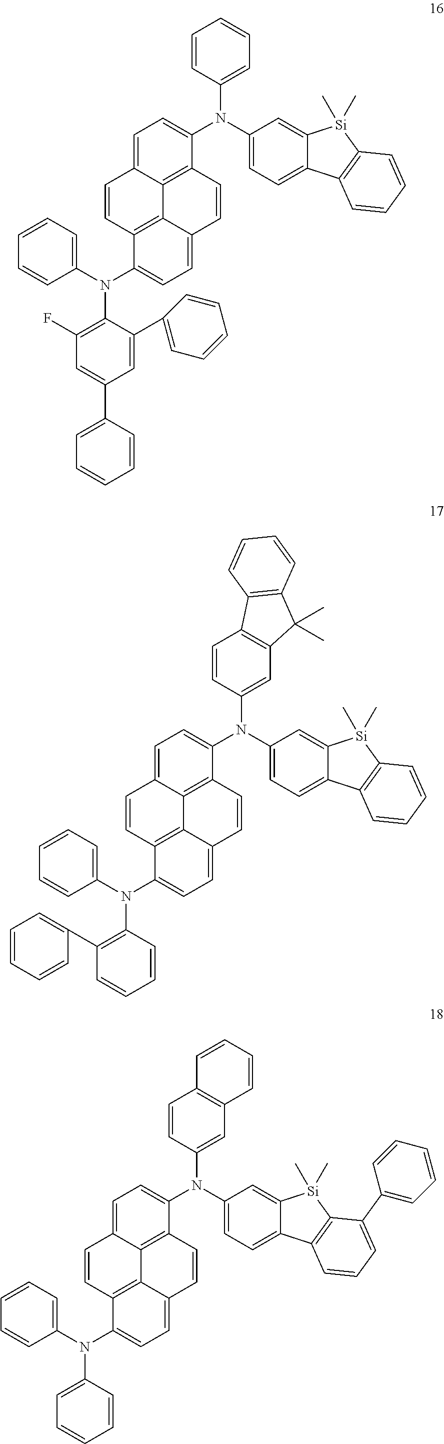 [SMILES: C[Si]1(C)c2ccccc2-c2ccc(N(c3ccccc3)c3ccc4ccc5c(N(c6ccccc6)c6c(F)cc(-c7ccccc7)cc6-c6ccccc6)ccc6ccc3c4c65)cc21 ; CC1(C)c2ccccc2-c2ccc(N(c3ccc4c(c3)[Si](C)(C)c3ccccc3-4)c3ccc4ccc5c(N(c6ccccc6)c6ccccc6-c6ccccc6)ccc6ccc3c4c65)cc21 ; C[Si]1(C)c2cc(N(c3ccc4ccccc4c3)c3ccc4ccc5c(N(c6ccccc6)c6ccccc6)ccc6ccc3c4c65)ccc2-c2cccc(-c3ccccc3)c21]

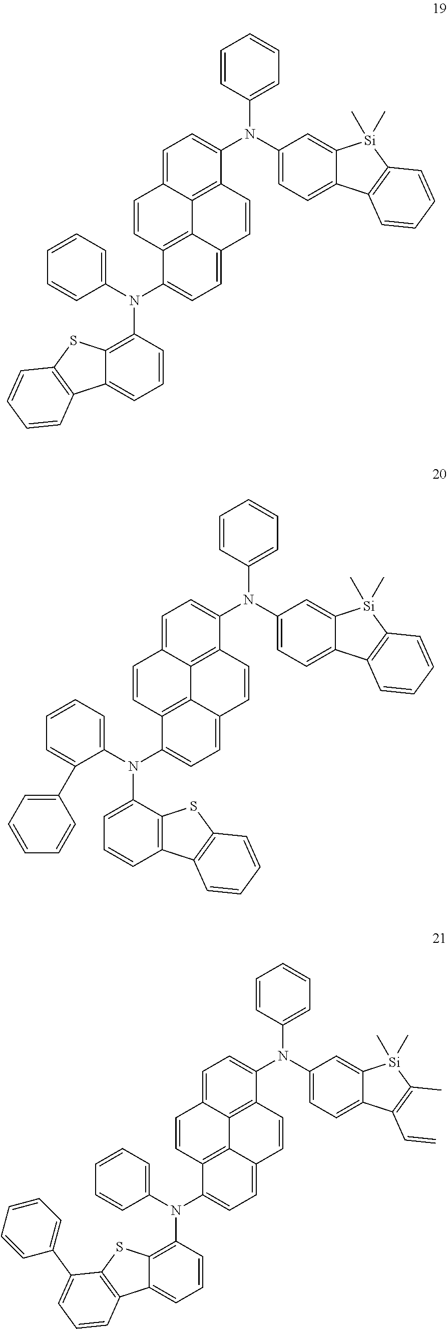 [SMILES: C[Si]1(C)c2ccccc2-c2ccc(N(c3ccccc3)c3ccc4ccc5c(N(c6ccccc6)c6cccc7c6sc6ccccc67)ccc6ccc3c4c65)cc21 ; C[Si]1(C)c2ccccc2-c2ccc(N(c3ccccc3)c3ccc4ccc5c(N(c6ccccc6-c6ccccc6)c6cccc7c6sc6ccccc67)ccc6ccc3c4c65)cc21 ; C=CC1=C(C)[Si](C)(C)c2cc(N(c3ccccc3)c3ccc4ccc5c(N(c6ccccc6)c6cccc7c6sc6c(-c8ccccc8)cccc67)ccc6ccc3c4c65)ccc21]

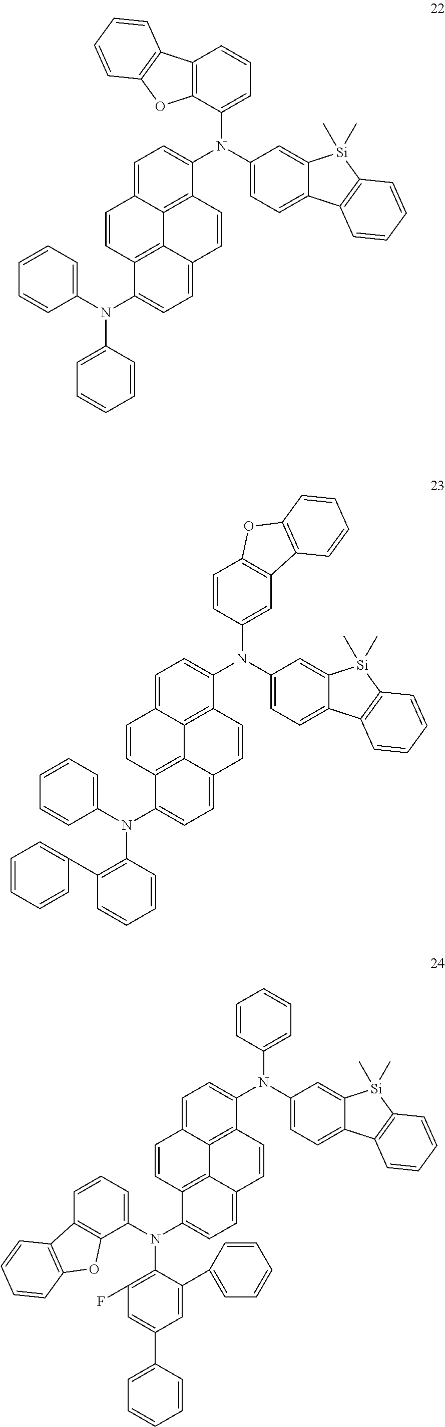 [SMILES: C[Si]1(C)c2ccccc2-c2ccc(N(c3ccc4ccc5c(N(c6ccccc6)c6ccccc6)ccc6ccc3c4c65)c3cccc4c3oc3ccccc34)cc21 ; C[Si]1(C)c2ccccc2-c2ccc(N(c3ccc4oc5ccccc5c4c3)c3ccc4ccc5c(N(c6ccccc6)c6ccccc6-c6ccccc6)ccc6ccc3c4c65)cc21 ; C[Si]1(C)c2ccccc2-c2ccc(N(c3ccccc3)c3ccc4ccc5c(N(c6c(F)cc(-c7ccccc7)cc6-c6ccccc6)c6cccc7c6oc6ccccc67)ccc6ccc3c4c65)cc21]

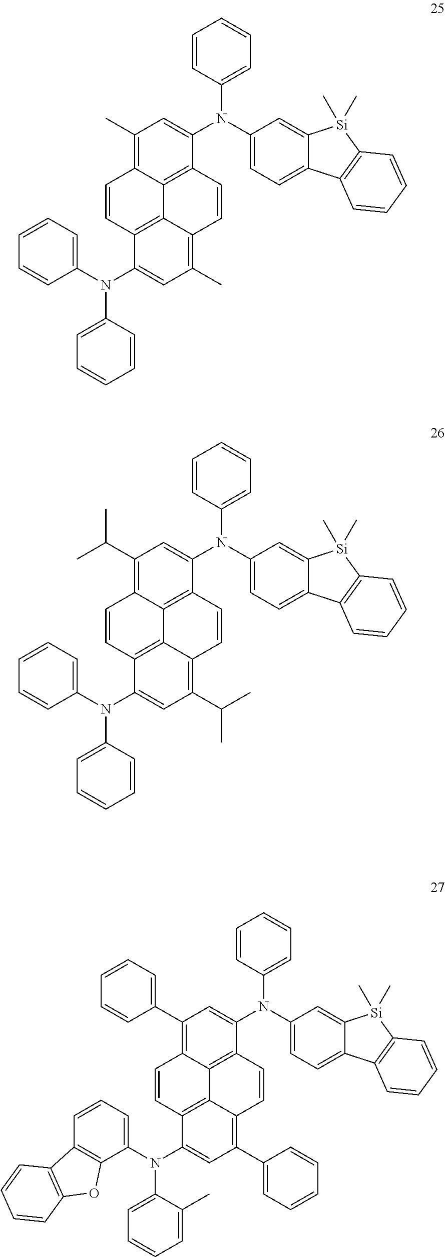 [SMILES: Cc1cc(N(c2ccccc2)c2ccccc2)c2ccc3c(C)cc(N(c4ccccc4)c4ccc5c(c4)[Si](C)(C)c4ccccc4-5)c4ccc1c2c34 ; CC(C)c1cc(N(c2ccccc2)c2ccccc2)c2ccc3c(C(C)C)cc(N(c4ccccc4)c4ccc5c(c4)[Si](C)(C)c4ccccc4-5)c4ccc1c2c34 ; Cc1ccccc1N(c1cc(-c2ccccc2)c2ccc3c(N(c4ccccc4)c4ccc5c(c4)[Si](C)(C)c4ccccc4-5)cc(-c4ccccc4)c4ccc1c2c43)c1cccc2c1oc1ccccc12]

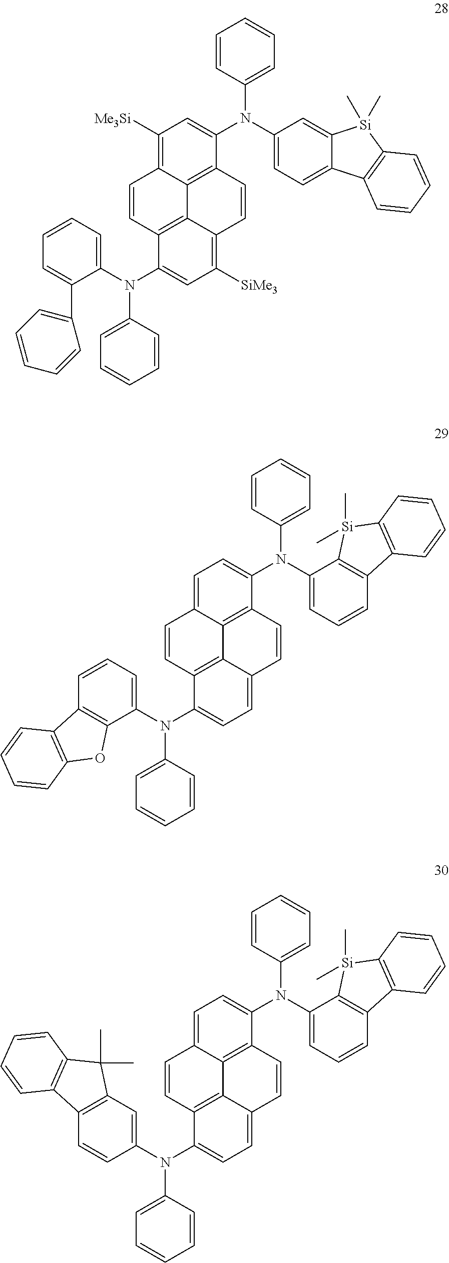 [SMILES: C[Si](C)(C)c1cc(N(c2ccccc2)c2ccc3c(c2)[Si](C)(C)c2ccccc2-3)c2ccc3c([Si](C)(C)C)cc(N(c4ccccc4)c4ccccc4-c4ccccc4)c4ccc1c2c43 ; C[Si]1(C)c2ccccc2-c2cccc(N(c3ccccc3)c3ccc4ccc5c(N(c6ccccc6)c6cccc7c6oc6ccccc67)ccc6ccc3c4c65)c21 ; CC1(C)c2ccccc2-c2ccc(N(c3ccccc3)c3ccc4ccc5c(N(c6ccccc6)c6cccc7c6[Si](C)(C)c6ccccc6-7)ccc6ccc3c4c65)cc21]

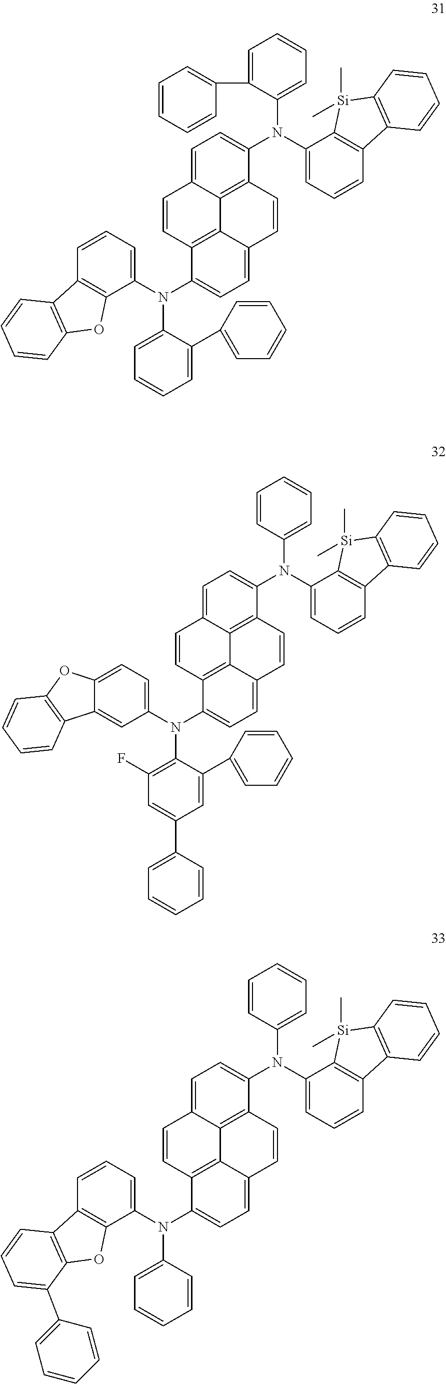 [SMILES: C[Si]1(C)c2ccccc2-c2cccc(N(c3ccccc3-c3ccccc3)c3ccc4ccc5c(N(c6ccccc6-c6ccccc6)c6cccc7c6oc6ccccc67)ccc6ccc3c4c65)c21 ; C[Si]1(C)c2ccccc2-c2cccc(N(c3ccccc3)c3ccc4ccc5c(N(c6ccc7oc8ccccc8c7c6)c6c(F)cc(-c7ccccc7)cc6-c6ccccc6)ccc6ccc3c4c65)c21 ; C[Si]1(C)c2ccccc2-c2cccc(N(c3ccccc3)c3ccc4ccc5c(N(c6ccccc6)c6cccc7c6oc6c(-c8ccccc8)cccc67)ccc6ccc3c4c65)c21]

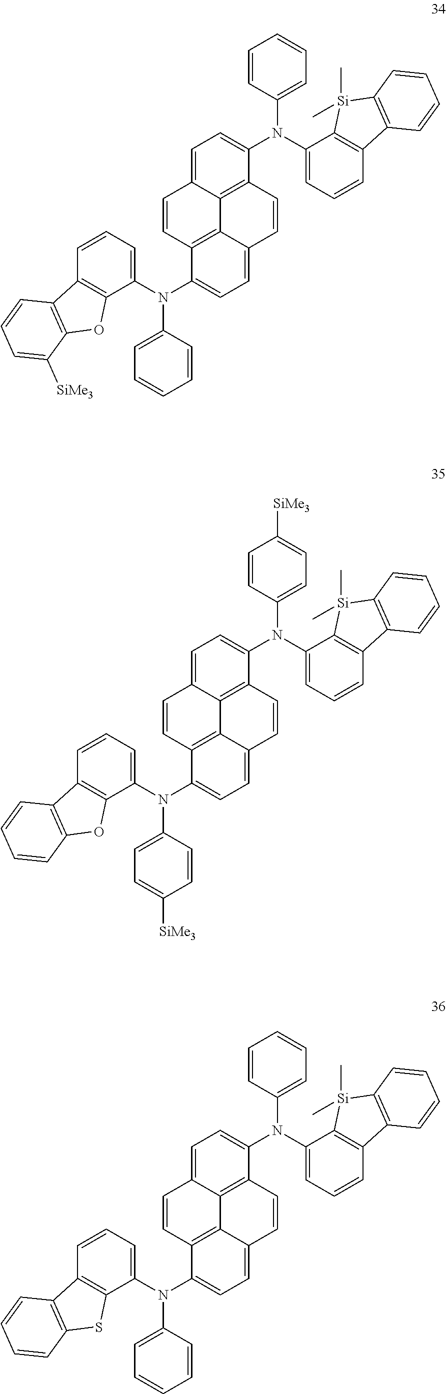 [SMILES: C[Si](C)(C)c1cccc2c1oc1c(N(c3ccccc3)c3ccc4ccc5c(N(c6ccccc6)c6cccc7c6[Si](C)(C)c6ccccc6-7)ccc6ccc3c4c65)cccc12 ; C[Si](C)(C)c1ccc(N(c2cccc3c2[Si](C)(C)c2ccccc2-3)c2ccc3ccc4c(N(c5ccc([Si](C)(C)C)cc5)c5cccc6c5oc5ccccc56)ccc5ccc2c3c54)cc1 ; C[Si]1(C)c2ccccc2-c2cccc(N(c3ccccc3)c3ccc4ccc5c(N(c6ccccc6)c6cccc7c6sc6ccccc67)ccc6ccc3c4c65)c21]

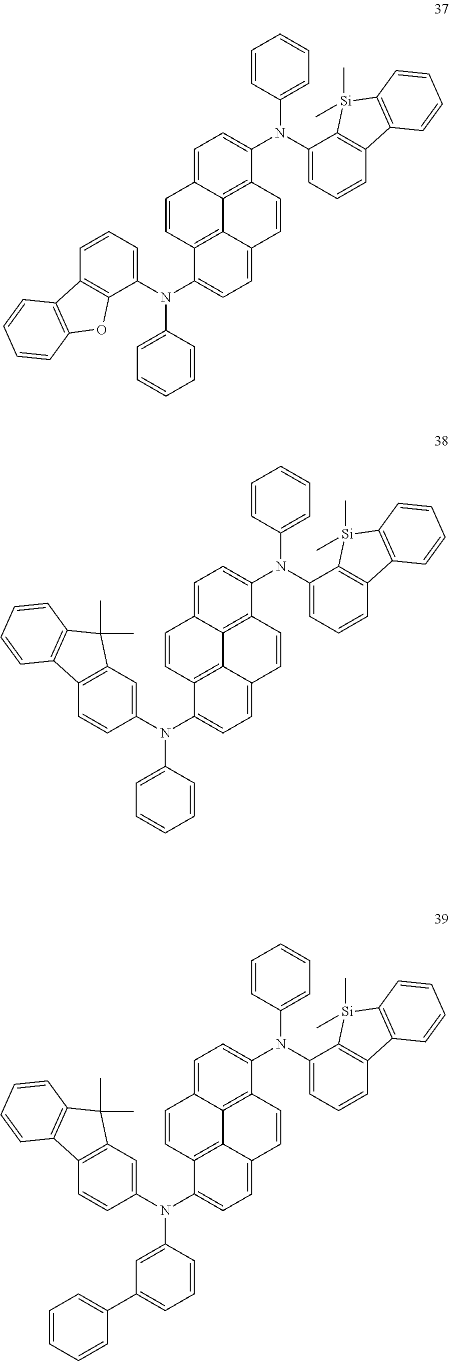 [SMILES: C[Si]1(C)c2ccccc2-c2cccc(N(c3ccccc3)c3ccc4ccc5c(N(c6ccccc6)c6cccc7c6oc6ccccc67)ccc6ccc3c4c65)c21 ; CC1(C)c2ccccc2-c2ccc(N(c3ccccc3)c3ccc4ccc5c(N(c6ccccc6)c6cccc7c6[Si](C)(C)c6ccccc6-7)ccc6ccc3c4c65)cc21 ; CC1(C)c2ccccc2-c2ccc(N(c3cccc(-c4ccccc4)c3)c3ccc4ccc5c(N(c6ccccc6)c6cccc7c6[Si](C)(C)c6ccccc6-7)ccc6ccc3c4c65)cc21]

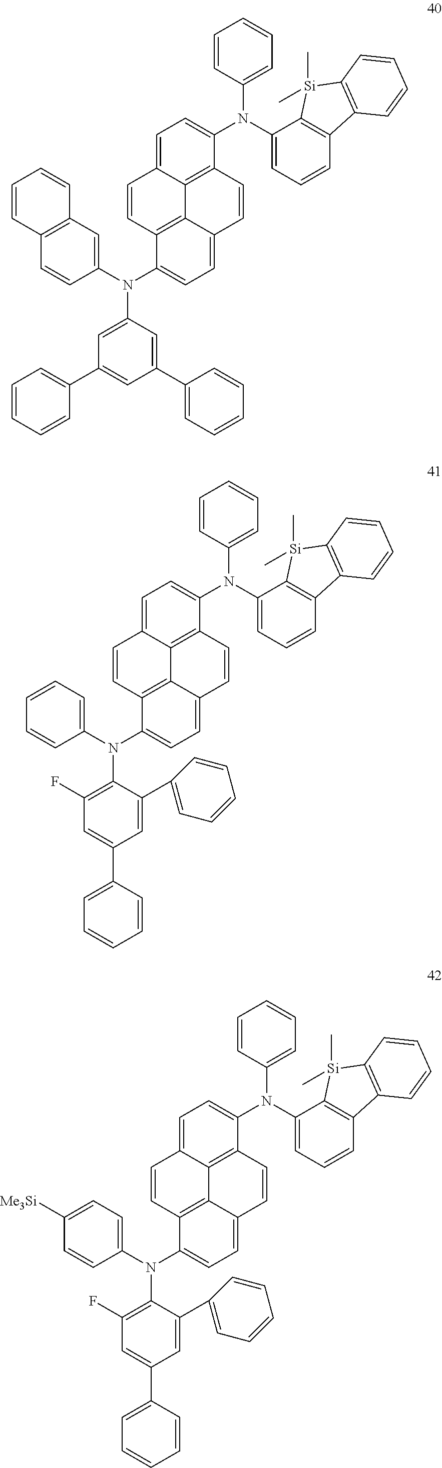 [SMILES: C[Si]1(C)c2ccccc2-c2cccc(N(c3ccccc3)c3ccc4ccc5c(N(c6cc(-c7ccccc7)cc(-c7ccccc7)c6)c6ccc7ccccc7c6)ccc6ccc3c4c65)c21 ; C[Si]1(C)c2ccccc2-c2cccc(N(c3ccccc3)c3ccc4ccc5c(N(c6ccccc6)c6c(F)cc(-c7ccccc7)cc6-c6ccccc6)ccc6ccc3c4c65)c21 ; C[Si](C)(C)c1ccc(N(c2c(F)cc(-c3ccccc3)cc2-c2ccccc2)c2ccc3ccc4c(N(c5ccccc5)c5cccc6c5[Si](C)(C)c5ccccc5-6)ccc5ccc2c3c54)cc1]

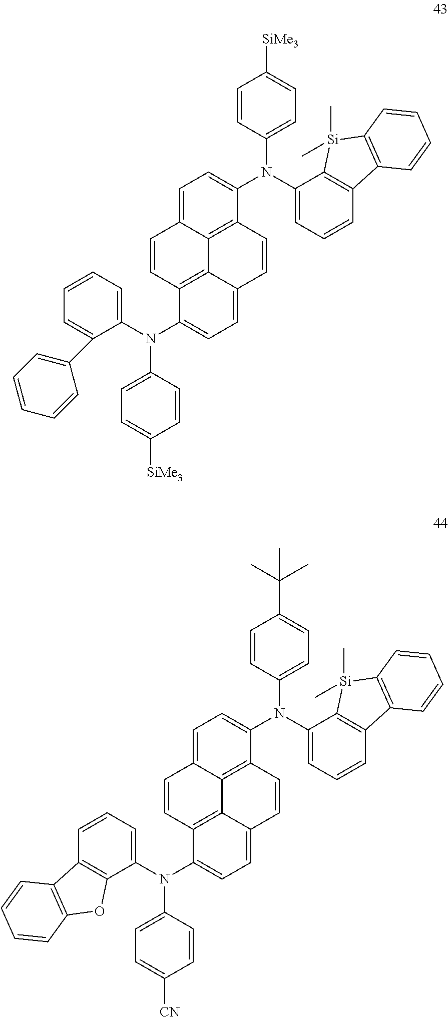 [SMILES: C[Si](C)(C)c1ccc(N(c2ccccc2-c2ccccc2)c2ccc3ccc4c(N(c5ccc([Si](C)(C)C)cc5)c5cccc6c5[Si](C)(C)c5ccccc5-6)ccc5ccc2c3c54)cc1 ; CC(C)(C)c1ccc(N(c2cccc3c2[Si](C)(C)c2ccccc2-3)c2ccc3ccc4c(N(c5ccc(C#N)cc5)c5cccc6c5oc5ccccc56)ccc5ccc2c3c54)cc1]

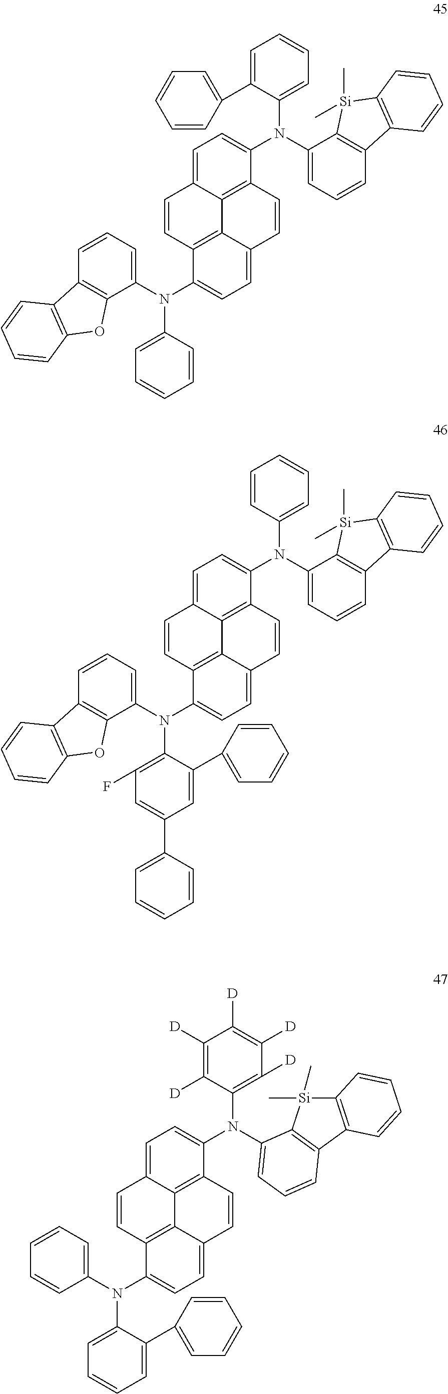 [SMILES: C[Si]1(C)c2ccccc2-c2cccc(N(c3ccccc3-c3ccccc3)c3ccc4ccc5c(N(c6ccccc6)c6cccc7c6oc6ccccc67)ccc6ccc3c4c65)c21 ; C[Si]1(C)c2ccccc2-c2cccc(N(c3ccccc3)c3ccc4ccc5c(N(c6c(F)cc(-c7ccccc7)cc6-c6ccccc6)c6cccc7c6oc6ccccc67)ccc6ccc3c4c65)c21 ; [2H]c1c([2H])c([2H])c(N(c2cccc3c2[Si](C)(C)c2ccccc2-3)c2ccc3ccc4c(N(c5ccccc5)c5ccccc5-c5ccccc5)ccc5ccc2c3c54)c([2H])c1[2H]]

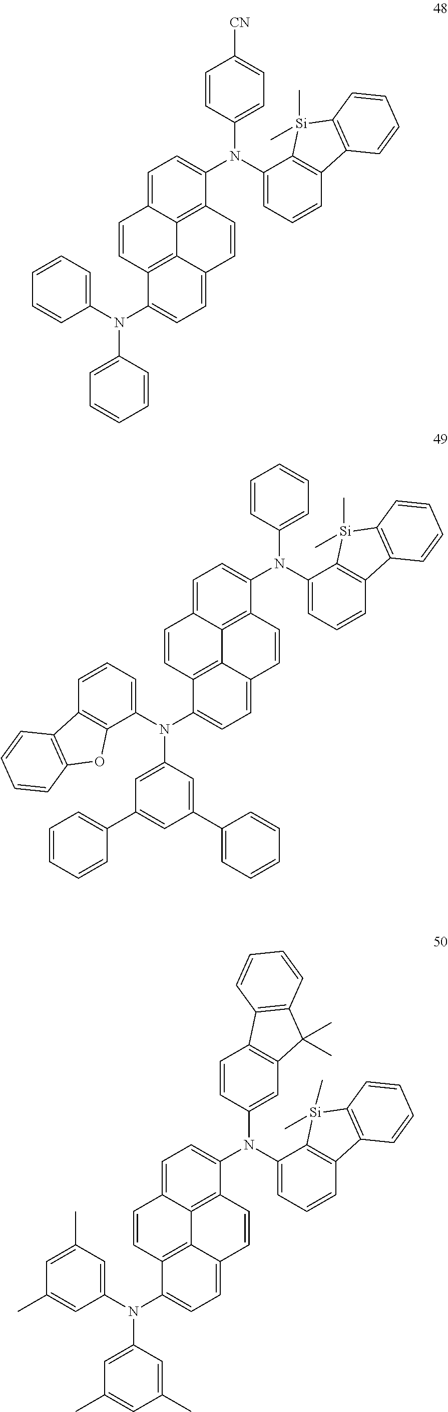 [SMILES: C[Si]1(C)c2ccccc2-c2cccc(N(c3ccc(C#N)cc3)c3ccc4ccc5c(N(c6ccccc6)c6ccccc6)ccc6ccc3c4c65)c21 ; C[Si]1(C)c2ccccc2-c2cccc(N(c3ccccc3)c3ccc4ccc5c(N(c6cc(-c7ccccc7)cc(-c7ccccc7)c6)c6cccc7c6oc6ccccc67)ccc6ccc3c4c65)c21 ; Cc1cc(C)cc(N(c2cc(C)cc(C)c2)c2ccc3ccc4c(N(c5ccc6c(c5)C(C)(C)c5ccccc5-6)c5cccc6c5[Si](C)(C)c5ccccc5-6)ccc5ccc2c3c54)c1]

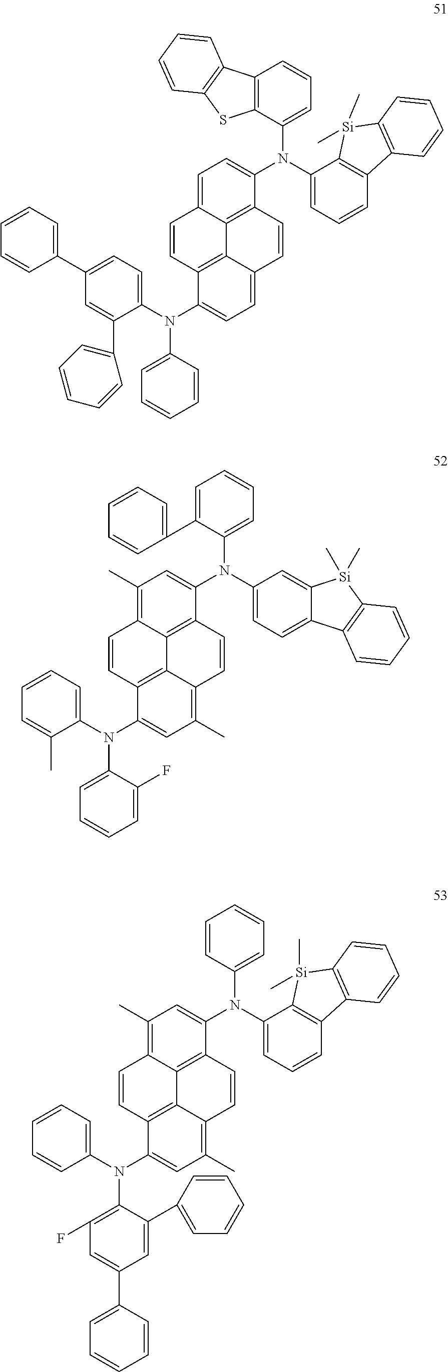 [SMILES: C[Si]1(C)c2ccccc2-c2cccc(N(c3ccc4ccc5c(N(c6ccccc6)c6ccc(-c7ccccc7)cc6-c6ccccc6)ccc6ccc3c4c65)c3cccc4c3sc3ccccc34)c21 ; Cc1ccccc1N(c1ccccc1F)c1cc(C)c2ccc3c(N(c4ccc5c(c4)[Si](C)(C)c4ccccc4-5)c4ccccc4-c4ccccc4)cc(C)c4ccc1c2c43 ; Cc1cc(N(c2ccccc2)c2cccc3c2[Si](C)(C)c2ccccc2-3)c2ccc3c(C)cc(N(c4ccccc4)c4c(F)cc(-c5ccccc5)cc4-c4ccccc4)c4ccc1c2c34]

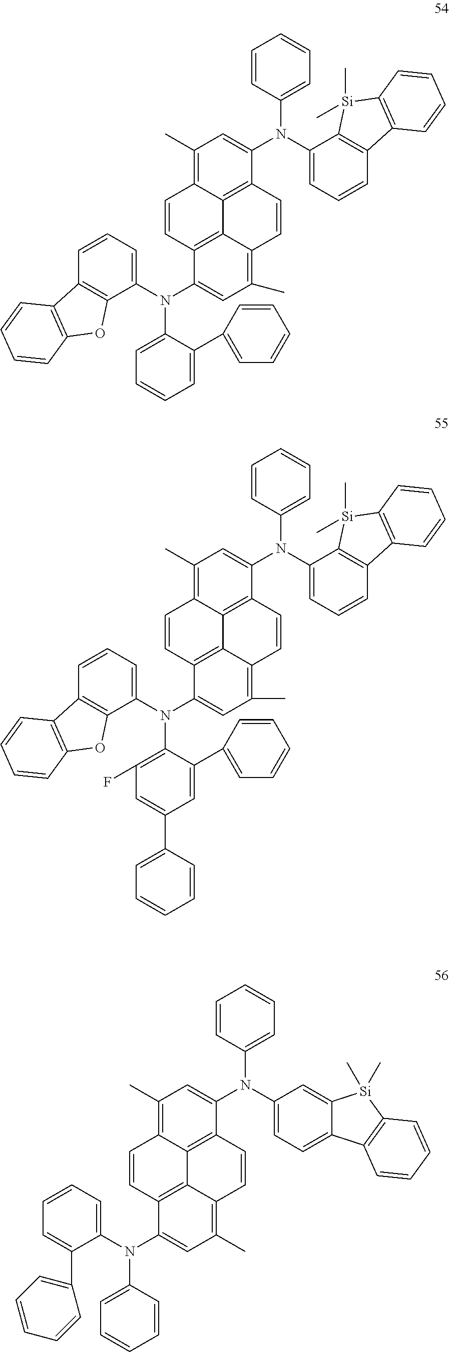 [SMILES: Cc1cc(N(c2ccccc2)c2cccc3c2[Si](C)(C)c2ccccc2-3)c2ccc3c(C)cc(N(c4ccccc4-c4ccccc4)c4cccc5c4oc4ccccc45)c4ccc1c2c34 ; Cc1cc(N(c2ccccc2)c2cccc3c2[Si](C)(C)c2ccccc2-3)c2ccc3c(C)cc(N(c4c(F)cc(-c5ccccc5)cc4-c4ccccc4)c4cccc5c4oc4ccccc45)c4ccc1c2c34 ; Cc1cc(N(c2ccccc2)c2ccc3c(c2)[Si](C)(C)c2ccccc2-3)c2ccc3c(C)cc(N(c4ccccc4)c4ccccc4-c4ccccc4)c4ccc1c2c34]

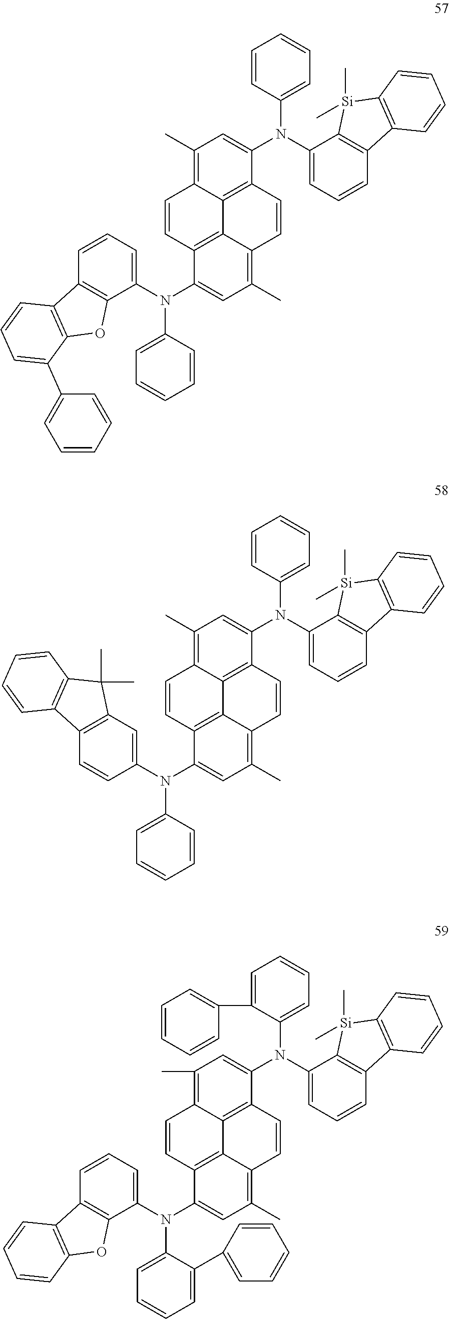 [SMILES: Cc1cc(N(c2ccccc2)c2cccc3c2[Si](C)(C)c2ccccc2-3)c2ccc3c(C)cc(N(c4ccccc4)c4cccc5c4oc4c(-c6ccccc6)cccc45)c4ccc1c2c34 ; Cc1cc(N(c2ccccc2)c2ccc3c(c2)C(C)(C)c2ccccc2-3)c2ccc3c(C)cc(N(c4ccccc4)c4cccc5c4[Si](C)(C)c4ccccc4-5)c4ccc1c2c34 ; Cc1cc(N(c2ccccc2-c2ccccc2)c2cccc3c2[Si](C)(C)c2ccccc2-3)c2ccc3c(C)cc(N(c4ccccc4-c4ccccc4)c4cccc5c4oc4ccccc45)c4ccc1c2c34]

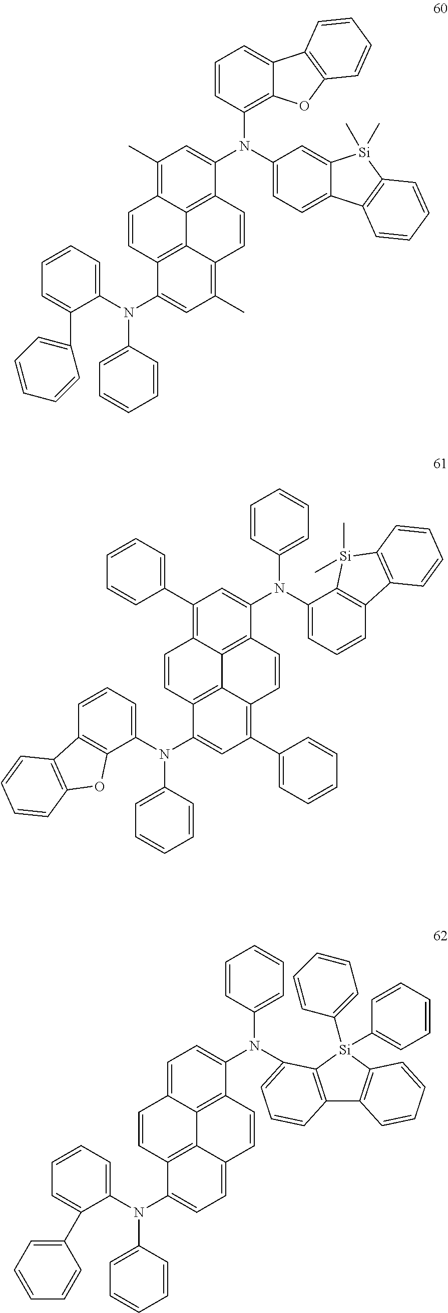 [SMILES: Cc1cc(N(c2ccccc2)c2ccccc2-c2ccccc2)c2ccc3c(C)cc(N(c4ccc5c(c4)[Si](C)(C)c4ccccc4-5)c4cccc5c4oc4ccccc45)c4ccc1c2c34 ; C[Si]1(C)c2ccccc2-c2cccc(N(c3ccccc3)c3cc(-c4ccccc4)c4ccc5c(N(c6ccccc6)c6cccc7c6oc6ccccc67)cc(-c6ccccc6)c6ccc3c4c65)c21 ; c1ccc(-c2ccccc2N(c2ccccc2)c2ccc3ccc4c(N(c5ccccc5)c5cccc6c5[Si](c5ccccc5)(c5ccccc5)c5ccccc5-6)ccc5ccc2c3c54)cc1]

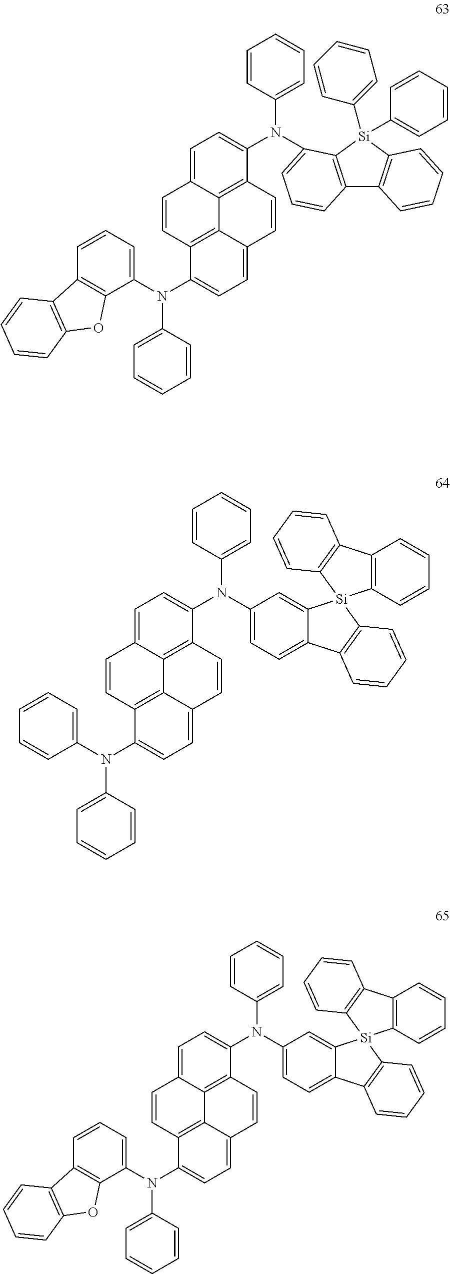 [SMILES: c1ccc(N(c2cccc3c2[Si](c2ccccc2)(c2ccccc2)c2ccccc2-3)c2ccc3ccc4c(N(c5ccccc5)c5cccc6c5oc5ccccc56)ccc5ccc2c3c54)cc1 ; c1ccc(N(c2ccccc2)c2ccc3ccc4c(N(c5ccccc5)c5ccc6c(c5)[Si]5(c7ccccc7-c7ccccc75)c5ccccc5-6)ccc5ccc2c3c54)cc1 ; c1ccc(N(c2ccc3c(c2)[Si]2(c4ccccc4-c4ccccc42)c2ccccc2-3)c2ccc3ccc4c(N(c5ccccc5)c5cccc6c5oc5ccccc56)ccc5ccc2c3c54)cc1]

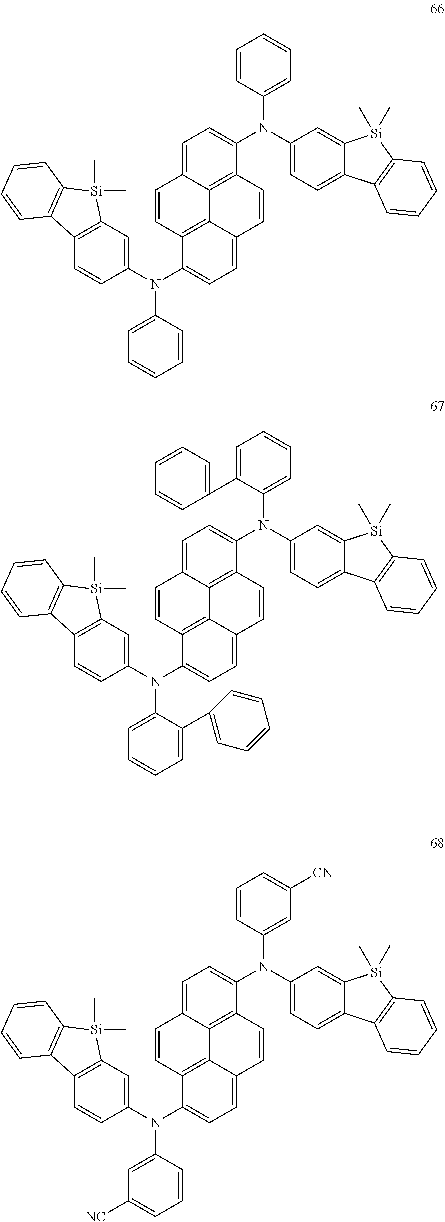 [SMILES: C[Si]1(C)c2ccccc2-c2ccc(N(c3ccccc3)c3ccc4ccc5c(N(c6ccccc6)c6ccc7c(c6)[Si](C)(C)c6ccccc6-7)ccc6ccc3c4c65)cc21 ; C[Si]1(C)c2ccccc2-c2ccc(N(c3ccccc3-c3ccccc3)c3ccc4ccc5c(N(c6ccc7c(c6)[Si](C)(C)c6ccccc6-7)c6ccccc6-c6ccccc6)ccc6ccc3c4c65)cc21 ; C[Si]1(C)c2ccccc2-c2ccc(N(c3cccc(C#N)c3)c3ccc4ccc5c(N(c6cccc(C#N)c6)c6ccc7c(c6)[Si](C)(C)c6ccccc6-7)ccc6ccc3c4c65)cc21]

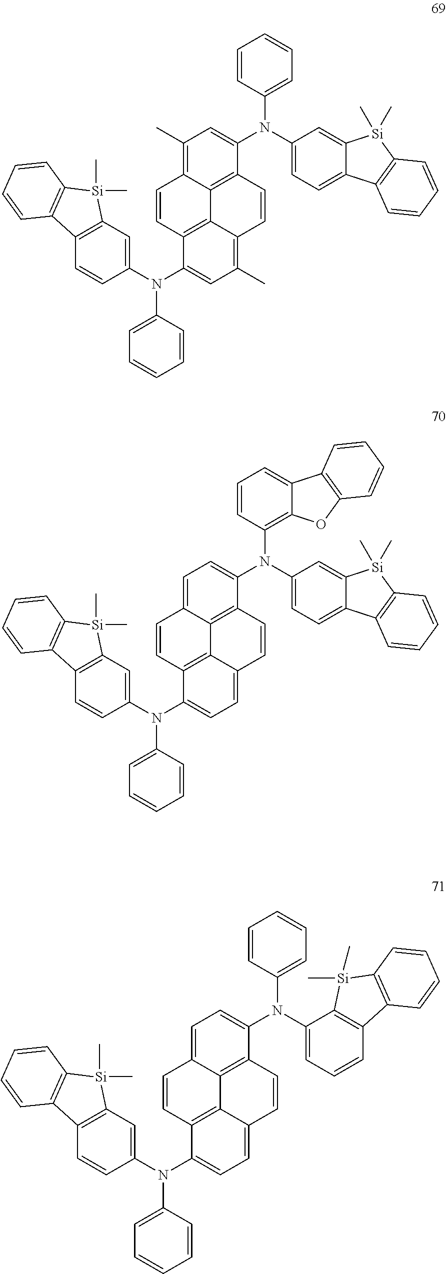 [SMILES: Cc1cc(N(c2ccccc2)c2ccc3c(c2)[Si](C)(C)c2ccccc2-3)c2ccc3c(C)cc(N(c4ccccc4)c4ccc5c(c4)[Si](C)(C)c4ccccc4-5)c4ccc1c2c34 ; C[Si]1(C)c2ccccc2-c2ccc(N(c3ccccc3)c3ccc4ccc5c(N(c6ccc7c(c6)[Si](C)(C)c6ccccc6-7)c6cccc7c6oc6ccccc67)ccc6ccc3c4c65)cc21 ; C[Si]1(C)c2ccccc2-c2ccc(N(c3ccccc3)c3ccc4ccc5c(N(c6ccccc6)c6cccc7c6[Si](C)(C)c6ccccc6-7)ccc6ccc3c4c65)cc21]

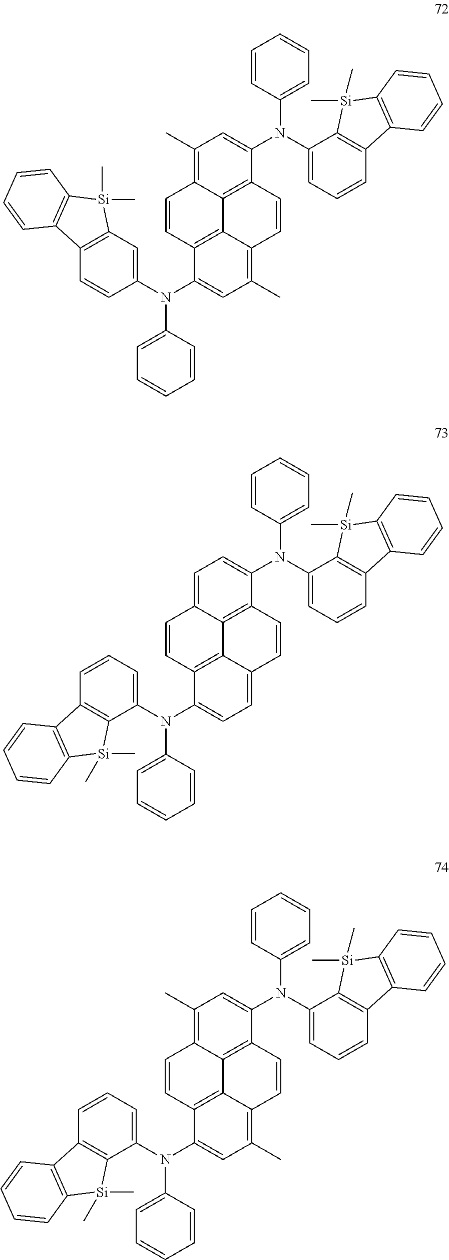 [SMILES: Cc1cc(N(c2ccccc2)c2ccc3c(c2)[Si](C)(C)c2ccccc2-3)c2ccc3c(C)cc(N(c4ccccc4)c4cccc5c4[Si](C)(C)c4ccccc4-5)c4ccc1c2c34 ; C[Si]1(C)c2ccccc2-c2cccc(N(c3ccccc3)c3ccc4ccc5c(N(c6ccccc6)c6cccc7c6[Si](C)(C)c6ccccc6-7)ccc6ccc3c4c65)c21 ; Cc1cc(N(c2ccccc2)c2cccc3c2[Si](C)(C)c2ccccc2-3)c2ccc3c(C)cc(N(c4ccccc4)c4cccc5c4[Si](C)(C)c4ccccc4-5)c4ccc1c2c34]

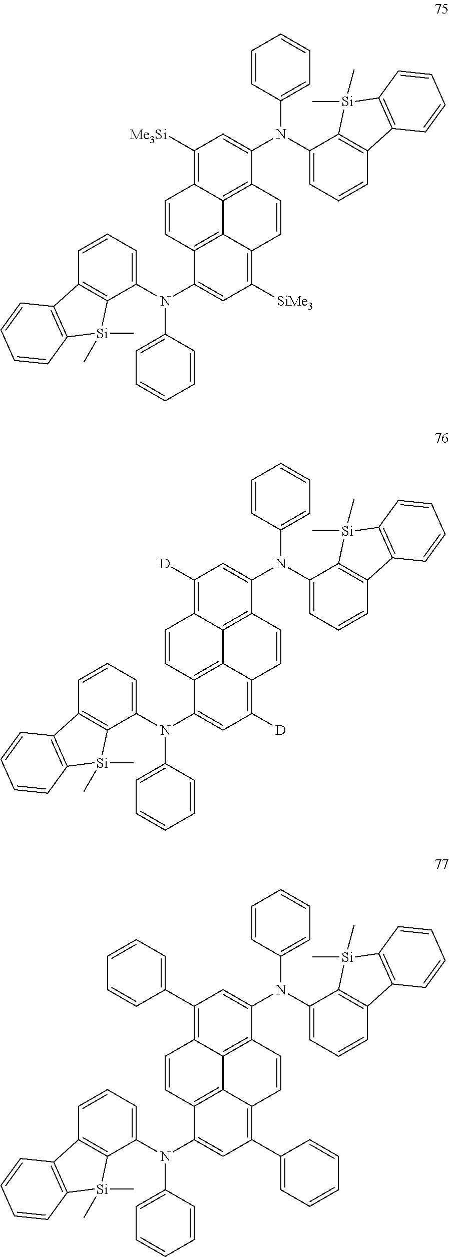 [SMILES: C[Si](C)(C)c1cc(N(c2ccccc2)c2cccc3c2[Si](C)(C)c2ccccc2-3)c2ccc3c([Si](C)(C)C)cc(N(c4ccccc4)c4cccc5c4[Si](C)(C)c4ccccc4-5)c4ccc1c2c43 ; [2H]c1cc(N(c2ccccc2)c2cccc3c2[Si](C)(C)c2ccccc2-3)c2ccc3c([2H])cc(N(c4ccccc4)c4cccc5c4[Si](C)(C)c4ccccc4-5)c4ccc1c2c34 ; C[Si]1(C)c2ccccc2-c2cccc(N(c3ccccc3)c3cc(-c4ccccc4)c4ccc5c(N(c6ccccc6)c6cccc7c6[Si](C)(C)c6ccccc6-7)cc(-c6ccccc6)c6ccc3c4c65)c21]

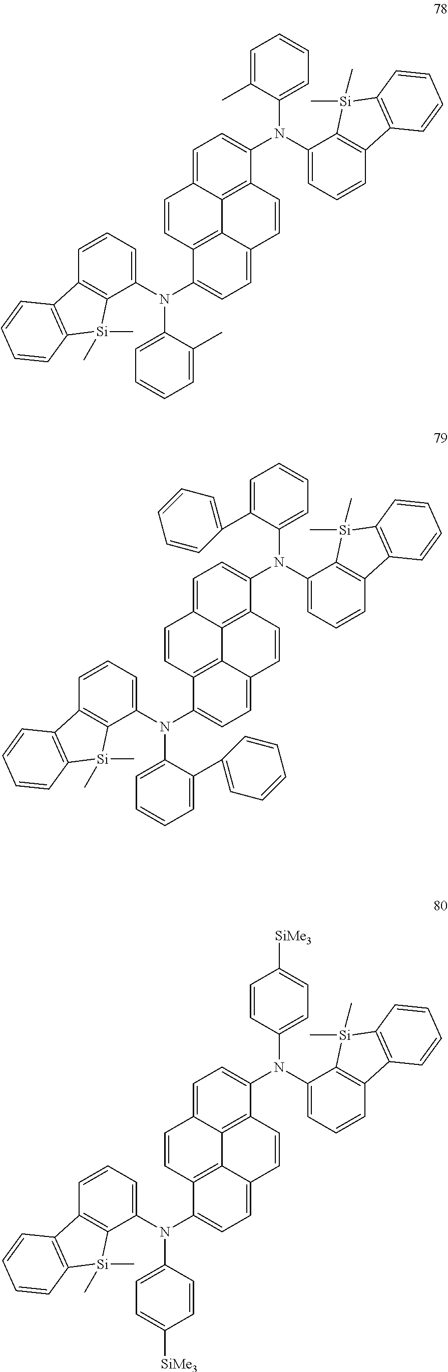 [SMILES: Cc1ccccc1N(c1cccc2c1[Si](C)(C)c1ccccc1-2)c1ccc2ccc3c(N(c4ccccc4C)c4cccc5c4[Si](C)(C)c4ccccc4-5)ccc4ccc1c2c43 ; C[Si]1(C)c2ccccc2-c2cccc(N(c3ccccc3-c3ccccc3)c3ccc4ccc5c(N(c6ccccc6-c6ccccc6)c6cccc7c6[Si](C)(C)c6ccccc6-7)ccc6ccc3c4c65)c21 ; C[Si](C)(C)c1ccc(N(c2cccc3c2[Si](C)(C)c2ccccc2-3)c2ccc3ccc4c(N(c5ccc([Si](C)(C)C)cc5)c5cccc6c5[Si](C)(C)c5ccccc5-6)ccc5ccc2c3c54)cc1]

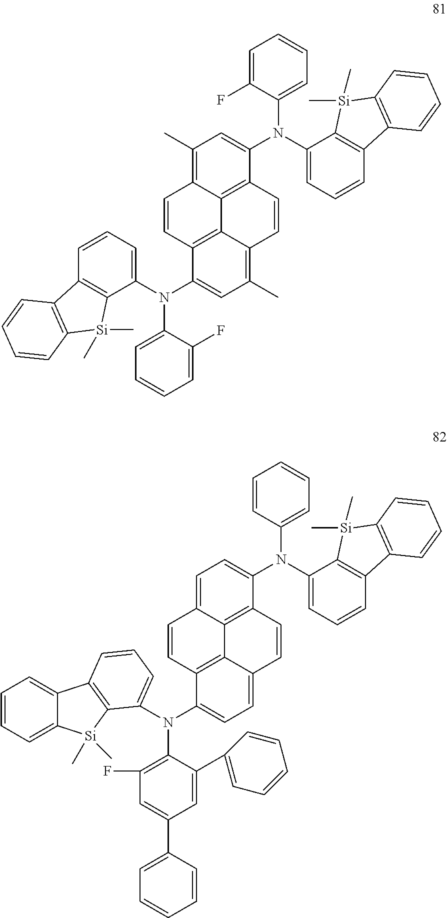 [SMILES: Cc1cc(N(c2ccccc2F)c2cccc3c2[Si](C)(C)c2ccccc2-3)c2ccc3c(C)cc(N(c4ccccc4F)c4cccc5c4[Si](C)(C)c4ccccc4-5)c4ccc1c2c34 ; C[Si]1(C)c2ccccc2-c2cccc(N(c3ccccc3)c3ccc4ccc5c(N(c6cccc7c6[Si](C)(C)c6ccccc6-7)c6c(F)cc(-c7ccccc7)cc6-c6ccccc6)ccc6ccc3c4c65)c21]

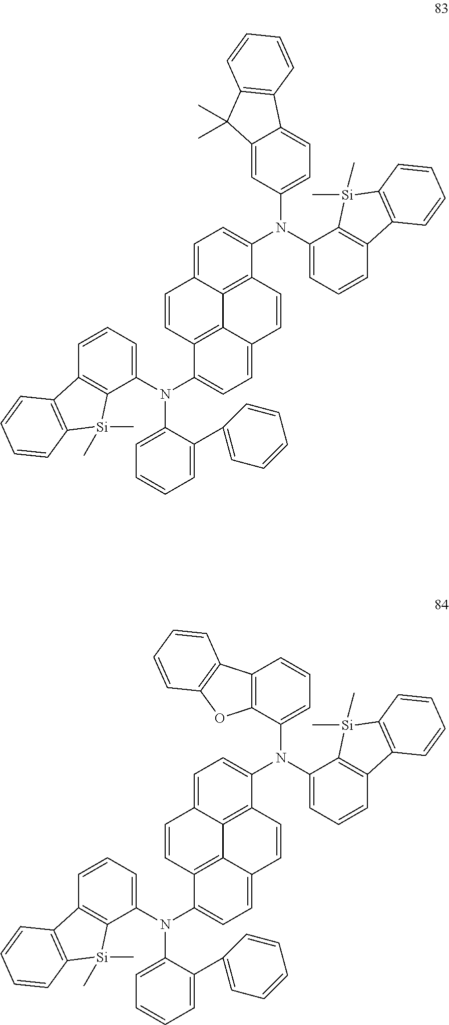 [SMILES: CC1(C)c2ccccc2-c2ccc(N(c3cccc4c3[Si](C)(C)c3ccccc3-4)c3ccc4ccc5c(N(c6ccccc6-c6ccccc6)c6cccc7c6[Si](C)(C)c6ccccc6-7)ccc6ccc3c4c65)cc21 ; C[Si]1(C)c2ccccc2-c2cccc(N(c3ccccc3-c3ccccc3)c3ccc4ccc5c(N(c6cccc7c6[Si](C)(C)c6ccccc6-7)c6cccc7c6oc6ccccc67)ccc6ccc3c4c65)c21]

An organic light-emitting device according to an embodiment includes a first electrode, a second electrode, and an organic layer disposed between the first electrode and the second electrode, wherein the organic layer includes the compound represented by Formula 1.

In some embodiments, the organic layer may include at least one layer selected from a hole injection layer, a hole transport layer, a functional layer having a hole injection function and a hole transport function (hereinafter referred to as “H-functional layer”), a buffer layer, an electron blocking layer, an emission layer, a hole blocking layer, an electron transport layer, an electron injection layer, and a functional layer having an electron transport function and an electron injection function (hereinafter referred to as “E-functional layer”).

In some embodiments, the organic layer may be an emission layer, and the compound may be used as a fluorescent dopant. For example, the compound may be used as a blue fluorescent dopant.

According to an embodiment, the organic layer is an emission layer, and the emission layer may include a compound represented by Formula 2:

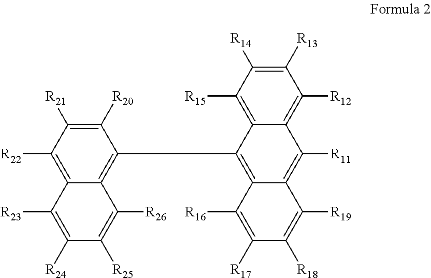

in Formula 2, R₁₁ to R₂₆ may be each independently a hydrogen, a deuterium, a substituted or unsubstituted a C₁ to C₃₀ alkylsilyl group, a substituted or unsubstituted a C₆ to C₃₀ arylsilyl group, a substituted or unsubstituted a C₁ to C₃₀ alkyl group, a substituted or unsubstituted a C₆ to C₃₀ aryl group, a substituted or unsubstituted a C₁ to C₃₀ heteroaryl group, or a substituted or unsubstituted a C₆ to C₃₀ condensed polycyclic group.

According to an embodiment, the compound represented by Formula 2 may be a host.

According to an embodiment, R₁₁, R₁₃, and R₂₁ to R₂₃ in Formula 2 may be each independently a hydrogen, a deuterium, a substituted or unsubstituted C₁ to C₂₀ alkyl group, —SiR₄₁R₄₂R₄₃, or any one of Formulae 4a to 4c:

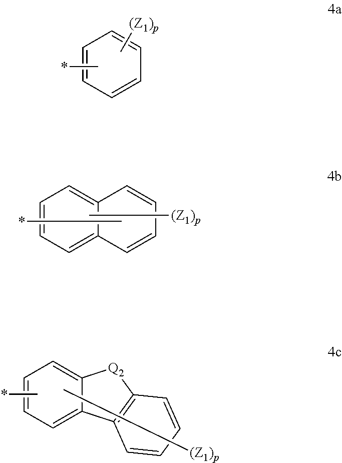

Q₂ in Formulae 4a to 4c may be —C(R₃₁)(R₃₂)—, —NR₃₃—, —S—, or —O—;
Z₁, R₃₁ to R₃₃, and R₄₁ to R₄₃ may be each independently a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, a halogen group, a substituted or unsubstituted C₁ to C₂₀ alkylsilyl group, a substituted or unsubstituted C₆ to C₂₀ arylsilyl group, a cyano group, a nitro group, a hydroxyl group, or a carboxyl group;
p may be an integer of 1 to 7; and * indicates an attachment point.

According to an embodiment, R₁₂, R₁₄ to R₂₀, R₂₄ to R₂₆ in Formula 2 may be each independently a hydrogen or a deuterium.

Examples of the compound represented by Formula 2 are compounds illustrated below, but are not limited thereto.

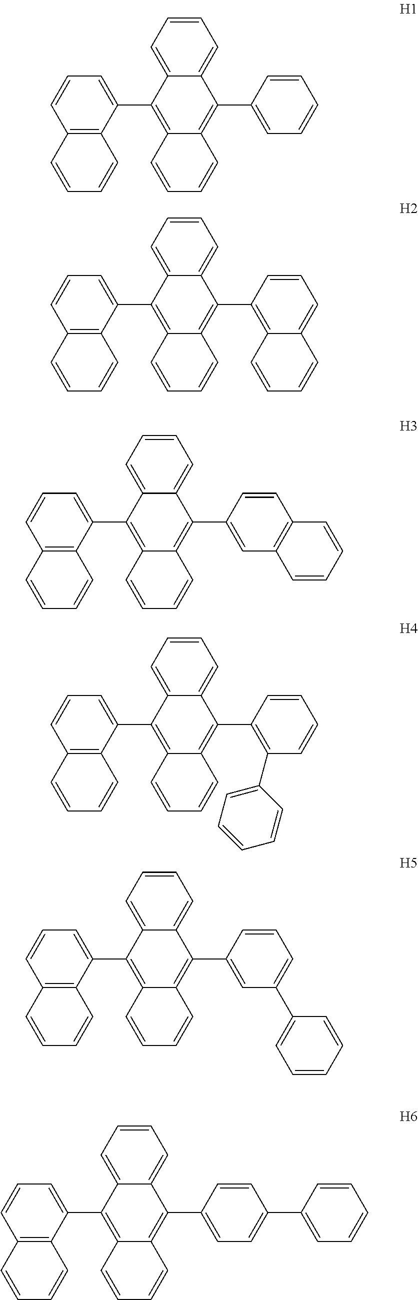

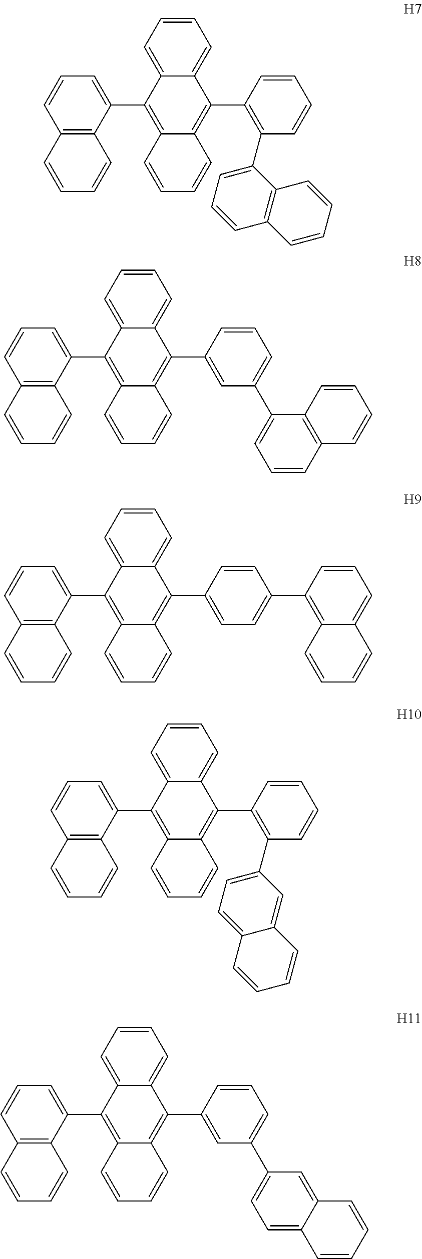

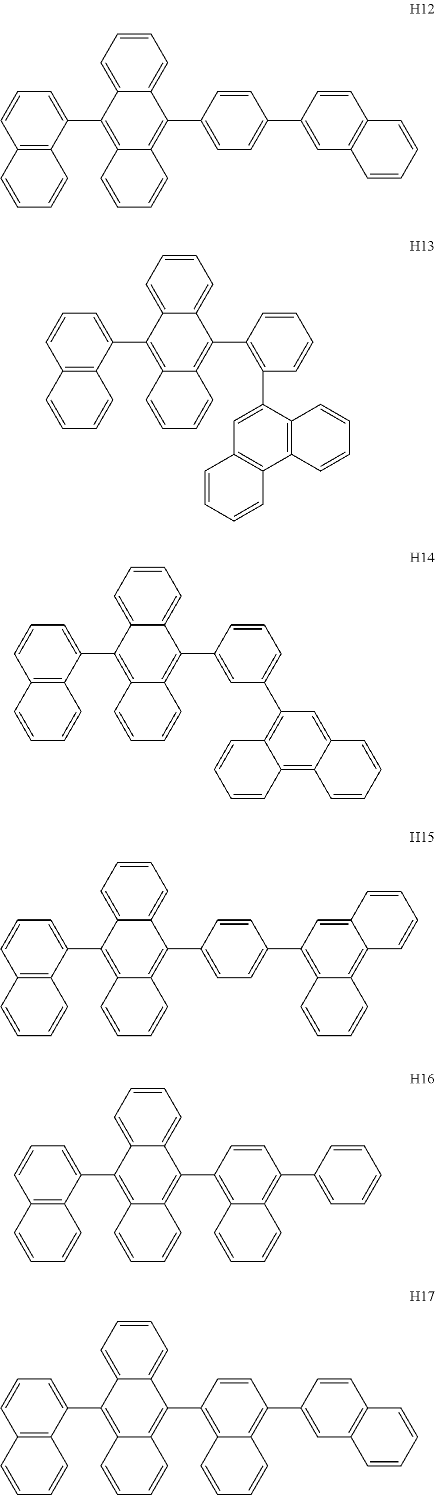

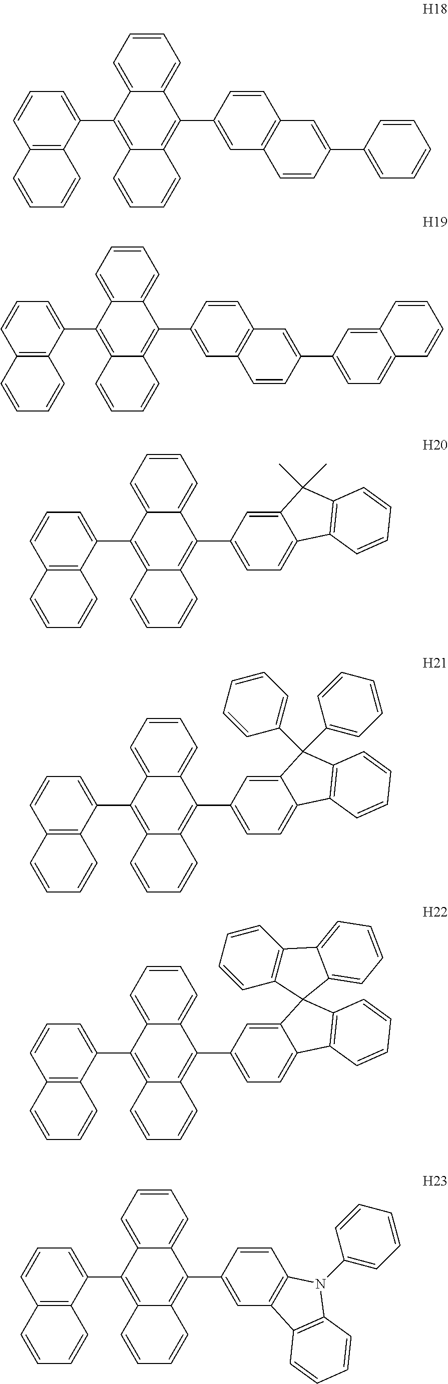

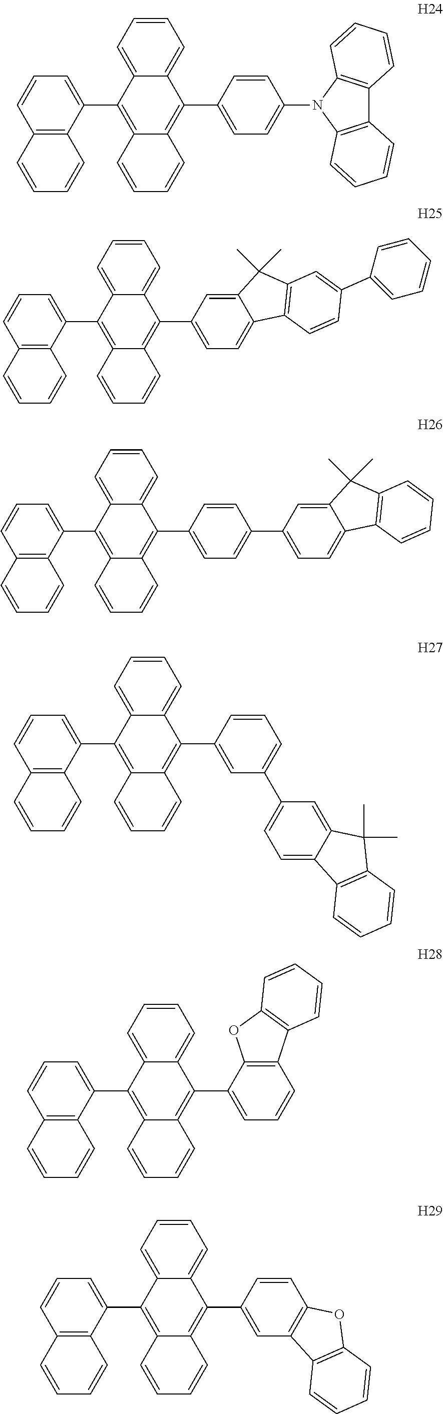

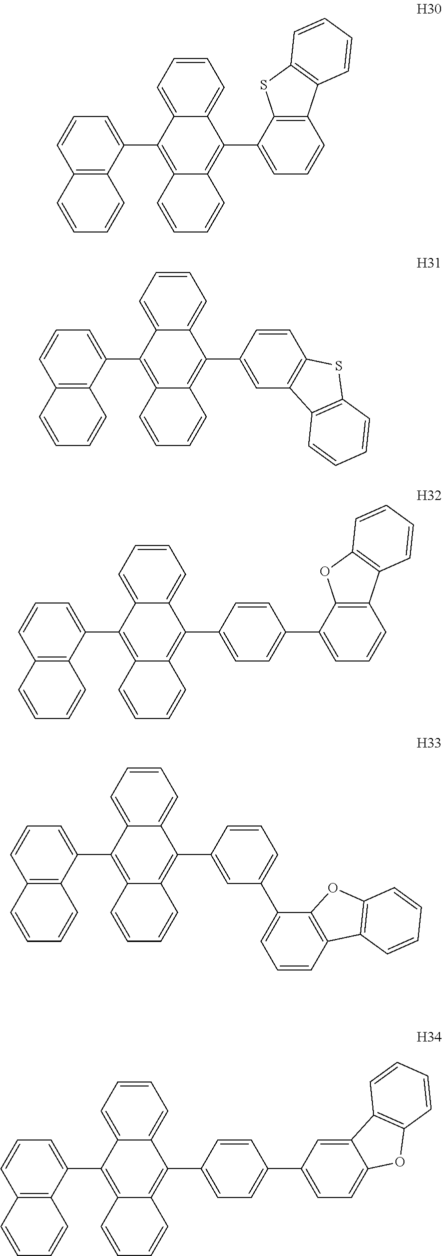

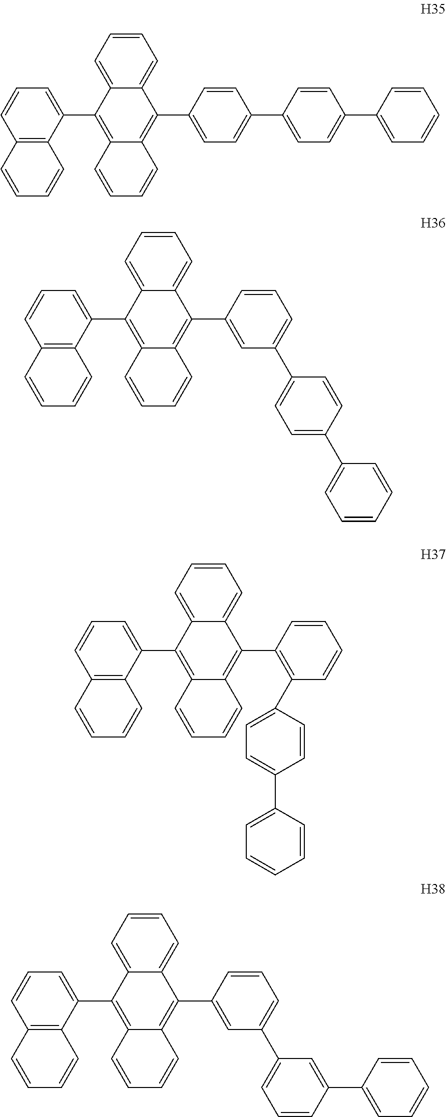

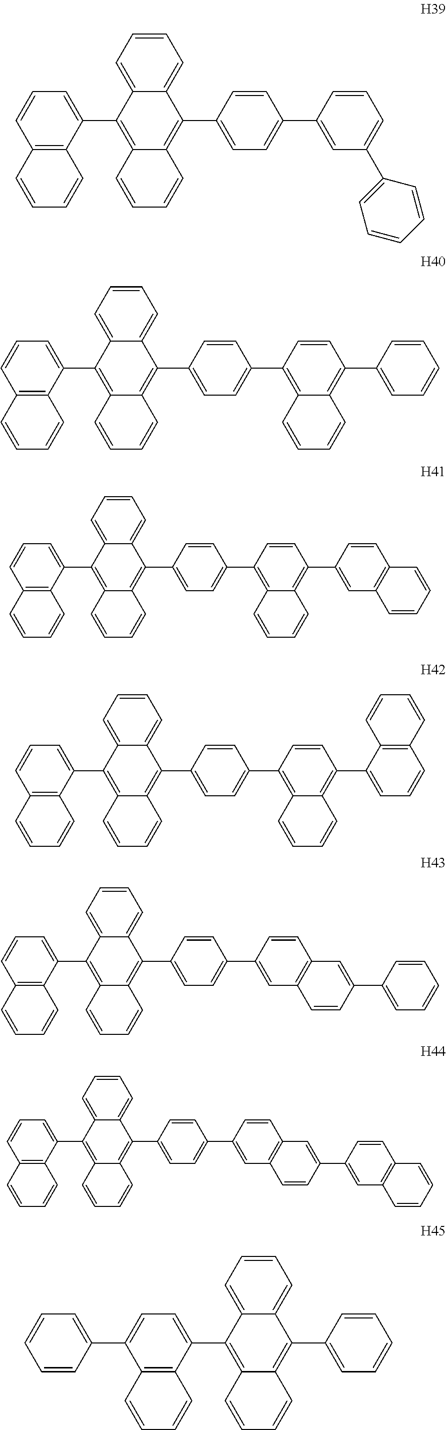

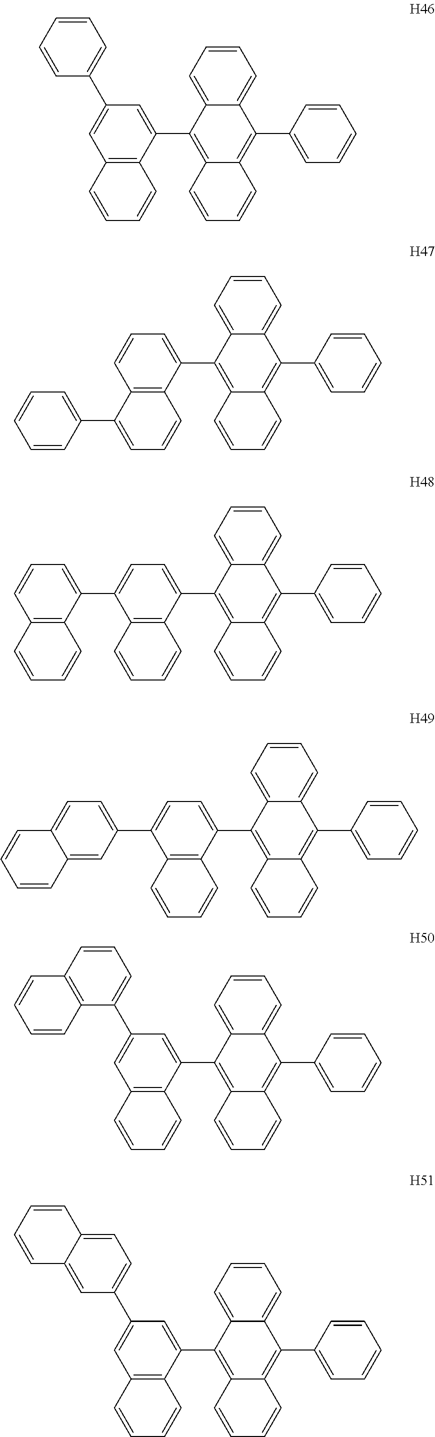

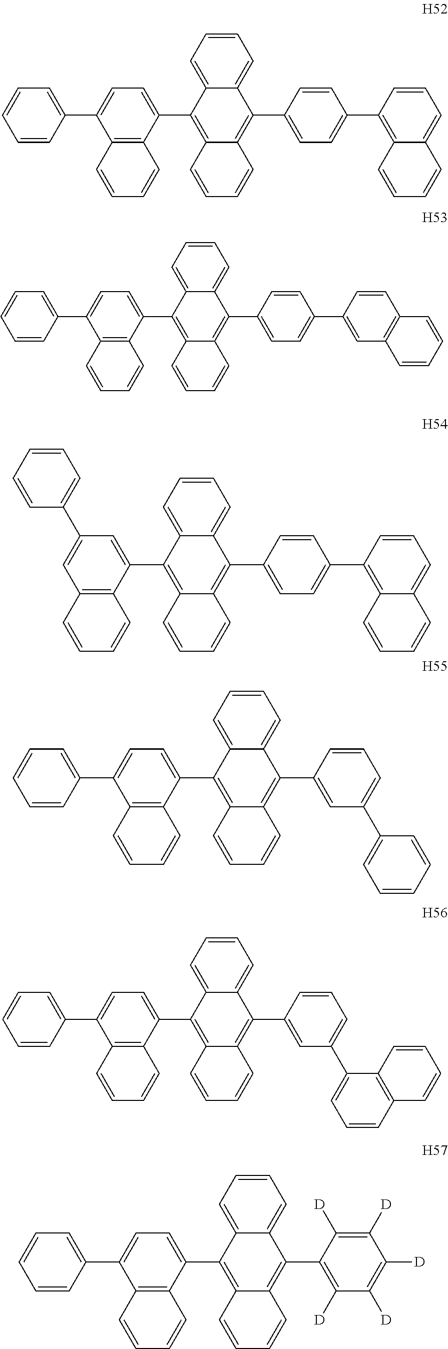

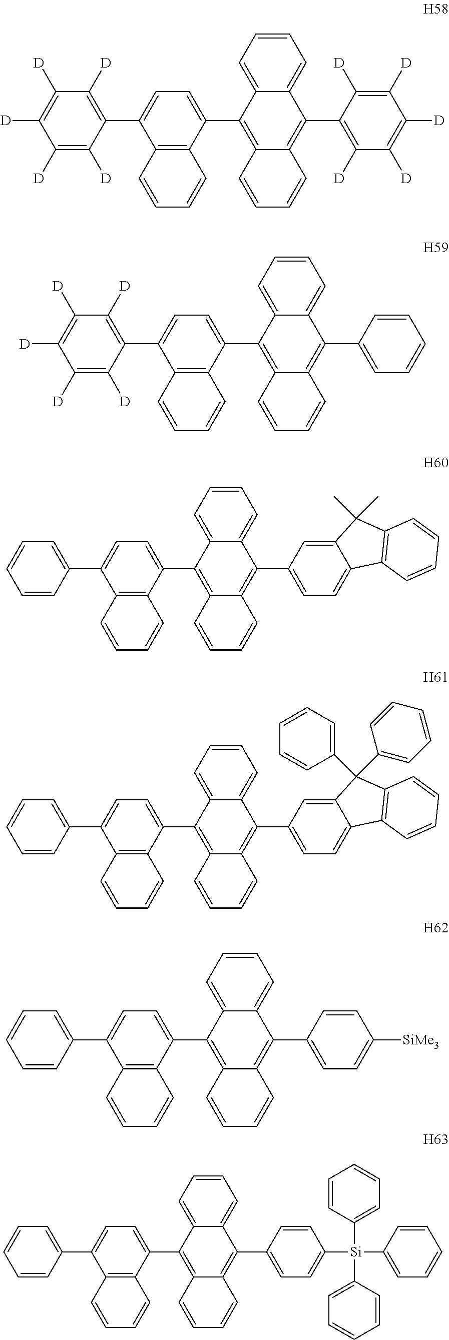

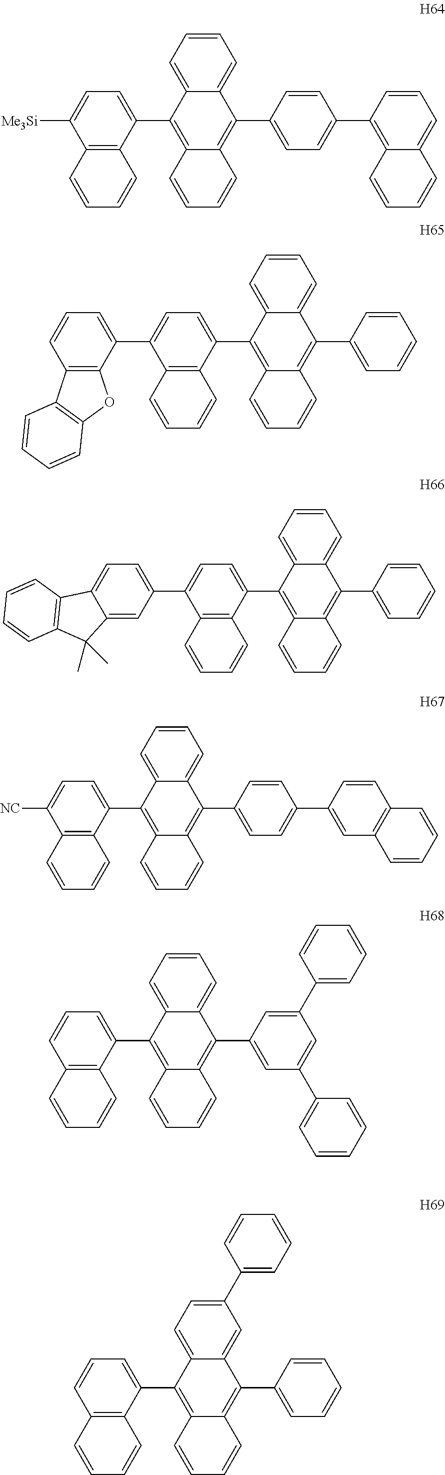

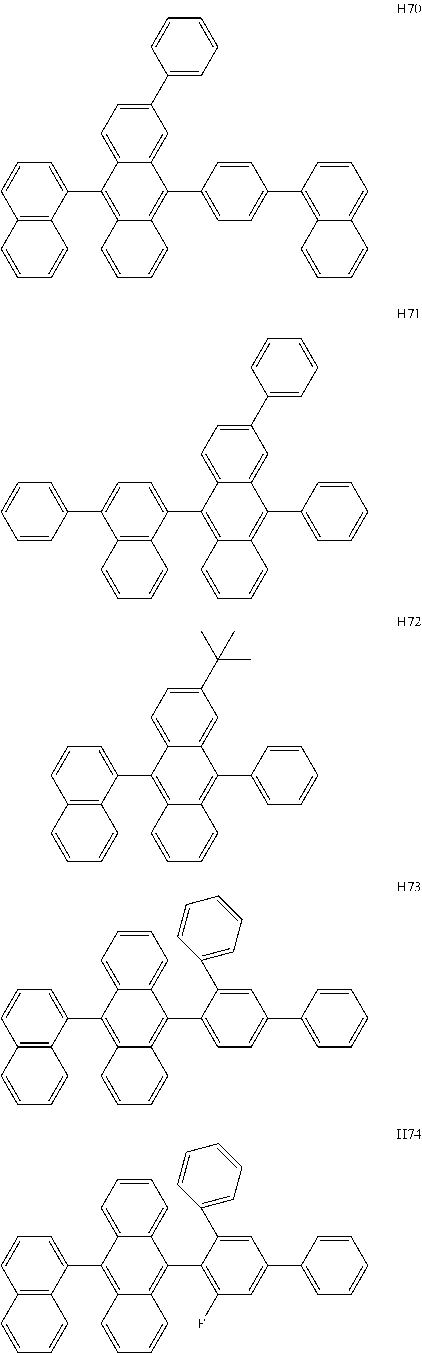

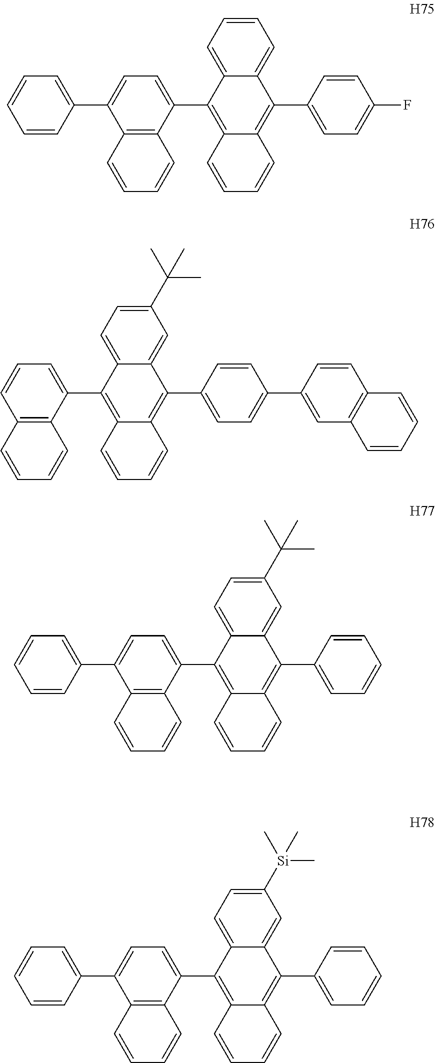

According to an embodiment, the organic light-emitting device may include an electron injection layer, an electron transport layer, an emission layer, a hole injection layer, a hole transport layer, or a H-functional layer, and the emission layer may include an anthracene-based compound, an arylamine-based compound, or a styryl-based compound.

According to another embodiment, the organic light-emitting device may include an electron injection layer, an electron transport layer, an emission layer, a hole injection layer, a hole transport layer, or a H-functional layer, and the emission layer may includes a red layer, a green layer, a blue layer, and a white layer, and any one of these layers may include a phosphorescent compound, and the hole injection layer, the hole transport layer, or the H-functional layer may include a charge-generation material. Also, the charge-generation material may be a p-dopant, and the p-dopant may be a quinone derivative, a metal oxide, or a cyano group-containing compound.

According to another embodiment, the organic layer may include an electron transport layer that includes a metal complex. The metal complex may be a Li complex.

The term “organic layer” as used herein refers to a single layer and/or a plurality of layers disposed between the first electrode and the second electrode of an organic light-emitting device.

FIG. 1 is a schematic cross-sectional view of an organic light-emitting device according to an embodiment. Hereinafter, the structure of an organic light-emitting device according to an embodiment and a method of manufacturing an organic light-emitting device according to an embodiment will be described in connection with FIG. 1.

A substrate (not shown) may be any one of various substrates that are used in a known organic light-emitting device, and may be a glass substrate or a transparent plastic substrate, with excellent mechanical strength, thermal stability, transparency, surface smoothness, ease of handling, and water repellency.

The first electrode may be formed by, for example, depositing or sputtering a material for a first electrode on the substrate. When the first electrode is an anode, the material for the first electrode may be selected from materials with a high work function to make holes be easily injected. The first electrode may be a reflective electrode or a transmission electrode. In some embodiments, the material for the first electrode may be a transparent and highly conductive material, and examples of such a material are indium tin oxide (ITO), indium zinc oxide (IZO), tin oxide (SnO₂), and zinc oxide (ZnO). In some embodiments, magnesium (Mg), aluminum (Al), aluminum-lithium (Al—Li), calcium (Ca), magnesium-indium (Mg—In), or magnesium-silver (Mg—Ag) may be used to form the first electrode as a reflective electrode.

In some embodiments, the first electrode may be a single- or multi-layered structure. For example, the first electrode may have a three-layered structure of ITO/Ag/ITO, but the structure of the first electrode is not limited thereto.

In some embodiments, an organic layer is disposed on the first electrode.

In some embodiments, the organic layer may include a hole injection layer, a hole transport layer, a buffer layer (not shown), an emission layer, an electron transport layer, or an electron injection layer.

In some embodiments, a hole injection layer (HIL) may be formed on the first electrode by using various methods, such as vacuum deposition, spin coating, casting, langmuir-blodgett (LB) deposition, or the like.

When a hole injection layer is formed by vacuum deposition, the deposition conditions may vary according to a material that is used to form the hole injection layer, and the structure and thermal characteristics of the hole injection layer. For example, the deposition conditions may include a deposition temperature of about 100 to about 500° C., a vacuum pressure of about 10⁻⁸ to about 10⁻³ torr, and a deposition rate of about 0.01 to about 100 Å/sec. However, the deposition conditions are not limited thereto.

When the hole injection layer is formed using spin coating, coating conditions may vary according to the material used to form the hole injection layer, and the structure and thermal properties of the hole injection layer. For example, a coating speed may be from about 2000 rpm to about 5000 rpm, and a temperature at which a heat treatment is performed to remove a solvent after coating may be from about 80° C. to about 200° C. However, the coating conditions are not limited thereto.

For use as a hole injection material, any known hole injection material may be used, and examples of any known hole injection material are N,N′-diphenyl-N,N′-bis-[4-(phenyl-m-tolyl-amino)-phenyl]-biphenyl-4,4′-diamine (DNTPD), a phthalocyanine compound such as copper phthalocyanine, 4,4′,4″-tris(3-methylphenylphenylamino)triphenylamine (m-MTDATA), N,N′-di(1-naphthyl)-N,N′-diphenylbenzidine (NPB), TDATA, 2-TNATA, a polyaniline/dodecylbenzenesulfonic acid (pani/DBSA), poly(3,4-ethylenedioxythiophene)/poly(4-styrenesulfonate) (PEDOT/PSS), polyaniline/camphor sulfonicacid (pani/CSA), and (polyaniline)/poly(4-styrenesulfonate) (PANI/PSS), but they are not limited thereto.

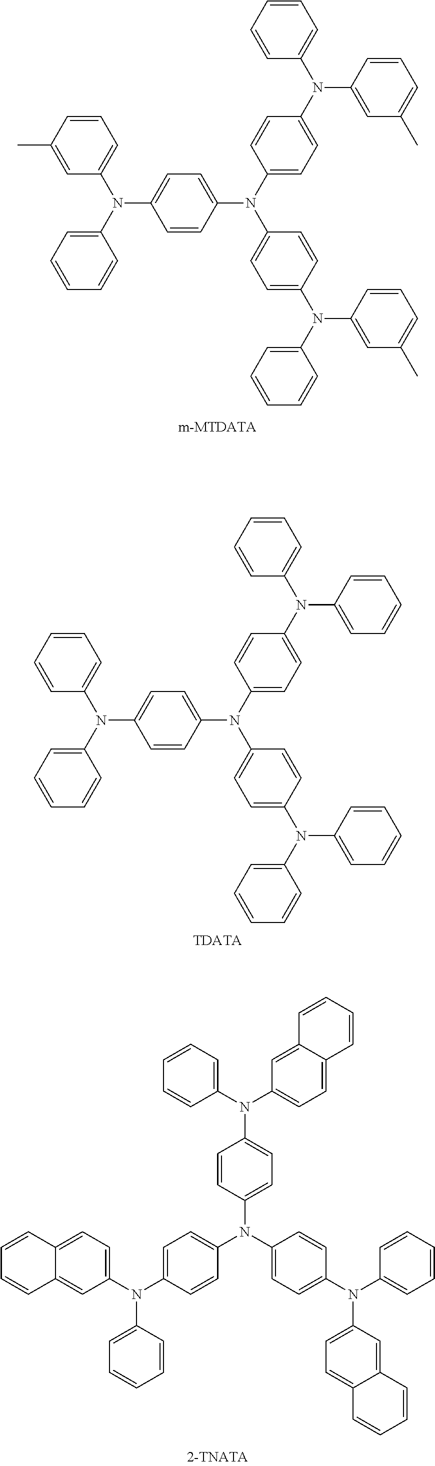

In some embodiments, a thickness of the hole injection layer may be in a range of about 100 Å to about 10,000 Å, for example, about 100 Å to about 1000 Å. If the thickness of the hole injection layer is within the ranges described above, excellent electron injection characteristics may be obtained without a substantial increase in driving voltage.

Then, a hole transport layer (HTL) may be formed on the hole injection layer by using vacuum deposition, spin coating, casting, or LB. When the hole transport layer is formed by vacuum deposition or spin coating, the deposition or coating conditions may be similar to those applied to form the hole injection layer although the deposition or coating conditions may vary according to the material that is used to form the hole transport layer.

For use as a hole transport material, any known hole transport material may be used. Examples of a known hole transport material are a carbazole derivative, such as N-phenylcarbazole or polyvinylcarbazol, N,N-bis(3-methylphenyl)-N,N-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine (NPB), but are not limited thereto.

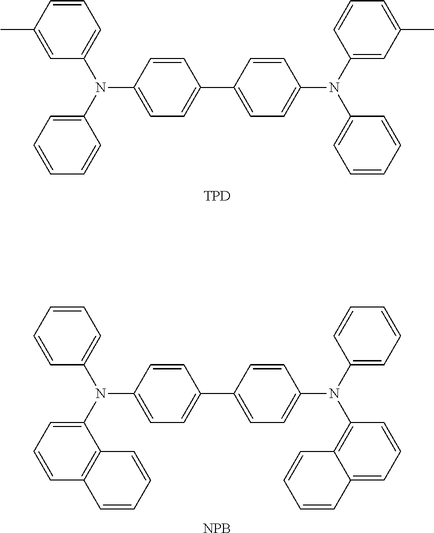

In some embodiments, a thickness of the hole transport layer may be in a range of about 50 Å to about 2,000 Å, for example, about 100 Å to about 1,500 Å. When the thickness of the hole transport layer is within these ranges, the hole transport layer may have satisfactory hole transporting ability without a substantial increase in driving voltage.

In some embodiments, the H-functional layer may include at least one material selected from the materials used to form a hole injection layer and the materials used to form a hole transport layer, and a thickness of the H-functional layer may be in a range of about 100 Å to about 10000 Å, for example, about 100 Å to about 1000 Å. When the thickness of the H-functional layer is within these ranges, satisfactory hole injection and transport characteristics may be obtained without a substantial increase in driving voltage.

In some embodiments, at least one layer of the hole injection layer, the hole transport layer, and the H-functional layer may include at least one of a compound represented by Formula 300 and a compound represented by Formula 350:

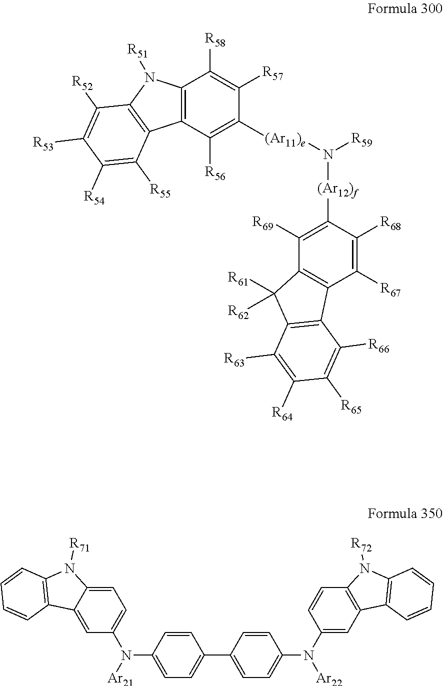

wherein in Formulae 300 and 350, Ar₁₁, Ar₁₁, Ar₂₁, and Ar₂₂ are each independently, a substituted or unsubstituted C₆-C₆₀ arylene group.

In some embodiments, e and f in Formula 300 may be each independently an integer of 0 to 5, or 0, 1 or 2. For example, e may be 1 and f may be 0, but are not limited thereto.

In some embodiments, R₅₁ to R₅₈, R₆₁ to R₆₉ and R₇₁ and R₇₂ in Formulae 300 and 350 may be each independently a hydrogen, a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₆-C₆₀ aryloxy group, or substituted or unsubstituted C₆-C₆₀ arylthio group. For example, R₅₁ to R₅₈, R₆₁ to R₆₉, and R₇₁ and R₇₂ may be each independently selected from a hydrogen; a deuterium; a halogen atom; a hydroxyl group; a cyano group; a nitro group; an amino group; an amidino group; a hydrazine group; a hydrazone group; a carboxylic acid group or a salt thereof; a sulfonic acid group or a salt thereof; a phosphoric acid group or a salt thereof; a C₁-C₁₀ alkyl group (for example, a methyl group, an ethyl group, a propyl group, a butyl group, a pentyl group, or a hexyl group); a C₁-C₁₀ alkoxy group (for example, a methoxy group, an ethoxy group, a propoxy group, a butoxy group, or a pentoxy group);
a C₁-C₁₀ alkyl group and a C₁-C₁₀ alkoxy group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof and a phosphoric acid group or a salt thereof;
a phenyl group; a naphthyl group; anthryl group; a fluorenyl group; a pyrenyl group; and
a phenyl group, a naphthyl group, anthryl group, a fluorenyl group and a pyrenyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₁₀ alkyl group, and a C₁-C₁₀ alkoxy group.
R₅₉ in Formula 300 may be one selected from
a phenyl group; a naphthyl group; anthryl group; a biphenyl group; a pyridyl group; and
a phenyl group, a naphthyl group, anthryl group, a biphenyl group and a pyridyl group, each substituted with at least one selected from a deuterium, a halogen atom, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₂₀ alkyl group, and a substituted or unsubstituted C₁-C₂₀ alkoxy group.

According to an embodiment, the compound represented by Formula 300 may be represented by Formula 300A, but is not limited thereto:

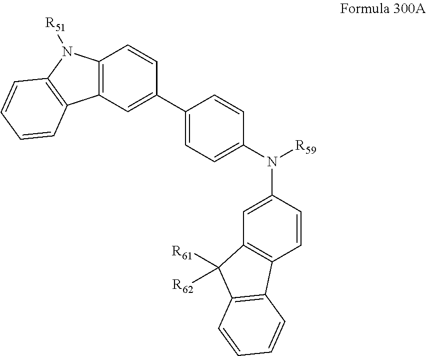

where R₅₁, R₆₀, R₆₁, and R₅₉ in Formula 300A are defined as described for Formula 300.

For example, at least one layer of the hole injection layer, the hole transport layer, and the H-functional layer may include at least one of Compounds 301 to 320, but may instead include other materials.

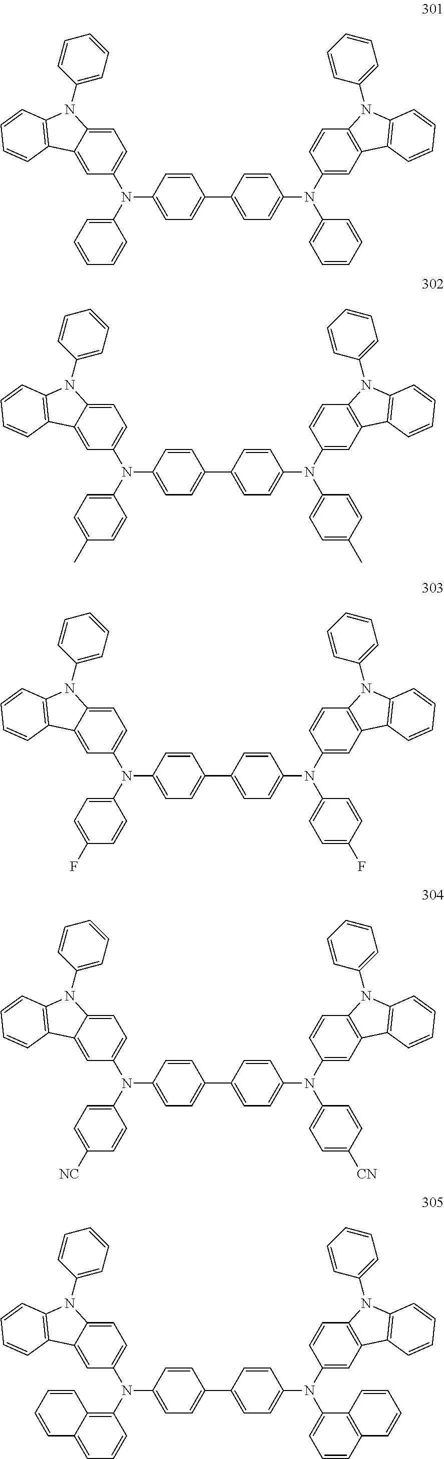

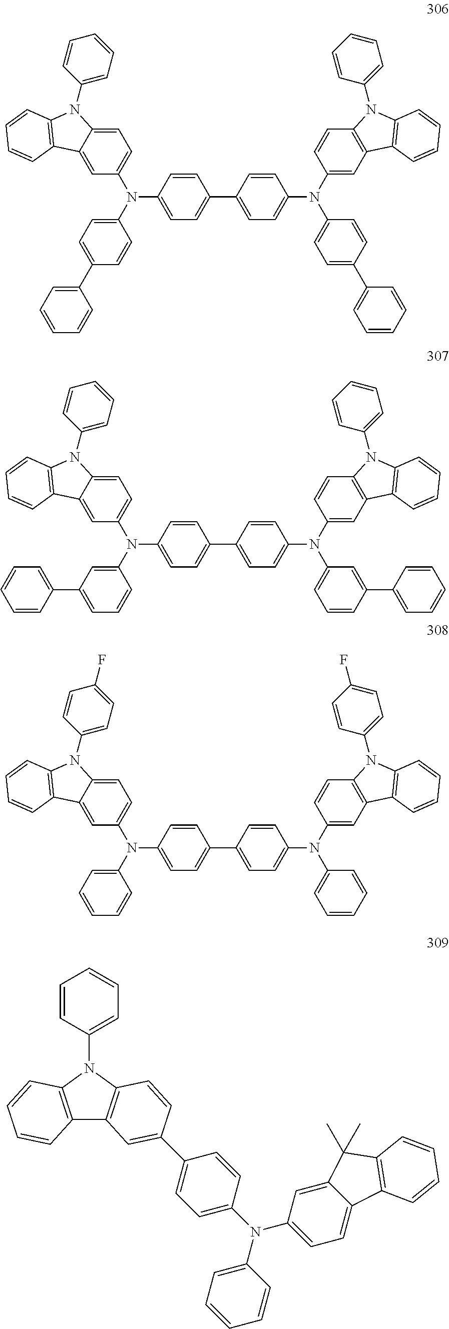 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

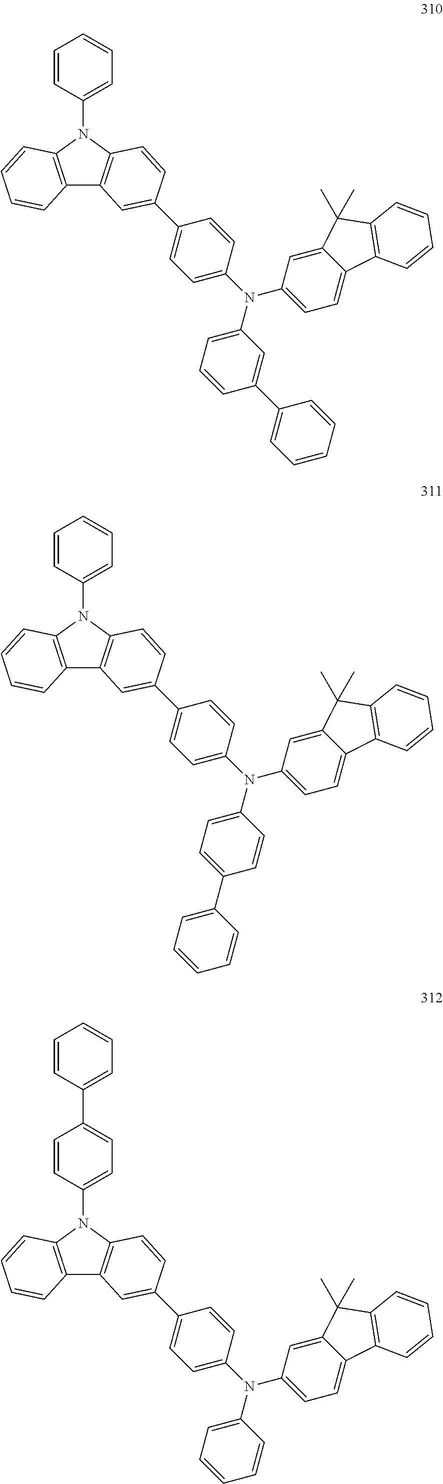 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

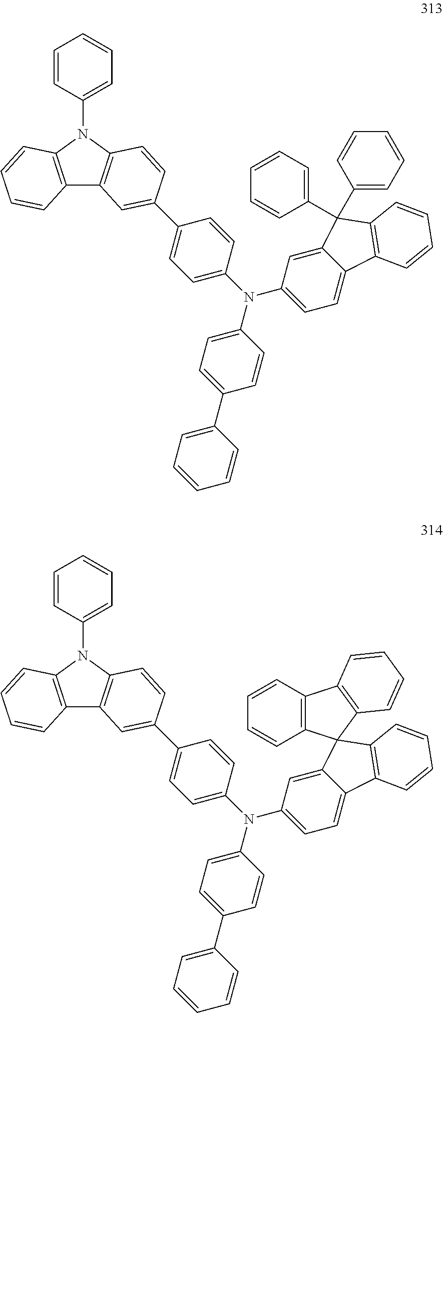

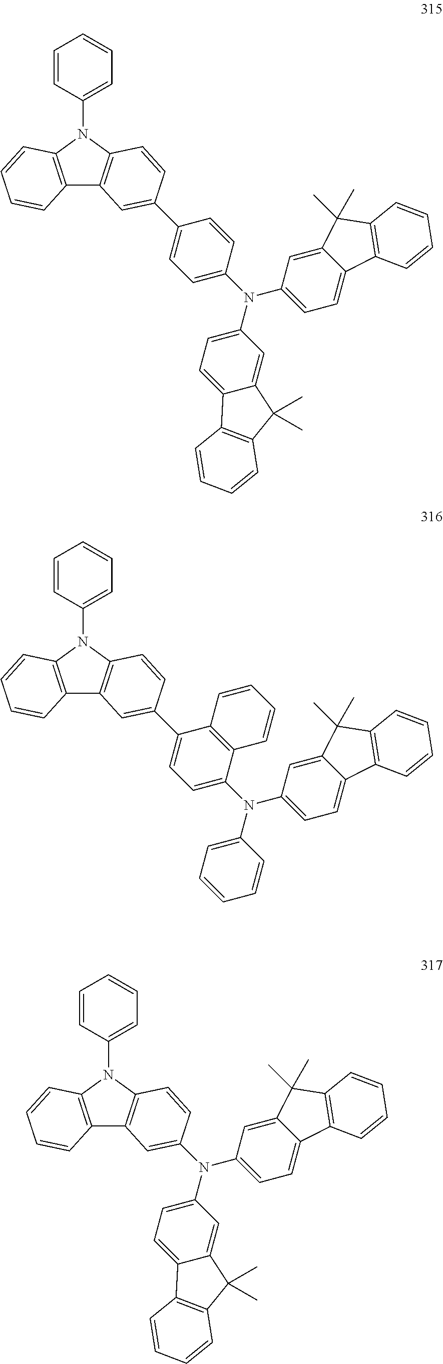 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21]

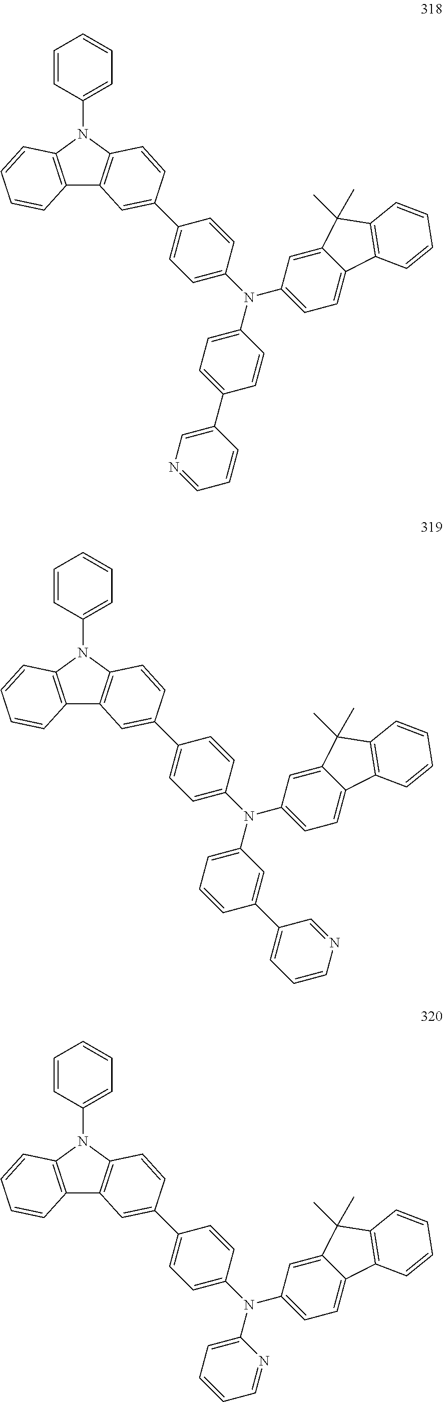 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

In some embodiments, at least one of the hole injection layer, the hole transport layer, and the H-functional layer may further include a charge-generating material to increase conductivity of a layer, in addition to such known hole injection materials, known hole transport materials, and/or known materials having both hole injection and hole transport capabilities.

In some embodiments, the charge-generation material may be, for example, a p-dopant. In some embodiments, the p-dopant may be one of a quinone derivative, a metal oxide, and a cyano group-containing compound, but is not limited thereto. Non-limiting examples of the p-dopant are a quinone derivative, such as tetracyanoquinonedimethane (TCNQ) or 2,3,5,6-tetrafluoro-tetracyano-1,4-benzoquinonedimethane (F4-TCNQ); a metal oxide, such as tungsten oxide or molybdenium oxide; and a cyano group-containing compound, such as Compound 200, but are not limited thereto.

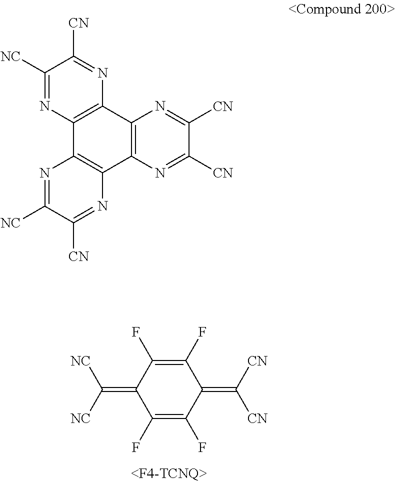 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, the hole transport layer or the H-functional layer further includes a charge-generation material, the charge-generation material may be homogeneously dispersed or non-homogeneously distributed in the hole injection layer, the hole transport layer, and the H-functional layer.

In some embodiments, a buffer layer may be disposed between at least one of the hole injection layer, the hole transport layer, and the H-functional layer, and an emission layer. Also, the buffer layer may compensate for an optical resonance distance according to a wavelength of light emitted from the emission layer, and thus, efficiency of a formed organic light-emitting device may be improved. The buffer layer may include a known hole injection material and a hole transport material. Also, the buffer layer may include a material that is identical to one of materials included in the hole injection layer, the hole transport layer, and the H-functional layer formed under the buffer layer.

Subsequently, an emission layer (EML) may be formed on the hole transport layer, the H-functional layer, or the buffer layer by spin coating, casting, or a LB method. When the emission layer is formed by vacuum deposition or spin coating, the deposition and coating conditions may be similar to those for the formation of the hole injection layer, though the conditions for deposition and coating may vary according to the material that is used to form the emission layer.

In some embodiments, the emission layer may include a compound as disclosed and described herein. For example, the compound represented by Formula 1 may be used as a dopant, and the compound represented by Formula 2 may be used as a host. In addition to the compound of Formula 1 and the compound of Formula 2, the emission layer may be formed by using any known luminescent materials. For example, the emission layer may be formed by using a known host and a known dopant. An example of the dopant may be any known fluorescent or phosphorescent dopant.

Examples of known host are Alq₃, 4,4′-N,N′-dicarbazole-biphenyl (CBP), poly(n-vinylcarbazole)(PVK), 9,10-di(naphthalene-2-yl)anthracene (ADN), TCTA, 1,3,5-tris(N-phenylbenzimidazole-2-yl)benzene (TPBI), 3-tert-butyl-9,10-di(naphth-2-yl) anthracene (TBADN), E3, distyrylarylene (DSA), dmCBP (see the following chemical structure), and Compounds 501 to 509, but are not limited thereto.

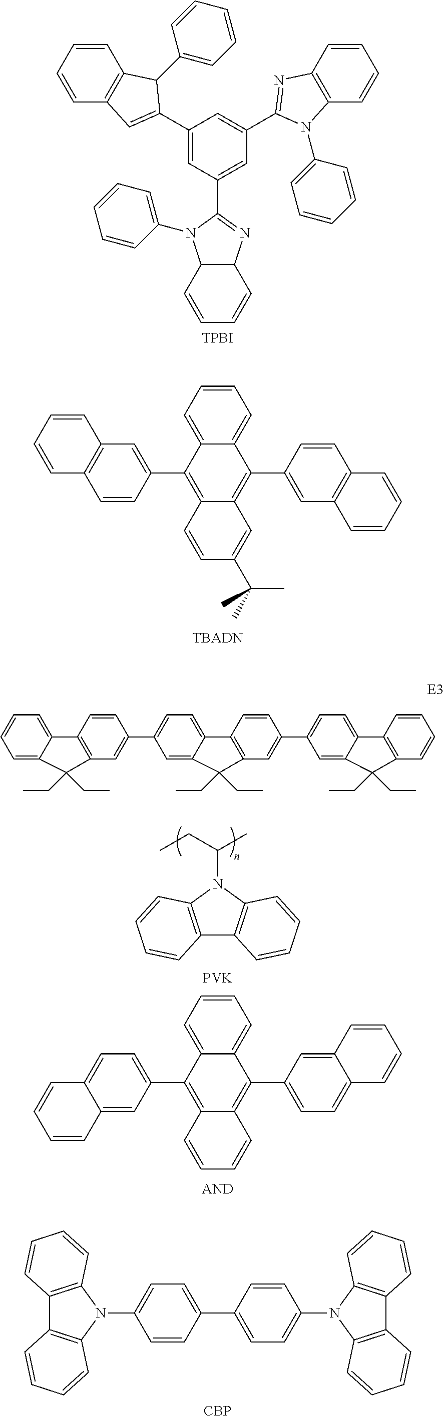

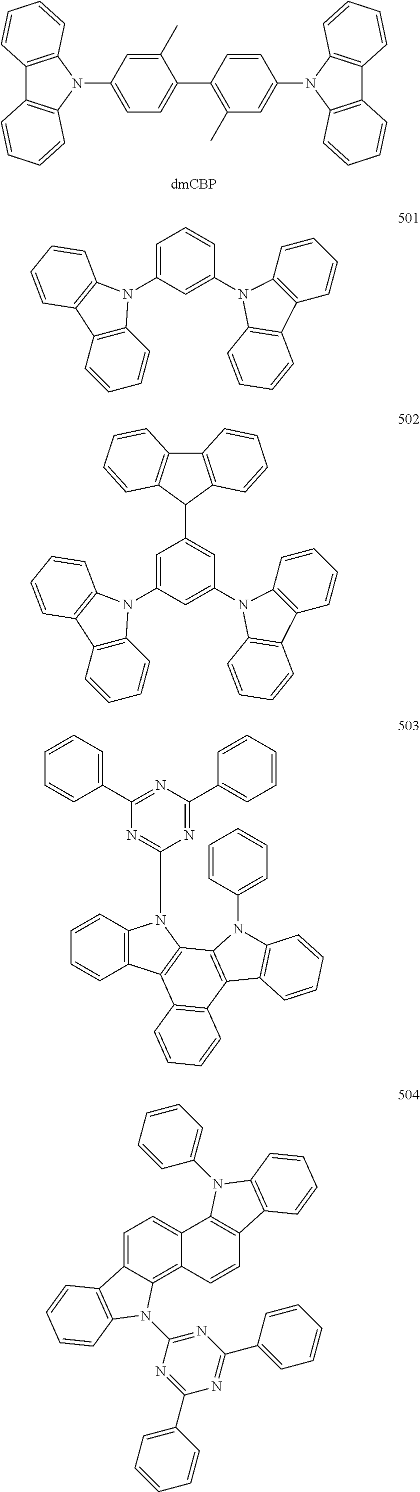

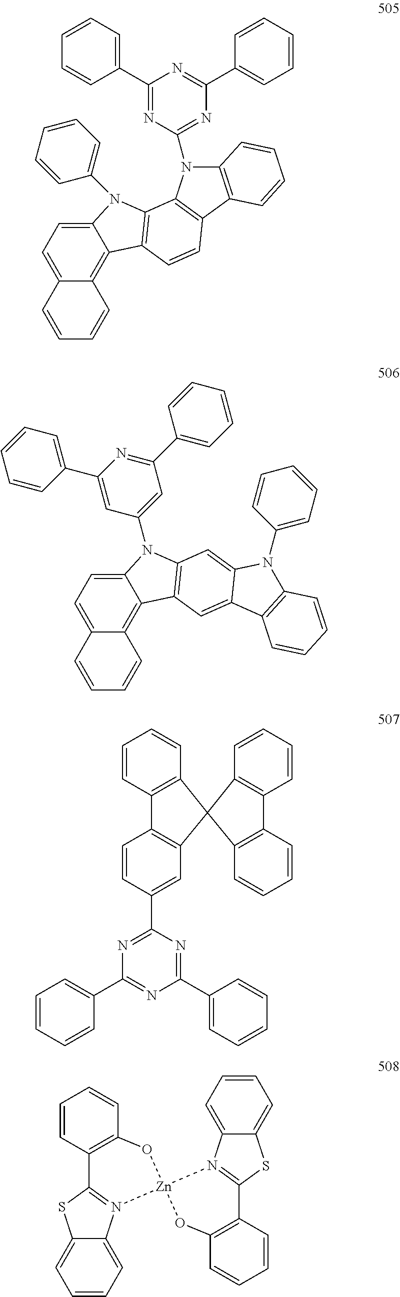

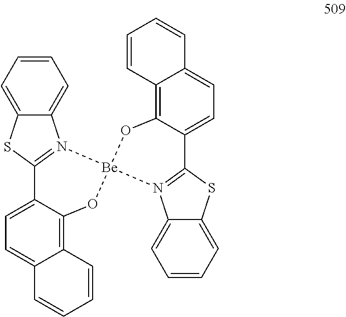

Also, the host may be an anthracene-based compound represented by Formula 401:

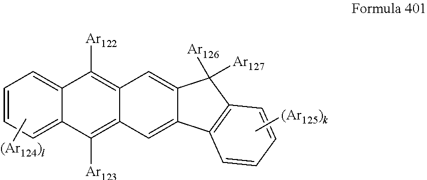

Ar₁₂₂ to Ar₁₂₅ in Formula 401 are the same as described in detail in connection with Ar₁₁₃ in Formula 400.

In some embodiments, Ar₁₂₆ and Ar₁₂₇ in Formula 401 may be each independently a C₁-C₁₀ alkyl group. In some embodiments, Ar₁₂₆ and Ar₁₂₇ in Formula 401 may be each independently a methyl group, an ethyl group, or a propyl group.

In some embodiments, k and l in Formula 401 may be each independently an integer of 0 to 4. For example, k and l may be 0, 1, or 2.

For example, the anthracene-based compound represented by Formula 401 may be one of the following compounds, but is not limited thereto:

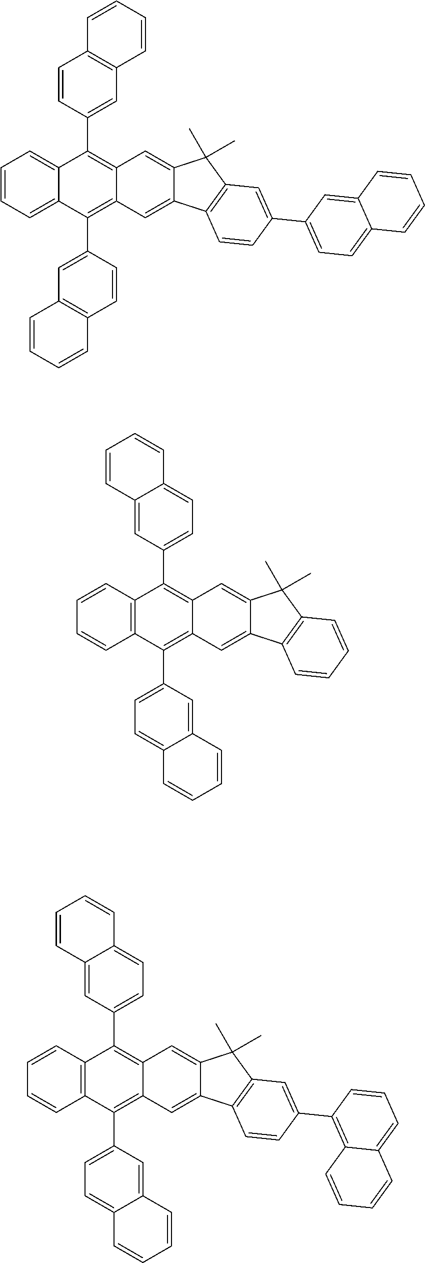

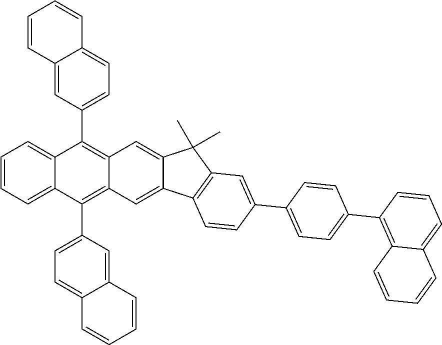 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting device is a full color organic light-emitting device, the emission layer may be patterned into a red emission layer, a green emission layer, and a blue emission layer.

Also, at least one of the red emission layer, the green emission layer, and the blue emission layer may include the following dopants (ppy=phenylpyridine)

For example, compounds illustrated below may be used as a blue dopant, but the blue dopant is not limited thereto.

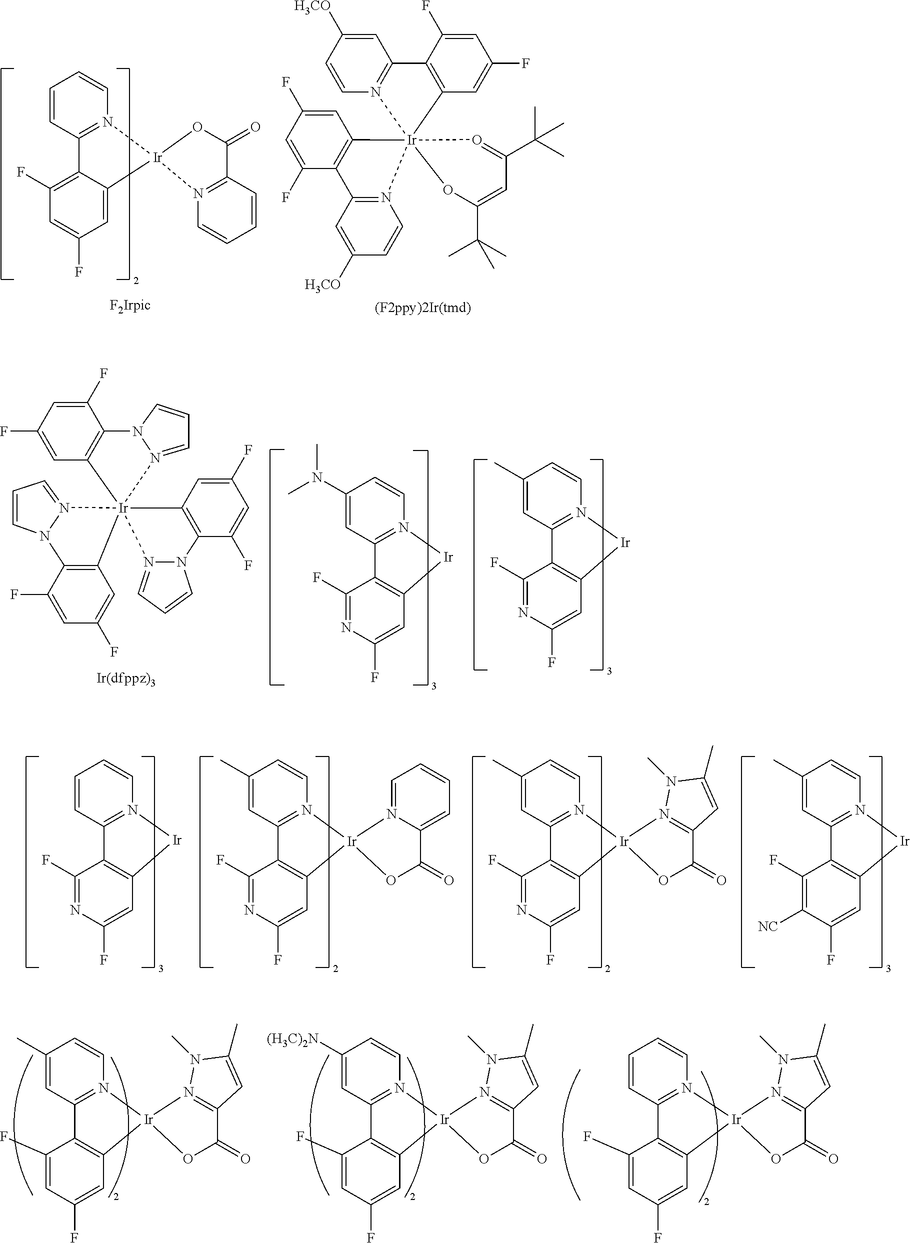

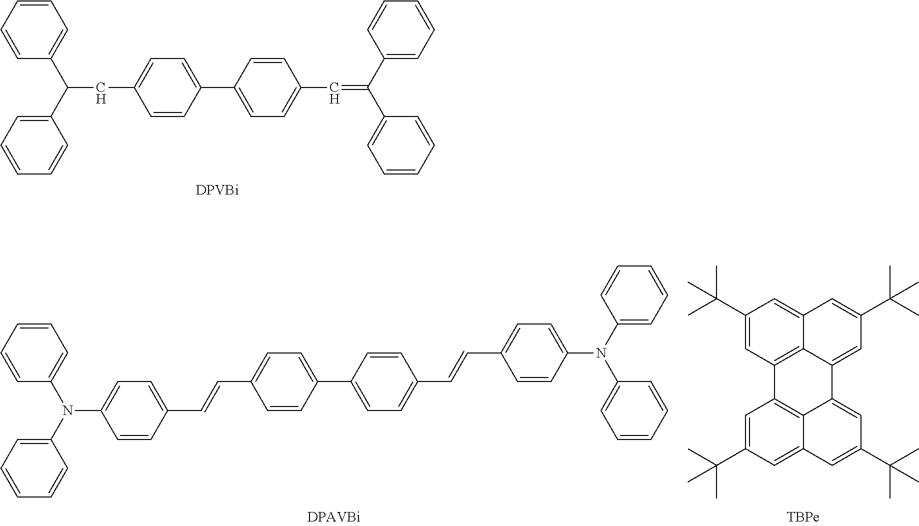

For example, compounds illustrated below may be used as a red dopant, but the red dopant is not limited thereto.

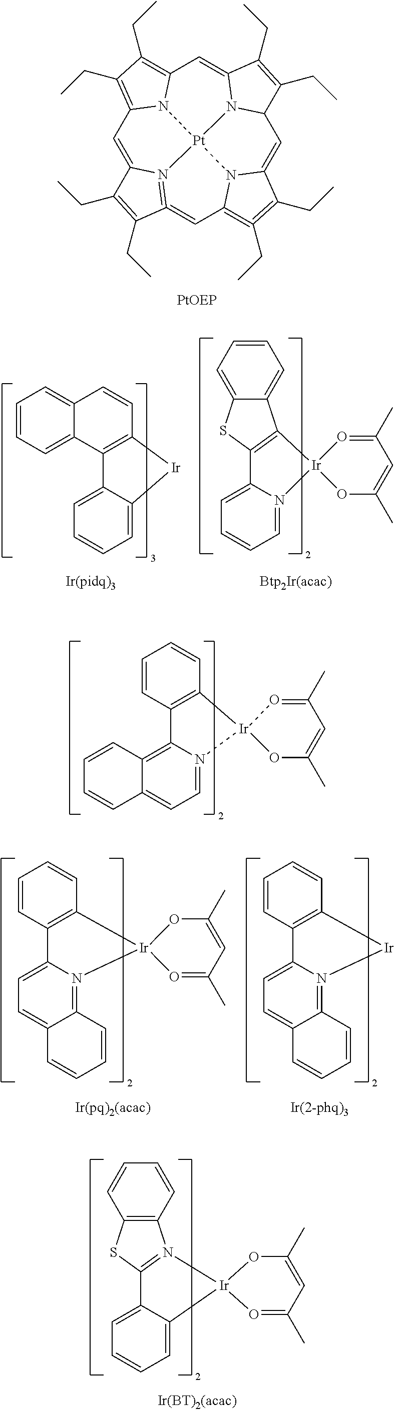

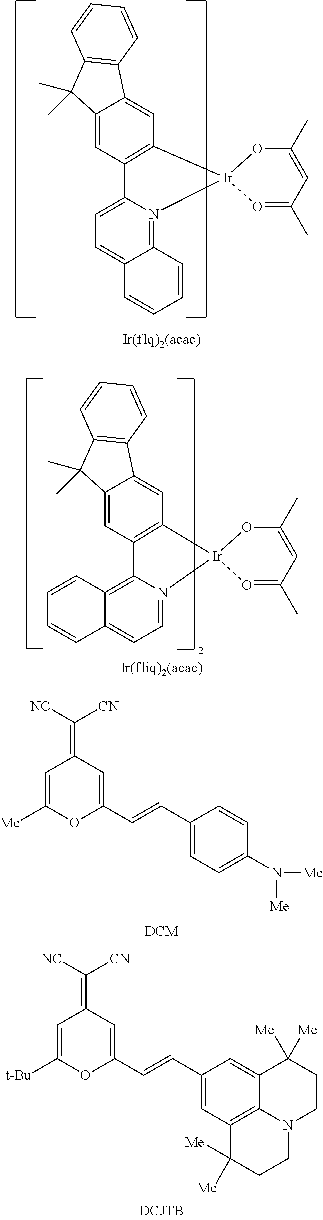

For example, compounds illustrated below may be used as a green dopant, but the green dopant is not limited thereto.

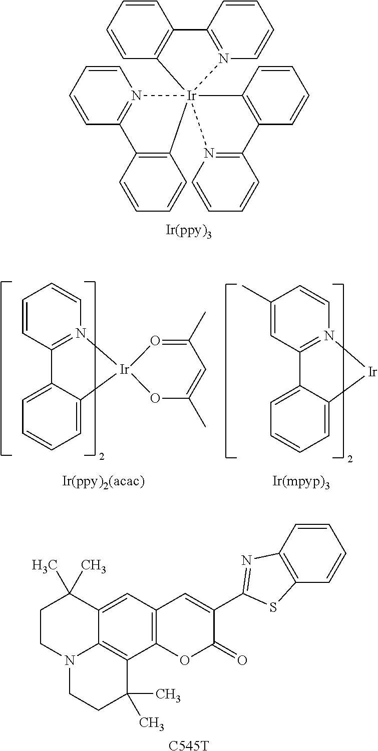

Also, the dopant available for use in the emission layer may be a complex described below, but is not limited thereto:

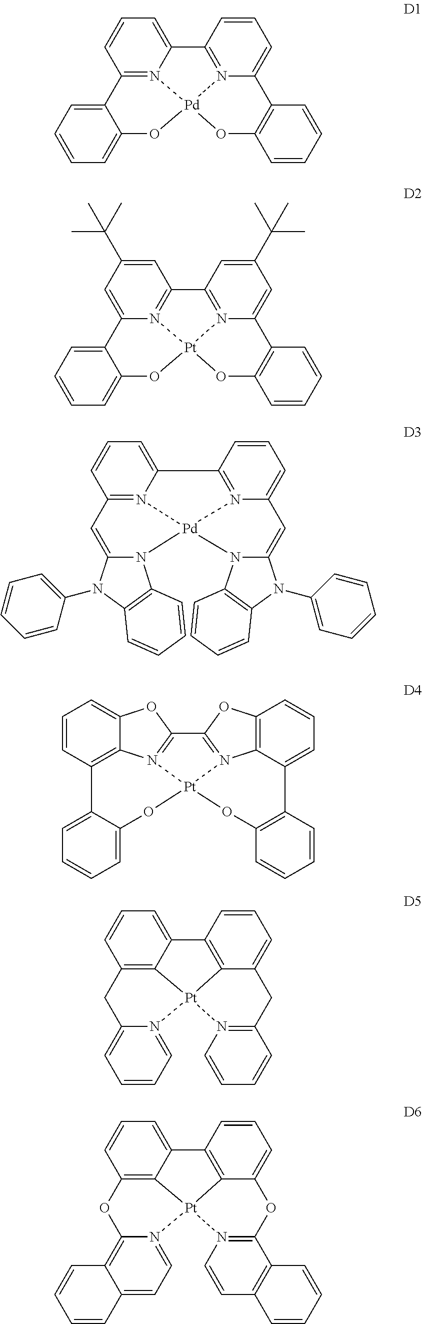

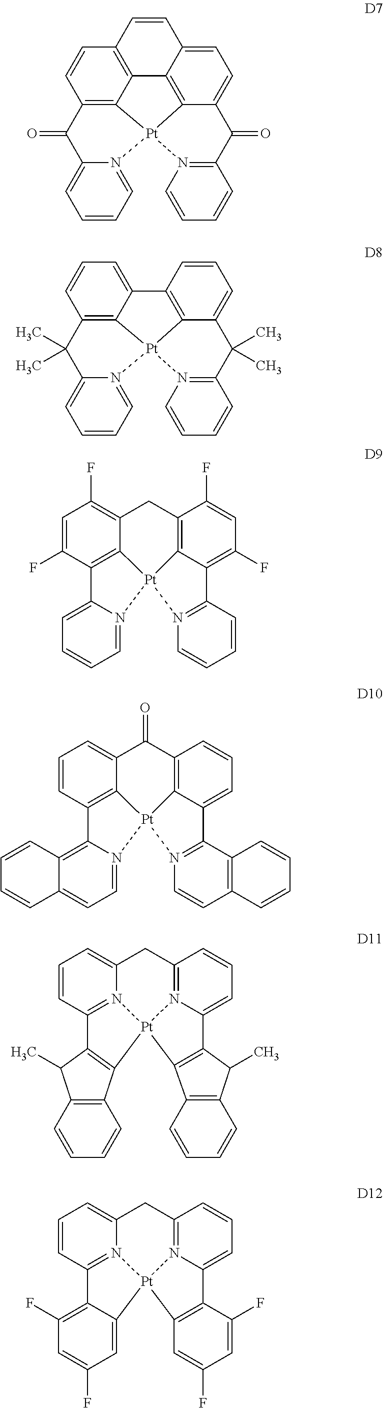

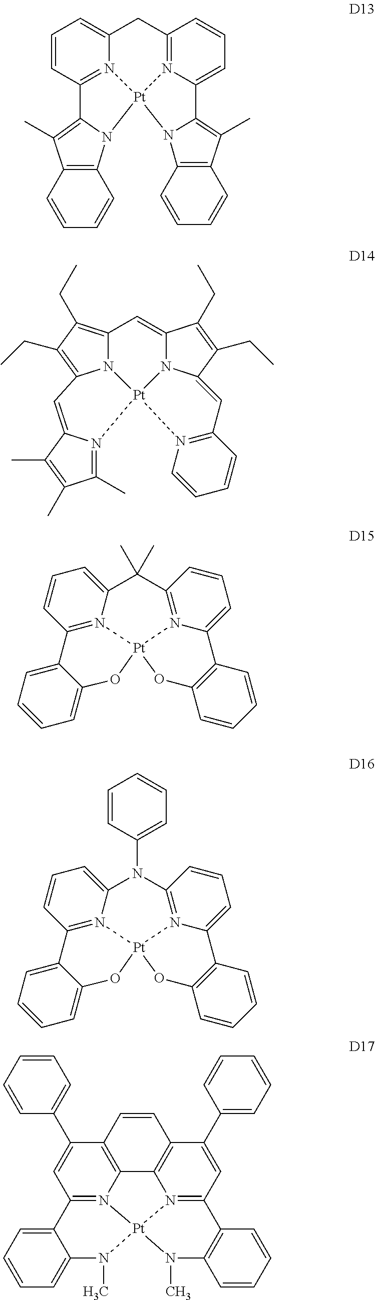

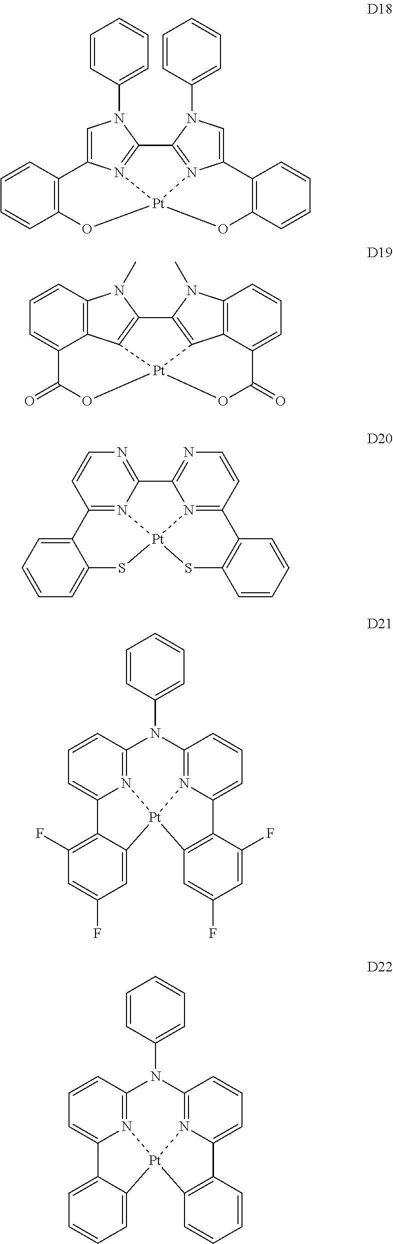

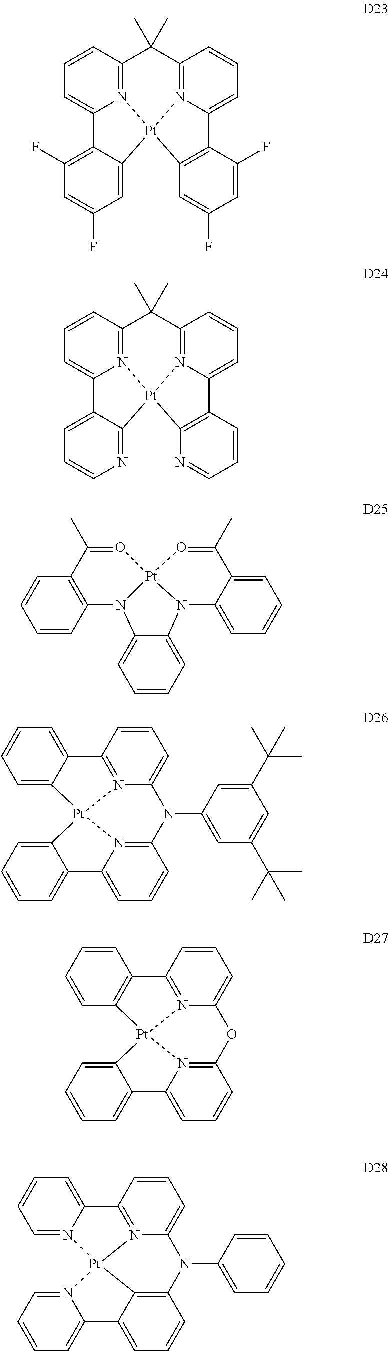

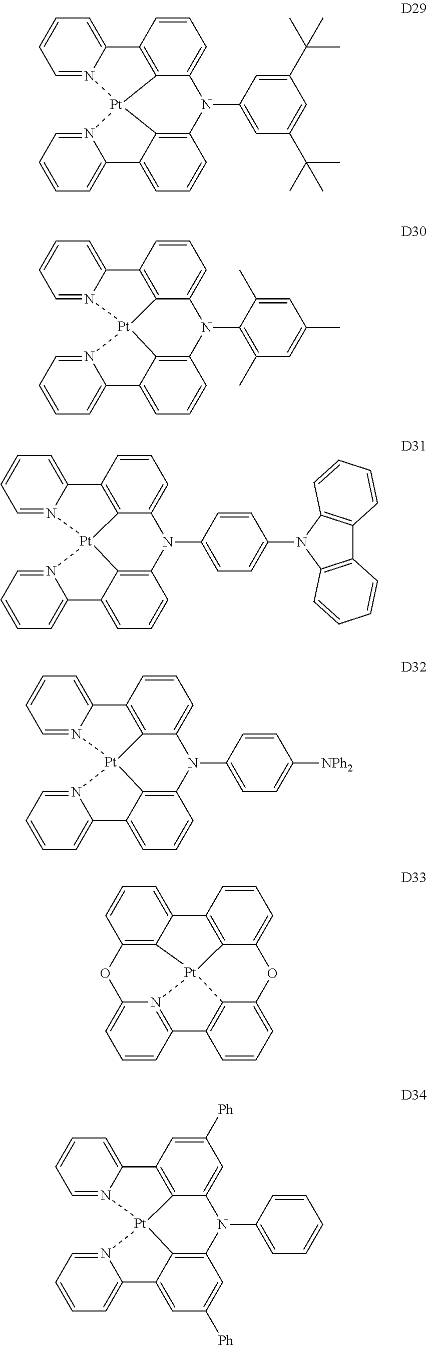

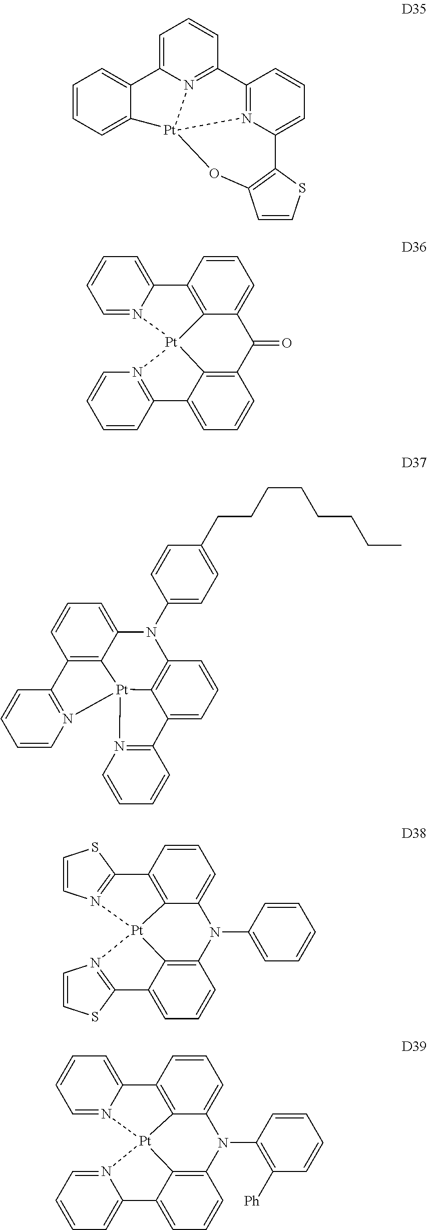

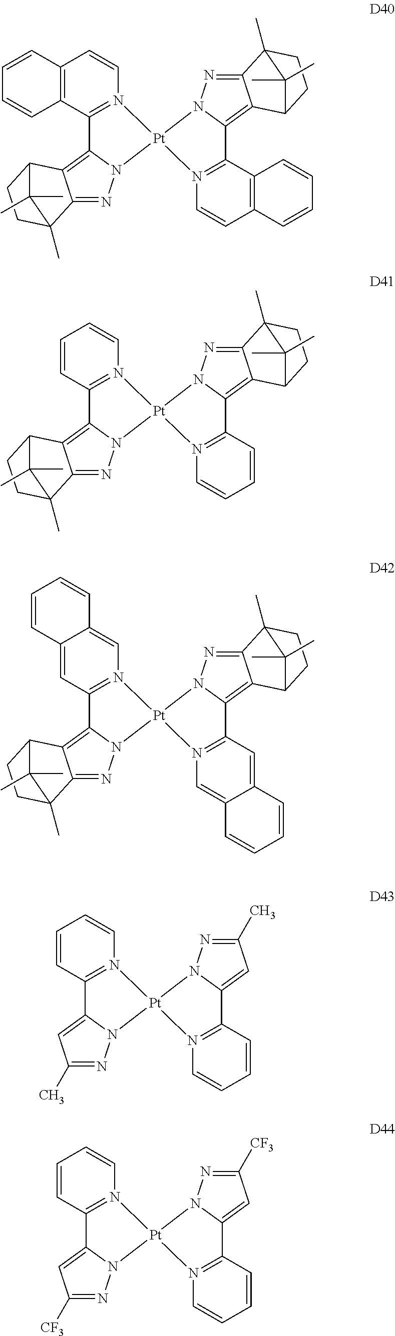

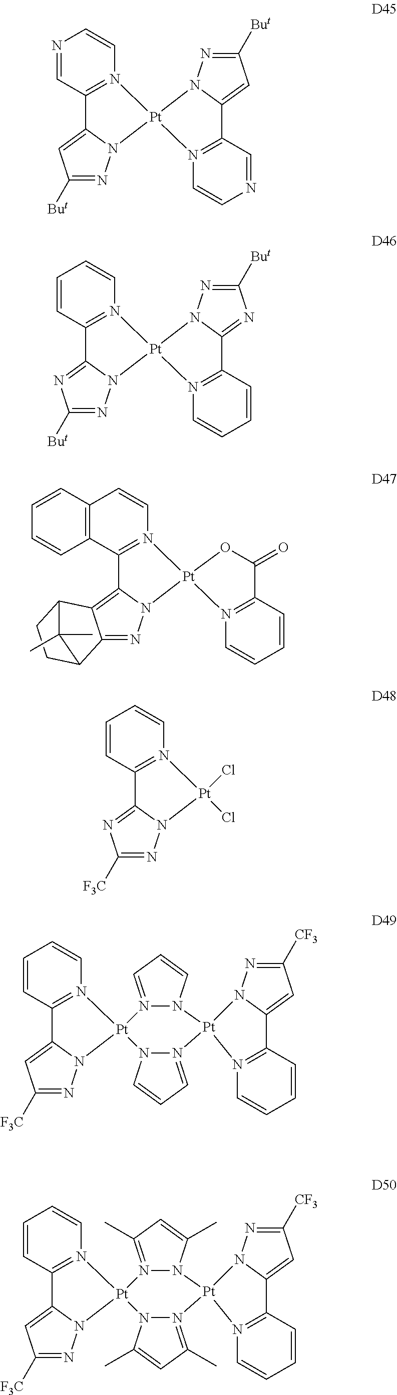

Also, the dopant available for use in the emission layer may be an Os-complex described below, but is not limited thereto:

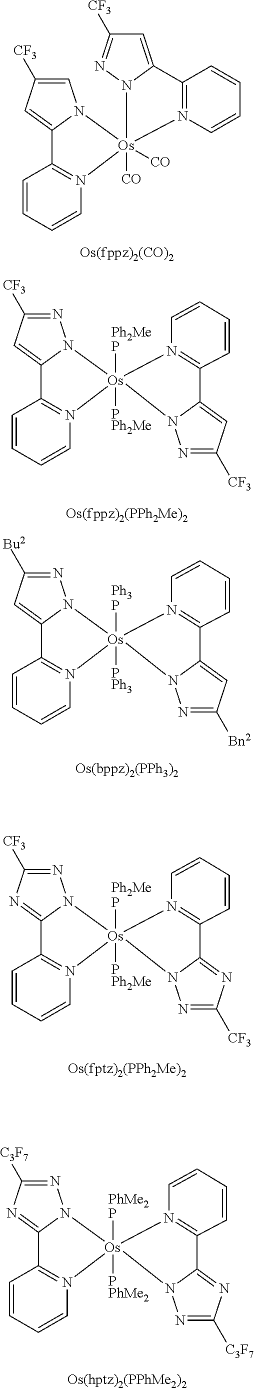

When the emission layer includes a host and a dopant, an amount of the dopant may be in a range of about 0.01 to about 15 parts by weight based on 100 parts by weight of the host, but is not limited thereto.

In some embodiments, a thickness of the emission layer may be in a range of about 100 Å to about 1,000 Å, for example, about 200 Å to about 600 Å. When the thickness of the emission layer is within this range, excellent light-emission characteristics may be obtained without a substantial increase in driving voltage.

Next, an electron transport layer (ETL) is formed on the emission layer by using various methods, for example, by vacuum deposition, spin coating, casting, or the like. When the electron transport layer is formed using vacuum deposition or spin coating, the deposition and coating conditions may be similar to those for the formation of the hole injection layer, though the conditions for deposition and coating may vary according to the material that is used to form the electron transport layer.

A material for forming the electron transport layer may stably transport electrons injected from an electron injection electrode (cathode), and may be a known electron transportation material. Examples of known electron transport materials are a quinoline derivative, such as tris(8-quinolinolate)aluminum (Alq3), TAZ, Balq, beryllium bis(benzoquinolin-10-olate) (Bebq₂), ADN, Compound 201, and Compound 202, but are not limited thereto.

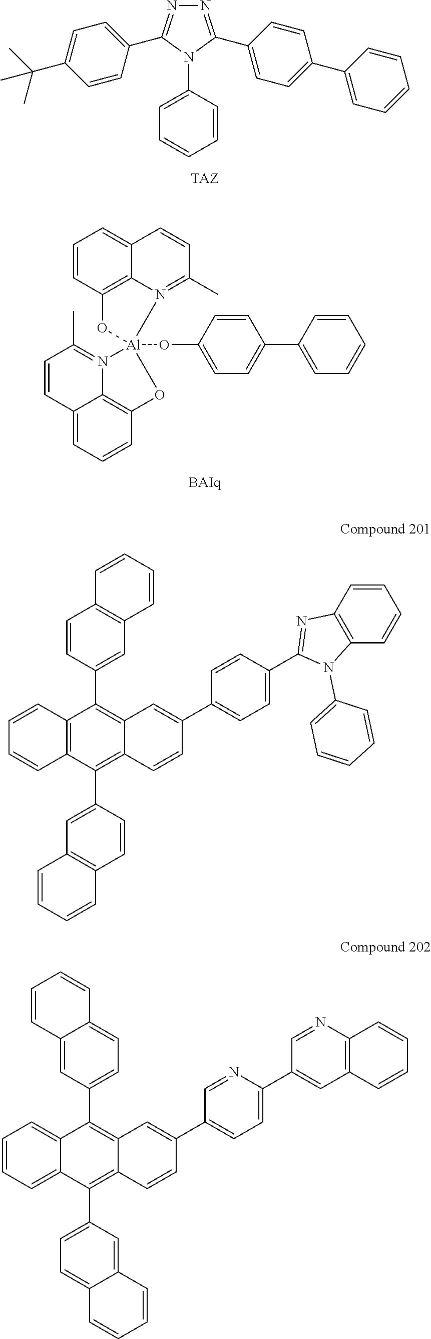

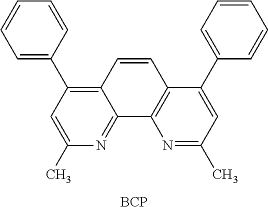 [SMILES: Cc1cc(-c2ccccc2)c2ccc3c(-c4ccccc4)cc(C)nc3c2n1 ; "BCP"]

In some embodiments, a thickness of the electron transport layer may be in a range of about 100 Å to about 1,000 Å, for example, about 150 Å to about 500 Å. When the thickness of the electron transport layer is within the range described above, the electron transport layer may have satisfactory electron transport characteristics without a substantial increase in driving voltage.

Also, the electron transport layer may include, in addition to an electron transport organic compound, a metal-containing material.

In some embodiments, the metal-containing material may include a Li complex. Non-limiting examples of the Li complex are lithium quinolate (LiQ) and Compound 203:

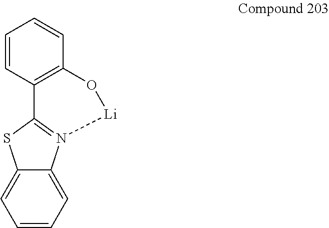

Then, an electron injection layer (EIL), which facilitates injection of electrons from the cathode, may be formed on the electron transport layer. Any suitable electron injection material may be used to form the electron injection layer.

Non-limiting examples of electron injection materials are LiF, NaCl, CsF, Li₂O, and BaO, which are known in the art. The deposition conditions of the electron injection layer may be similar to those used to form the hole injection layer, although the deposition conditions may vary according to the material that is used to form the electron injection layer.

In some embodiments, a thickness of the electron injection layer may be in a range of about 1 Å to about 100 Å, for example, about 3 Å to about 90 Å. When the thickness of the electron injection layer is within the range described above, the electron injection layer may have satisfactory electron injection characteristics without a substantial increase in driving voltage.

In some embodiments, a second electrode is disposed on the organic layer. In some embodiments, the second electrode may be a cathode that is an electron injection electrode, and in this regard, a metal for forming the second electrode may be a material having a low work function, and such a material may be metal, alloy, an electrically conductive compound, or a mixture thereof. For example, lithium (Li), magnesium (Mg), aluminum (Al), aluminum-lithium (Al—Li), calcium (Ca), magnesium-indium (Mg—In), or magnesium-silver (Mg—Ag) may be formed as a thin film to obtain a transmissive electrode. Also, to manufacture a top emission type light-emitting device, a transmissive electrode formed using ITO or IZO may be formed.

Hereinbefore, the organic light-emitting device has been described with reference to FIG. 1, but is not limited thereto.

In addition, when a phosphorescent dopant is used in the emission layer, a triplet exciton or a hole may diffuse to the electron transport layer. To prevent the diffusion, a hole blocking layer (HBL) may be formed between the hole transport layer and the emission layer or between the H-functional layer and the emission layer by vacuum deposition, spin coating, casting, LB deposition, or the like. When the hole blocking layer is formed by vacuum deposition or spin coating, the deposition or coating conditions may be similar to those applied to form the hole injection layer, although the deposition or coating conditions may vary according to the material that is used to form the hole blocking layer. A hole blocking material may be any one of known hole blocking materials, and examples thereof are an oxadiazole derivative, a triazole derivative, a phenanthroline derivative, and so on. For example, BCP illustrated below may be used as the hole-blocking material.

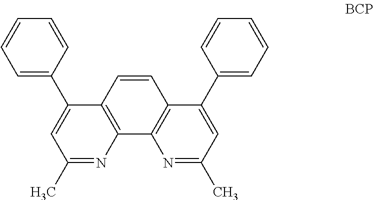 [SMILES: Cc1cc(-c2ccccc2)c2ccc3c(-c4ccccc4)cc(C)nc3c2n1]

In some embodiments, a thickness of the hole blocking layer may be in a range of about 20 Å to about 1,000 Å, for example, about 30 Å to about 300 Å. When the thickness of the hole blocking layer is within these ranges, the hole blocking layer may have excellent hole blocking characteristics without a substantial increase in driving voltage.

An organic light-emitting device according to an embodiment may be used in various flat panel display apparatuses, such as a passive matrix organic light-emitting display apparatus or an active matrix organic light-emitting display apparatus. In particular, when the organic light-emitting device is included in an active matrix organic light-emitting display apparatus, a first electrode disposed on a substrate acts as a pixel and may be electrically connected to a source electrode or a drain electrode of a thin film transistor. In addition, the organic light-emitting device may be included in a flat panel display apparatus that emits light in opposite directions.

Also, an organic layer according to an embodiment may be formed by depositing the compound according to an embodiment, or may be formed by using a wet method in which the compound according to an embodiment is prepared in the form of solution and then the solution of the compound is used for coating.

Hereinafter, an organic light-emitting device according to an embodiment is described in detail with reference to Synthesis Example and Examples. However, the organic light-emitting device is not limited thereto.

### EXAMPLE

### Representative Synthesis Example

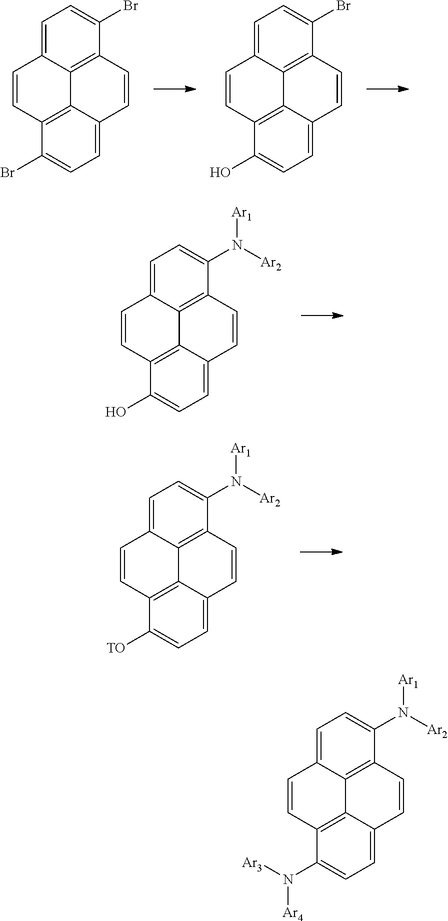

An unsubstituted pyrene-diamine, which is an example of the compound of Formula 1, as in Representative Reaction Scheme illustrated above, may be synthesized by using 1,6-dibromopyrene. One bromine of 1,6-dibromopyrene is replaced with hydroxyl to give 6-bromopyren-1-ol. Subsequently, amination is performed on 6-bromopyren-1-ol by using a palladium catalyst, and then, a triflate was formed, and then, amination is performed thereon once more, thereby producing the desired diamino compound.

Also, 3,8-the substituted asymmetric 1,6-pyrenediamine may be synthesized according to Reaction Scheme below.

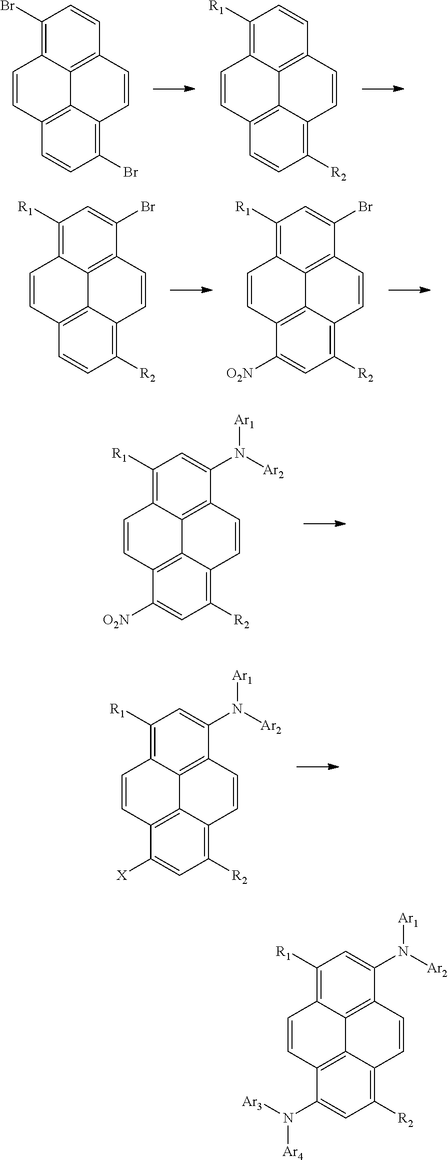

Hereinafter, Synthesis Examples for the preparation of some of compounds according to an embodiment will be provided, and these examples may be used to synthesize compounds represented by Formula 1.

### Synthesis Example 1

### Synthesis of Compound 1

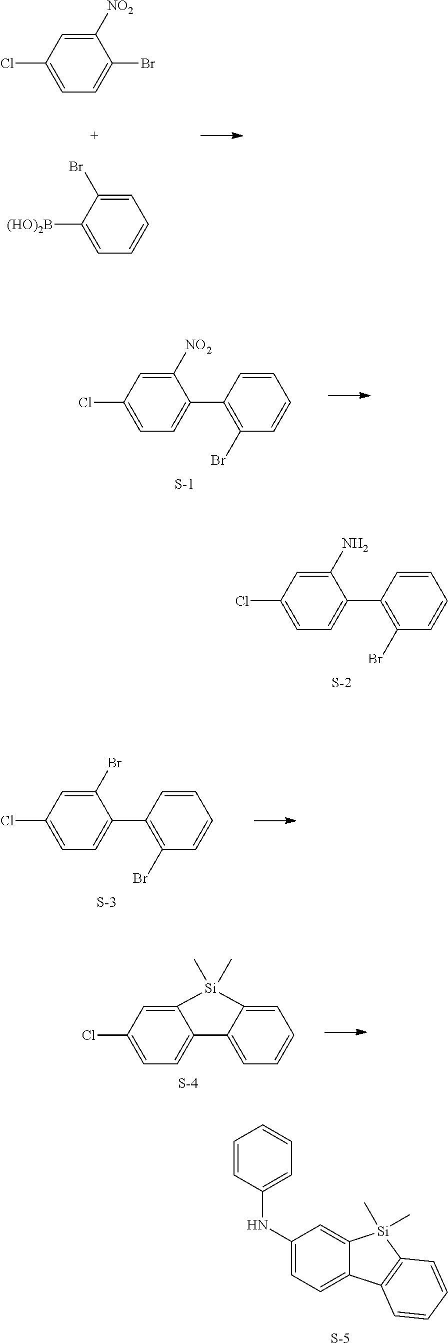

### Synthesis of Intermediate S-1

11.3 g (48.0 mmol) of 1-bromo-4-chloro-2-nitrobenzene, 8.0 g (40 mmol) of 2-bromophenylboronic acid, 2.3 g (2.0 mmol) of Pd(PPh₃)₄, and 16.6 g (120.0 mmol) of K₂CO₃ were dissolved in 100 mL of THF/H₂O (2/1) mixed solution, and then, the resultant solution was stirred at a temperature of 80° C. for 5 hours. The solution was cooled to room temperature, and then, 60 mL of water was added thereto, and an extraction process was performed thereon three times with 60 mL of diethylether. The combined organic layer was dried by using magnesium sulfate, and then the solvent was removed to give a residue. The residue was purified by silica gel column chromatography to obtain 9.1 g (yield of 72%) of Intermediate S-1. LC-MS. C₁₂H₇BrClNO₂: M+1 311.8.

### Synthesis of Intermediate S-2

9.0 g (28.8 mmol) of Intermediate S-1 was dissolved in 60 mL a toluene/EtOH (2/1) solution, and then, 27.0 g (120.0 mmol) of SnCl₂.2H₂O dissolved in 30 mL of 1N HCl was slowly added thereto, and then, the result mixture was refluxed for 8 hours while heating. The mixture was cooled to room temperature, and then, placed in 100 mL of ice water, and then, a pH of the mixture was adjusted with a NaOH aqueous solution to be in a range of pH 8 to 9, and extracted three times with diethylether. The combined organic layer was dried using magnesium sulfate, and then the solvent was removed to give a residue. The residue was purified by silica gel column chromatography to obtain 6.6 g (yield of 82%) of Intermediate S-2. LC-MS. C₁₂H₉BrClN: M+1 282.0.

### Synthesis of Intermediate S-3

6.2 g (22.0 mmol) of Intermediate S-2 and 3.0 g (22.0 mmol) of NaNO₂ were dissolved in 50 mL of a 1N HCl/CH₃CN (10/1) mixed solution, and then, the mixture was stirred at a temperature of 0° C. for 30 minutes. The solution was added to 9.5 g (80.0 mmol) of KBr dissolved in 30 mL of H₂O, and then, stirred at room temperature for 3 hours. 30 mL of 10% Na₂S₂O₃ aqueous solution was added to the reaction solution and then, extracted three times with 60 mL of diethylether. The combined organic layer was dried by using magnesium sulfate, and then the solvent was removed to give a residue. The residue was purified by silica gel column chromatography to obtain 6.4 g (yield of 89%) of Intermediate S-3. LC-MS. C₁₂H₇Br₂Cl: M+1 344.9.

### Synthesis of Intermediate S-4

6.02 g (17.4 mmol) of Intermediate S-3 was dissolved in 50 mL of THF, and then, the mixture was cooled to −78° C., and 14.0 mL (2.5M in hexane) of n-BuLi was slowly added thereto, and the resultant mixture was stirred at the same temperature for 2 hours. 2.1 mL (17.4 mmol) of dichlorodimethylsilane was slowly added to the mixture, and then stirred at the same temperature for 30 minutes, and then, stirred at room temperature for 3 hours. 40 mL of distilled water was added to the mixture, and then, the result was extracted three times with 40 mL of diethylether. The combined organic layer was dried using magnesium sulfate, and then the solvent was removed to give a residue. The residue was purified by silica gel column chromatography to obtain 2.6 g (yield of 59%) of Intermediate S-4. LC-MS. C₁₄H₁₃ClSi: M+1 245.0.

### Synthesis of Intermediate S-5

2.45 g (10.0 mmol) of Intermediate S-4, 1.4 g (15.0 mmol) of aniline, 0.18 g (0.2 mmol) of Pd₂(dba)₃, 0.04 g (0.2 mmol) of PtBu₃, and 1.9 g (20.0 mmol) of NaOtBu were dissolved in 30 mL of toluene, and then, the mixture was stirred at a temperature of 85° C. for 4 hours. The solution was cooled to room temperature, and then extracted three times with 30 mL of water and 30 mL of diethylether. The combined organic layer was dried by using magnesium sulfate, and then the solvent was removed to give a residue. The residue was purified by silica gel column chromatography to obtain 2.7 g (yield of 91%) of Intermediate S-5. LC-MS. C₂₀H₁₉NSi: M+1 302.1.

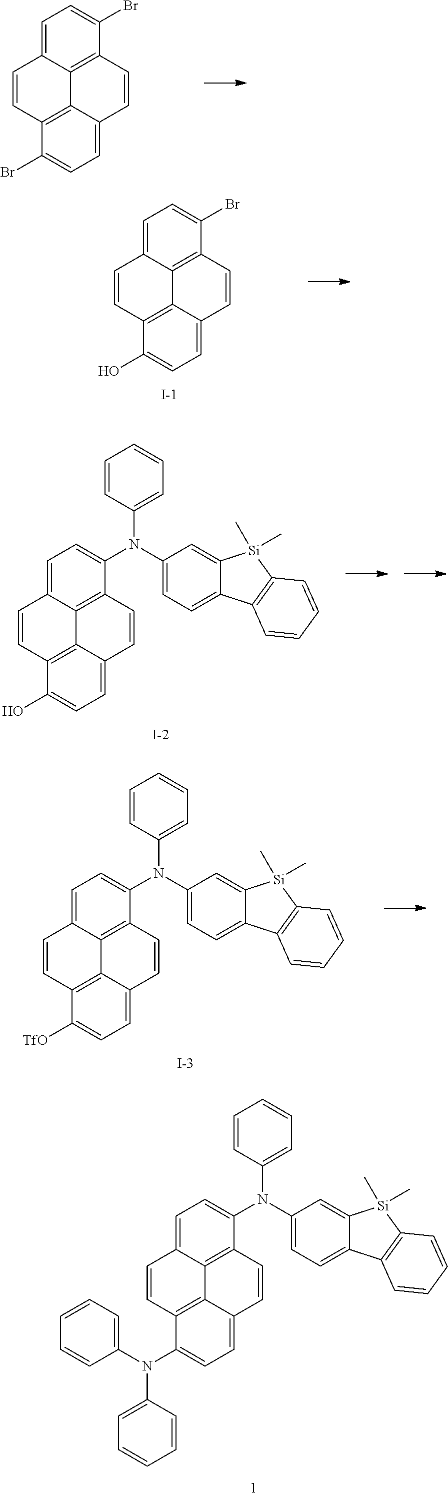

### Synthesis of Intermediate I-1

3.6 g (20.0 mmol) of 1,6-dibromopyrene, 0.38 g (2.0 mmol) of CuI, and 6.7 g (120.0 mmol) of KOH were dissolved in 100 mL of toluene/PEG400/H₂O (5/4/1) and stirred under a nitrogen atmosphere, and then heated at 110° C. and stirred for 8 hours. The solution was cooled to room temperature, and then, 10 mL of 1N HCl was added thereto, and a pH of the resulting solution was adjusted to be in a range of 2 to 3, and then the mixture was extracted three times with 60 mL of ethylacetate. The combined organic layer was dried by using magnesium sulfate, and then the solvent was removed to give a residue. The residue was purified by silica gel column chromatography to obtain 3.8 g (yield of 64%) of Intermediate I-1. LC-MS. C₁₆H₉BrO: M+1 297.0.

### Synthesis of Intermediate I-2

2.97 g (10.0 mmol) of Intermediate I-1, 3.3 g (11.0 mmol) of Intermediate S-5, 0.18 g (0.2 mmol) of Pd₂(dba)₃, 0.04 g (0.2 mmol) of PtBu₃, and 1.9 g (20.0 mmol) of NaOtBu were dissolved in 30 mL of toluene, and then, the mixture was stirred at 85° C. for 4 hours. The solution was cooled to room temperature, and then extracted three times with 30 mL of water and 30 mL of diethylether. The combined organic layer was dried by using magnesium sulfate, and then the solvent was removed to give a residue. The residue was purified by silica gel column chromatography to obtain 4.6 g (yield of 89%) of Intermediate I-2. LC-MS. C₃₆H₂₇NOSi: M+1 518.2

### Synthesis of Intermediate I-3

4.6 g (8.9 mmol) of Intermediate I-2 and 1 g (15.0 mmol) of pyridine were dissolved in 20 mL of dichloromethane, and then, 3.0 g (10. 7 mmol) of triflic anhydride was slowly added thereto at a temperature of 0° C. Then, the temperature was increased to room temperature and the result mixture was stirred for 2 hours. 20 mL of water was added to the mixture and then, extracted three times with 20 mL of dichloromethane. The combined organic layer was dried by using magnesium sulfate, and then the solvent was removed to give a residue. The residue was purified by silica gel column chromatography to obtain 5.4 g (yield of 93%) of Intermediate I-3. LC-MS. C₃₇H₂₆NO₃SSi: M+1 650.1.

### Synthesis of Compound 1

5.4 g (8.3 mmol) of Intermediate I-3, 1.55 g (9.14 mmol) of diphenylamine, 0.15 g (0.17 mmol) of Pd₂(dba)₃, 0.03 g (0.17 mmol) of PtBu₃, and 1.2 g (12.5 mmol) of NaOtBu were dissolved in 30 mL of toluene, and then, the mixture was stirred at a temperature of 85° C. for 4 hours. The solution was cooled to room temperature, and then extracted three times with 30 mL of water and 30 mL of diethylether. The combined organic layer was dried by using magnesium sulfate, and then the solvent was removed to give a residue. The residue was purified by silica gel column chromatography to obtain 4.7 g (yield of 84%) of Compound 1. LC-MS C₄₈H₃₆N₂Si: M+1 669.3.

¹H NMR (400 MHz, CDCl₃) 7.90-7.87 (m, 2H), 7.77 (d, 1H), 7.65 (d, 1H), 7.57-7.45 (m, 6H), 7.39-7.35 (m, 2H), 7.31-7.27 (m, 1H), 7.17-7.06 (m, 8H), 7.02-6.98 (m, 3H), 6.83-6.78 (m, 6H), 0.4 (s, 6H).

### Synthesis Example 2

### Synthesis of Compound 54

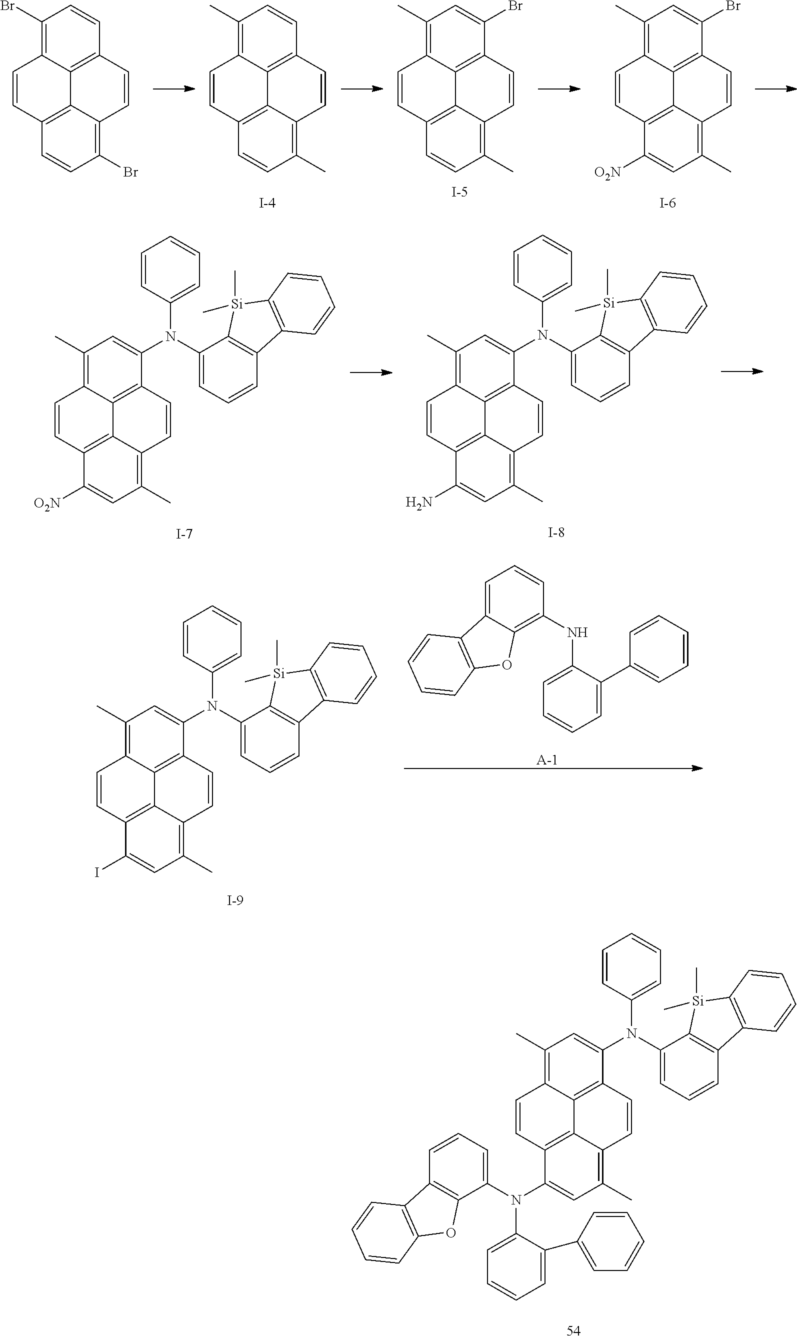

### Synthesis of Intermediate I-4

7.2 g (20.0 mmol) of 1,6-dibromopyrene was dissolved in 60 mL of THF, and then, the mixture was cooled to −78° C., and 48.0 mL (2.5M in hexane) of n-BuLi was slowly added thereto, and the resultant mixture was heated up to −30° C. and stirred. One hour after the stirring, the solution was cooled to −78° C. and then, 7.5 mL of iodomethane was slowly added thereto, and the result mixture was stirred at room temperature for 4 hours. 60 mL of distilled water was added to the reaction solution, and then, the result was extracted three times with 60 mL of diethylether. The combined organic layer was dried by using magnesium sulfate, and then the solvent was removed to give a residue. The residue was purified by silica gel column chromatography to obtain 2.99 g (yield of 65%) of Intermediate I-4. LC-MS. C₁₈H₁₄: M+1 231.1.

### Synthesis of Intermediate I-5

2.9 g (12.6 mmol) of Intermediate I-4 was dissolved in 30 mL of diethylether/methanol (2.5/1) mixed solution, and then, 3.8 mL (33 wt % in AcOH) of HBr was slowly added thereto at 0° C., and then, the result mixture was stirred for 30 minutes. 1.73 mL of hydrogen peroxide (30 wt % in H₂O) was slowly added to the mixture at 0° C., and then, stirred at room temperature for 8 hours. Subsequently, 30 mL of distilled water was added to the mixture, and then, the result mixture was extracted three time with 30 mL of diethylether. The combined organic layer was dried by using magnesium sulfate, and then the solvent was removed to give a residue. The residue was purified by silica gel column chromatography to obtain 3.58 g (yield of 92%) of Intermediate I-5. LC-MS. C₁₈H₁₃Br: M+1 309.0.

### Synthesis of Intermediate I-6

3.5 g (11.3 mmol) of Intermediate I-5 was dissolved in 30 mL of dichloromethane, and then, 0.85 g (12.4 mmol) NaNO₂ dissolved in 10 mL of trifluoroacetic acid was slowly added thereto at a temperature of 0° C., and the result mixture was stirred for 30 minutes. 10 mL of triethylamine was added to the mixture, and the obtained solid was collected by filteration and 40 mL of distilled water was added thereto, and the result aqueous mixture was extracted three times with 30 mL of dichloromethane. The combined organic layer was dried using magnesium sulfate, and then the solvent was removed to give a residue. The residue was purified by silica gel column chromatography to obtain 2.88 g (yield of 72%) of Intermediate I-6. LC-MS. C₁₈H₁₂BrNO₂: M+1 354.0.

### Synthesis of Intermediate I-7

2.86 g (8.1 mmol) of Intermediate I-6, 2.93 g (9.72 mmol) of Intermediate S-5, 0.15 g (0.17 mmol) of Pd₂(dba)₃, 0.03 g (0.17 mmol) of PtBu₃, and 1.2 g (12.5 mmol) of NaOtBu were dissolved in 30 mL of toluene, and then, the mixture was stirred at a temperature of 85° C. for 4 hours. The solution was cooled to room temperature, and then extracted three times with 30 mL of water and 30 mL of diethylether. The combined organic layer was dried using magnesium sulfate, and then the solvent was removed to give a residue. The residue was purified by silica gel column chromatography to obtain 3.4 g (yield of 73%) of Intermediate I-7. LC-MS. C₃₈H₃₀N₂O₂Si: M+1 575.2.

### Synthesis of Intermediate I-8

3.4 g (5.91 mmol) of Intermediate I-7 was dissolved in 20 mL of dichloromethane/methanol (1/1) mixed solution, and then, 0.5 g of Pd/C was added thereto. The mixture was placed under 1 atm of hydrogen gas and stirred for 3 hours. The hydrogen gas was replaced and the solid removed by filtration using celite. The solvent was removed to give a residue. The residue was purified by silica gel column chromatography to obtain 2.96 g (yield of 92%) of Intermediate I-8. LC-MS. C₃₈H₃₂N₂Si: M+1 545.2.

### Synthesis of Intermediate I-9

2.9 g (5.32 mmol) of Intermediate I-8 was dissolved in 15 mL of acetonitrile, and then, 16 mL of 1N HCl was slowly added at a temperature of 0° C. The result mixture was stirred at 0° C. for 30 minutes, and then, 0.92 g (13.3 mmol) of NaNO₂ was slowly added thereto, and then, the result mixture was stirred for 30 minutes. 8 g (48 mmol) of KI was added to the mixture, and then, stirred for 2 hours. 20 mL of saturated NaHCO₃ solution was added mixture, and then, the result mixture was extracted three times with 30 mL of ethylacetate. The combined organic layer was dried by using magnesium sulfate, and then the solvent was removed to give a residue. The residue was purified by silica gel column chromatography to obtain 2.02 g (yield of 58%) of Intermediate I-7. LC-MS. C₃₈H₃₀INSi: M+1 656.1.

### Synthesis of Compound 54

2.0 g (3.05 mmol) of Intermediate I-9, 1.2 g (3.6 mmol) of Intermediate A-1, 0.05 g (0.06 mmol) of Pd₂(dba)₃, 0.01 g (0.06 mmol) of PtBu₃, and 0.44 g (4.6 mmol) of NaOtBu were dissolved in 20 mL of toluene, and then, the mixture was stirred at a temperature of 85° C. for 4 hours. The solution was cooled to room temperature, and then extracted three times with 20 mL of water and 20 mL of diethylether. The combined organic layer was dried by using magnesium sulfate, and then the solvent was removed to give a residue. The residue was purified by silica gel column chromatography to obtain 2.26 g (yield of 86%) of Compound 54. LC-MS and ¹H NMR. C₆₂H₄₆N₂OSi: M+1 863.3.

¹H NMR (400 MHz, CDCl₃) δ 8.06-8.00 (m, 2H), 7.87-7.81 (m, 2H), 7.77-7.64 (m, 4H), 7.62-7.55 (m, 5H), 7.51-7.38 (m, 4H), 7.32 (dd, 1H), 7.26-7.20 (m, 2H), 7.19 (d, 1H), 7.12-6.91 (m, 8H), 6.89-6.85 (m, 2H), 6.83 (dt, 1H), 6.78-6.74 (m, 2H), 2.57 (s, 6H), 0.33 (s, 6H).

### Synthesis Example 3

### Synthesis of Compound 79

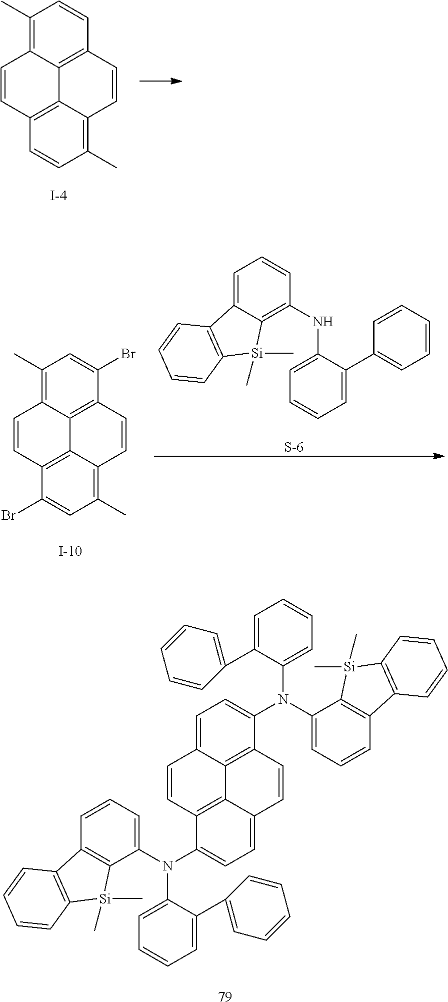

### Synthesis of Intermediate I-10

2.3 g (10.0 mmol) of Intermediate I-4 was dissolved in 30 mL of dichloromethane, and then, 4.4 g (25.0 mmol) of N-bromosuccinimide was slowly added thereto and the result was stirred for 6 hours. 30 mL of distilled water was added to the solution and then, extracted three times with 30 mL of dichloromethane. The combined organic layer was dried by using magnesium sulfate, and then the solvent was removed to give a residue. The residue was purified by silica gel column chromatography to obtain 2.95 g (yield of 76%) of Intermediate I-10. LC-MS. C₁₈H₁₂Br₂: M+1 386.9.

### Synthesis of Compound 79

2.9 g (12.5 mmol) of Intermediate I-10, 10.3 g (27.5 mmol) of Intermediate S-6, 0.55 g (0.6 mmol) of Pd₂(dba)₃, 0.12 g (0.6 mmol) of PtBu₃, and 3.6 g (37.5 mmol) of NaOtBu were dissolved in 40 mL of toluene, and then, the mixture was stirred at a temperature of 85° C. for 4 hours. The solution was cooled to room temperature, and then extracted three times with 40 mL of water and 40 mL of diethylether. The combined organic layer was dried by using magnesium sulfate, and then the solvent was removed to give a residue. The residue was purified by silica gel column chromatography to obtain 8.8 g (yield of 74%) of Compound 79. LC-MS C₆₈H₅₂N₂Si₂: M+1 953.4.

¹H NMR (400 MHz, CDCl₃) 8.02 (d, 2H), 7.80 (d, 2H), 7.67 (d, 2H), 7.60-7.55 (m, 12H), 7.51-7.42 (m, 4H), 7.34-7.12 (m, 10H), 7.02 (dd, 2H), 6.94-6.90 (m, 4H), 6.84 (d, 2H), 0.30 (s, 12H)

Similar to the procedure for Synthesis Examples for Intermediate S-5, Compound 1, and Compound 54, intermediates explained hereinafter will also be used to synthesize some compounds according to the present embodiments. However, the present embodiments are not limited to the compounds described below.

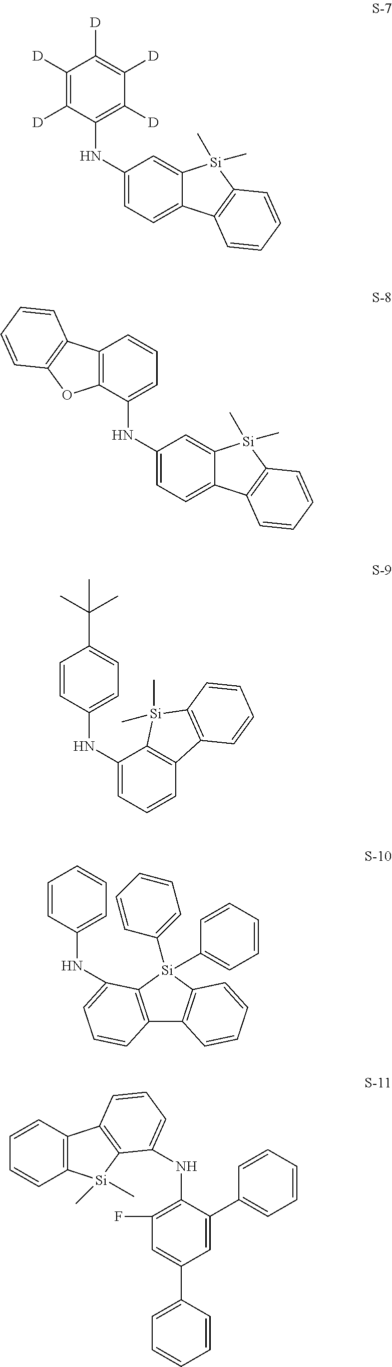 [SMILES: [2H]c1c([2H])c([2H])c(Nc2ccc3c(c2)[Si](C)(C)c2ccccc2-3)c([2H])c1[2H] ; C[Si]1(C)c2ccccc2-c2ccc(Nc3cccc4c3oc3ccccc34)cc21 ; CC(C)(C)c1ccc(Nc2cccc3c2[Si](C)(C)c2ccccc2-3)cc1 ; c1ccc(Nc2cccc3c2[Si](c2ccccc2)(c2ccccc2)c2ccccc2-3)cc1 ; C[Si]1(C)c2ccccc2-c2cccc(Nc3c(F)cc(-c4ccccc4)cc3-c3ccccc3)c21]

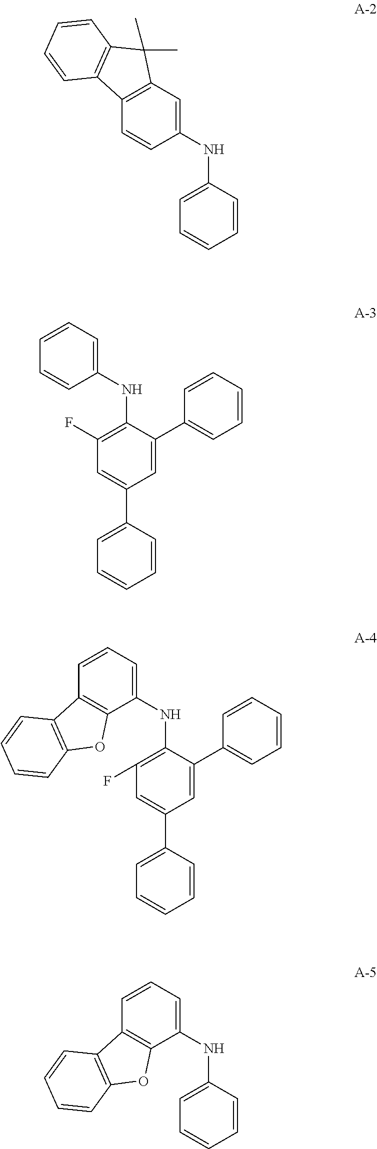 [SMILES: CC1(C)c2ccccc2-c2ccc(Nc3ccccc3)cc21 ; Fc1cc(-c2ccccc2)cc(-c2ccccc2)c1Nc1ccccc1 ; Fc1cc(-c2ccccc2)cc(-c2ccccc2)c1Nc1cccc2c1oc1ccccc12 ; c1ccc(Nc2cccc3c2oc2ccccc23)cc1]

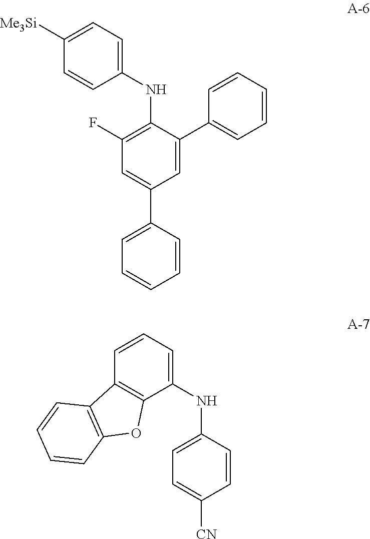

### Synthesis of Compound 6

Similar to the synthesis of Compound 1, Compound 6 was synthesized by using Intermediate I-1 and Intermediate S-7. Compound 6 LC-MS C₄₈H₃₁D₅N₂Si: M+1 674.3.

Compound 6 ¹H NMR (400 MHz, CDCl₃) δ 7.90-7.87 (m, 2H), 7.77 (d, 1H), 7.66 (d, 1H), 7.57-7.45 (m, 6H), 7.39-7.27 (m, 3H), 7.16-7.07 (m, 6H), 7.02-6.98 (m, 2H), 6.89-6.86 (m, 4H), 0.41 (s, 6H).

### Synthesis of Compound 11

Similar to the procedure for the synthesis of Compound 1, Compound 11 was synthesized by using Intermediate I-1, Intermediate S-5, and Intermediate A-2. Compound 11 LC-MS C₅₇H₄₄N₂Si: M+1 785.3

Compound 11 ¹H NMR (400 MHz, CDCl3) δ 7.89 (d, 2H), 7.79-7.75 (m, 2H), 7.66 (d, 1H), 7.57-7.42 (m, 6H), 7.39-7.27 (m, 5H), 7.19-7.06 (m, 8H), 7.02-6.96 (m, 3H), 6.92 (d, 1H), 6.86-6.82 (m, 4H), 1.61 (s, 6H), 0.40 (s, 6H)

### Synthesis of Compound 14

Similar to the procedure for the synthesis of Compound 1, Compound 14 was synthesized by using Intermediate I-1, Intermediate S-5, and Intermediate A-1. Compound 14 LC-MS C₆₀H₄₂N₂OSi: M+1 835.3.

Compound 14 ¹H NMR (400 MHz, CDCl₃) 7.95 (d, 1H), 7.90 (d, 1H), 7.83-7.76 (m, 2H), 7.70-7.64 (m, 4H), 7.60-7.35 (m, 13H), 7.31-7.27 (m, 1H), 7.19-7.02 (m, 10H), 6.97-6.93 (m, 1H), 6.85-6.81 (m, 1H), 6.78-6.75 (m, 2H), 0.41 (s, 6H).

### Synthesis of Compound 16

Similar to the procedure for the synthesis of Compound 1, Compound 16 was synthesized by using Intermediate I-1, Intermediate S-5, and Intermediate A-3. Compound 16 LC-MS C₆₀H₄₃FN₂Si: M+1 839.3.

Compound 16 ¹H NMR (400 MHz, CDCl₃) δ 7.90-7.84 (m, 2H), 7.77 (d, 1H), 7.69-7.48 (m, 15H), 7.42-7.35 (m, 3H), 7.31-7.27 (m, 2H), 7.19-7.06 (m, 8H), 7.02-6.94 (m, 2H), 6.89-6.82 (m, 4H), 0.42 (s, 6H).

### Synthesis of Compound 22

Similar to the procedure for the synthesis of Compound 1, Compound 22 was synthesized by using Intermediate I-1 and Intermediate S-8. Compound 22 LC-MS C54H₃₈N₂OSi: M+1759.3.

Compound 22 ¹H NMR (400 MHz, CDCl₃) δ 7.99 (d, 1H), 7.89-7.76 (m, 3H), 7.72-7.64 (m, 3H), 7.60-7.34 (m, 10H), 7.31-7.28 (m, 1H), 7.18-7.02 (m, 8H), 6.98-6.92 (m, 2H), 6.88-6.82 (m, 4H), 0.41 (s, 6H).

### Synthesis of Compound 24

Similar to the procedure for the synthesis of Compound 1, Compound 24 was synthesized by using Intermediate I-1, Intermediate S-5, and Intermediate A-4. Compound 24 LC-MS C₆₆H₄₅FN₂OSi: M+1 929.3.

Compound 24 ¹H NMR (400 MHz, CDCl₃) δ 7.97 (d, 1H), 7.89 (d, 1H), 7.84-7.76 (m, 3H), 7.72-7.60 (m, 9H), 7.57-7.45 (m, 8H), 7.42-7.18 (m, 8H), 7.11-7.02 (m, 5H), 6.99-6.94 (m, 1H), 6.92-6.88 (m, 1H), 6.83-6.79 (m, 2H), 0.40 (s, 6H).

### Synthesis of Compound 25

Similar to the procedure for the synthesis of Compound 54, Compound 25 was synthesized by using Intermediate I-6 and Intermediate S-5. Compound 25 LC-MS C₅₀H₄₀N₂Si: M+1 697.3.

Compound 25 ¹H NMR (400 MHz, CDCl₃) δ 8.01-7.98 (m, 2H), 7.87 (d, 2H), 7.77 (d, 1H), 7.67 (d, 1H), 7.49 (dd, 1H), 7.39-7.27 (m, 2H), 7.19-7.00 (m, 10H), 6.96-6.91 (m, 3H), 6.89-6.80 (m, 6H), 2.57 (s, 6H), 0.40 (s, 6H).

### Synthesis of Compound 29

Similar to the procedure for the synthesis of Compound 1, Compound 29 was synthesized by using Intermediate I-1, Intermediate S-5, and Intermediate A-5. Compound 29 LC-MS C₅₄H₃₈N₂OSi: M+1 759.3.

Compound 29 ¹H NMR (400 MHz, CDCl₃) δ 8.01-7.96 (m, 2H), 7.82-7.80 (m, 2H), 7.71-7.55 (m, 8H), 7.52-7.20 (m, 7H), 7.12-6.98 (m, 6H), 6.94 (d, 1H), 6.89-6.84 (m, 2H), 6.80-6.76 (m, 2H), 6.72-6.68 (m, 2H), 0.36 (s, 6H).

### Synthesis of Compound 31

Similar to the procedure for the synthesis of Compound 1, Compound 31 was synthesized by using Intermediate I-1, Intermediate S-6, and Intermediate A-1. Compound 31 LC-MS C₆₆H₄₆N₂OSi: M+1 911.3

Compound 31 ¹H NMR (400 MHz, CDCl₃) δ 8.00 (dd, 1H), 7.95 (d, 1H), 7.83-7.79 (m, 2H), 7.70-7.63 (m, 4H), 7.61-7.53 (m, 10H), 7.51-7.38 (m, 6H), 7.32 (t, 1H), 7.26-7.08 (m, 6H), 7.02-6.92 (m, 5H), 6.89-7.78 (m, 4H), 0.30 (s, 6H).

### Synthesis of Compound 42

Similar to the procedure for the synthesis of Compound 1, Compound 42 was synthesized by using Intermediate I-1, Intermediate S-5, and Intermediate A-6. Compound 42 LC-MS C₆₃H₅₁FN₂Si₂: M+1 911.4.

Compound 42 ¹H NMR (400 MHz, CDCl₃) δ 8.01 (d, 1H), 7.86-7.81 (m, 2H), 7.69-7.48 (m, 15H), 7.42-7.30 (m, 7H), 7.26-7.20 (m, 2H), 7.12-7.04 (m, 3H), 7.00 (d, 1H), 6.96-6.86 (m, 3H), 6.62-6.78 (m, 2H), 0.33 (s, 6H), 0.24 (s, 9H).

### Synthesis of Compound 44

Similar to the procedure for the synthesis of Compound 1, Compound 44 was synthesized by using Intermediate I-1, Intermediate S-9, and Intermediate A-7. Compound 44 LC-MS C₅₉H₄₅N₃OSi: M+1 840.3.

Compound 44 ¹H NMR (400 MHz, CDCl₃) δ 8.02-7.96 (m, 2H), 7.90 (d, 1H), 7.85-7.81 (m, 2H), 7.70-7.55 (m, 8H), 7.53-7.30 (m, 6H), 7.26-7.20 (m, 4H), 7.08-6.98 (m, 2H), 6.96-6.91 (m, 2H), 6.86 (d, 1H), 6.82-6.78 (m, 2H), 1.50 (s, 9H), 0.33 (s, 6H).

### Synthesis of Compound 59

Similar to the procedure for the synthesis of Compound 54, Compound 59 was synthesized by using Intermediate I-6, Intermediate S-6, and Intermediate A-1. Compound 59 LC-MS C₆₈H₅₀N₂OSi: M+1 939.4.

Compound 59 ¹H NMR (400 MHz, CDCl₃) δ 8.07-8.00 (m, 2H), 7.86-7.74 (m, 4H), 7.70-7.64 (m, 2H), 7.62-7.38 (m, 14), 7.34-7.02 (m, 13H), 6.97-6.91 (m, 2H), 6.87-6.83 (m, 1H), 2.57 (s, 6H), 0.30 (s, 6H).

### Synthesis of Compound 63

Similar to the procedure for the synthesis of Compound 1, Compound 63 was synthesized by using Intermediate I-1, Intermediate S-10, and Intermediate A-5. Compound 63 LC-MS C₆₄H₄₂N₂OSi: M+1 883.3.

Compound 63 ¹H NMR (400 MHz, CDCl₃) δ 7.98-7.92 (m, 2H), 7.83-7.77 (m, 3H), 7.72-7.38 (m, 13H), 7.32-7.10 (m, 11H), 7.06-6.88 (m, 6H), 6.86-6.76 (m, 3H), 6.72-6.66 (m, 4H).

### Synthesis of Compound 82

Similar to the procedure for the synthesis of Compound 1, Compound 82 was synthesized by using Intermediate I-1, Intermediate S-5, and Intermediate S-11. Compound 82 LC-MS C₆₈H₅₁FN₂Si₂: M+1 971.4.

Compound 82 ¹H NMR (400 MHz, CDCl₃) δ 8.01 (d, 2H), 7.83-7.79 (m, 2H), 7.72-7.47 (m, 17H), 7.42-7.20 (m, 10H), 7.13-7.08 (m, 2H), 7.03-6.94 (m, 3H), 6.92-6.86 (m, 1H), 6.82-6.76 (m, 2H), 0.33 (s, 6H), 0.24 (s, 6H).

### Synthesis Example 4

### Synthesis of Compound H-9

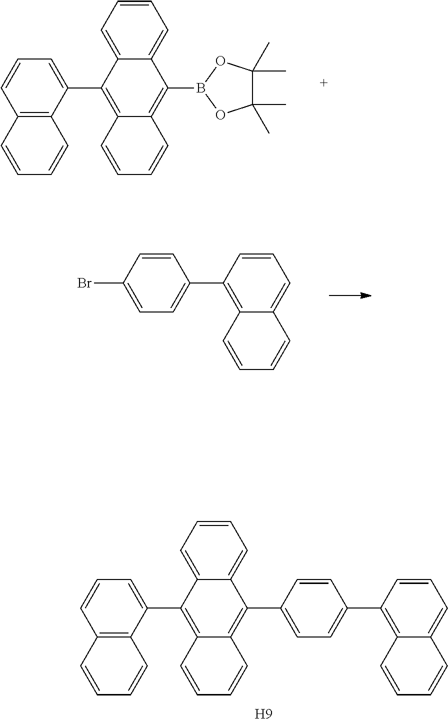

4.3 g (10.0 mmol) of 10-(1-naphthyl)anthracene-9-pinacolborate, 3.1 g (11.0 mmol) of 1-(4-bromophenyl)naphthalene, 0.58 g (0.5 mmol) of Pd(PPh₃)₄, and 4.1 g (30.0 mmol) of K₂CO₃ were dissolved in 40 mL of THF/H₂O (2/1) mixed solution, and then, the mixture was stirred at 80° C. for 5 hours. The solution was cooled to room temperature, and then, 40 mL of water was added thereto, and an extraction process was performed thereon three times with 40 mL of diethylether. The combined organic layer was dried by using magnesium sulfate, and then the solvent was removed to give a residue. The residue was purified by silica gel column chromatography to obtain 4.3 g (yield of 84%) of Compound H-9. Compound H-9 LC-MS C₄₀H₂₆: M+1 507.2.

Compound H-9 ¹H NMR δ (400 MHz, CDCl₃) 8.26 (d, 1H), 8.07 (d, H), 8.04-7.93 (m, 7H), 7.87 (d, 2H), 7.74-7.70 (m, 2H), 7.67 (dd, 1H), 7.61-7.49 (m, 4H), 7.47 (d, 2H), 7.38-7.34 (m, 2H), 7.27-7.19 (m, 4H).

### Synthesis of Compound H-45

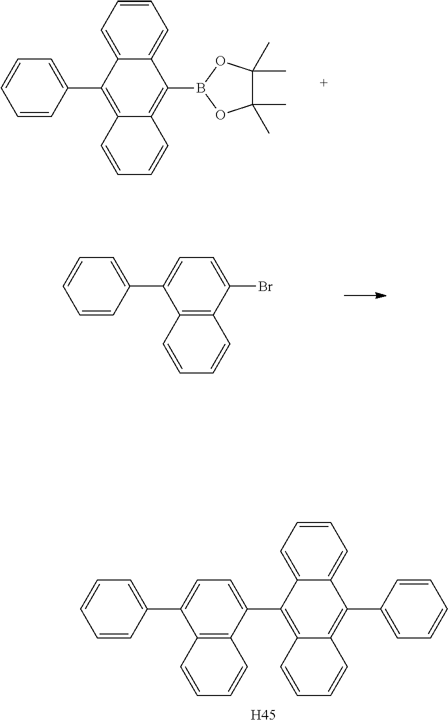

In the same manner as used to synthesize Compound H-9, Compound H-45 was obtained in the yield of 86% by using 10-(phenyl)anthracene-9-pinacolborate and 1-bromo-4-phenylnaphthalene illustrated immediately above. Compound H-45 LC-MS C₃₆H₂₄: M+1 457.2.

Compound H-45 ¹H NMR (400 MHz, CDCl₃) δ 8.08 (d, 1H), 7.75 (d, 2H), 7.68 (d, 2H), 7.65-7.52 (m, 11H), 7.42 (dt, 1H), 7.40 (dt, 1H), 7.31 (dd, 2H), 7.24-7.20 (m, 4).

### Synthesis of Compound H-60

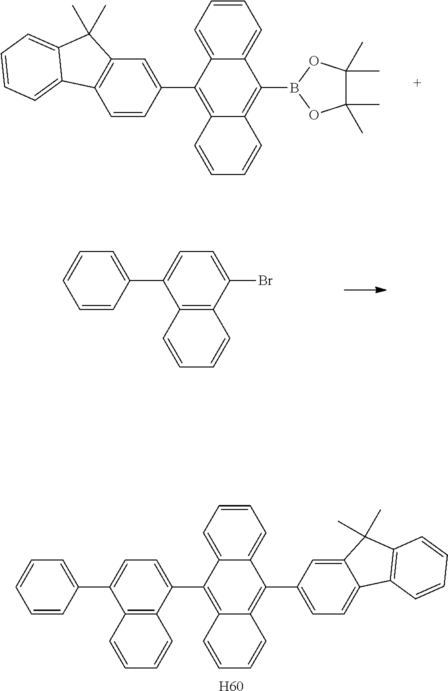

In the same manner as used to synthesize Compound H-9, Compound H-60 was obtained in the yield of 81% by using 10-(9,9-dimethyl-9H-fluoren-2-yl)anthracene-9-pinacolborate and 1-bromo-4-phenylnaphthalene illustrated immediately above. Compound H-60 LC-MS C₄₅H₃₂: M+1 573.3.

Compound H-60 ¹H NMR (400 MHz, CDCl₃) δ 8.05 (d, 2H), 7.76-7.55 (m, 12H), 7.45 (dt, 2H), 7.39-7.28 (m, 6H), 7.26-7.18 (m, 4H), 1.66 (s, 6H).

### Example 1

An anode was prepared by cutting a Corning 15 Ωcm² (1200 Å) ITO glass substrate to a size of 50 mm×50 mm×0.7 mm, ultrasonically cleaning the glass substrate by using isopropyl alcohol and pure water for 5 minutes each, and then irradiating UV light for 30 minutes thereto and exposing to ozone to clean. Then, the anode was loaded into a vacuum deposition apparatus.

4,4′-bis[N-phenyl-N-(9-phenylcarbazol-3-yl)amino]-1,1′-biphenyl (Compound 301), which is a known material, was vacuum deposited on the anode to form a hole injection layer having a thickness of 600 Å, and then, N-[1,1′-biphenyl]-4-yl-9,9-dimethyl-N-[4-(9-phenyl-9H-carbazol-3-yl)phenyl]-9H-fluoren-2-amine (Compound 311), which is a known hole transport compound, was vacuum deposited thereon to form a hole transport layer having a thickness of 300 Å.

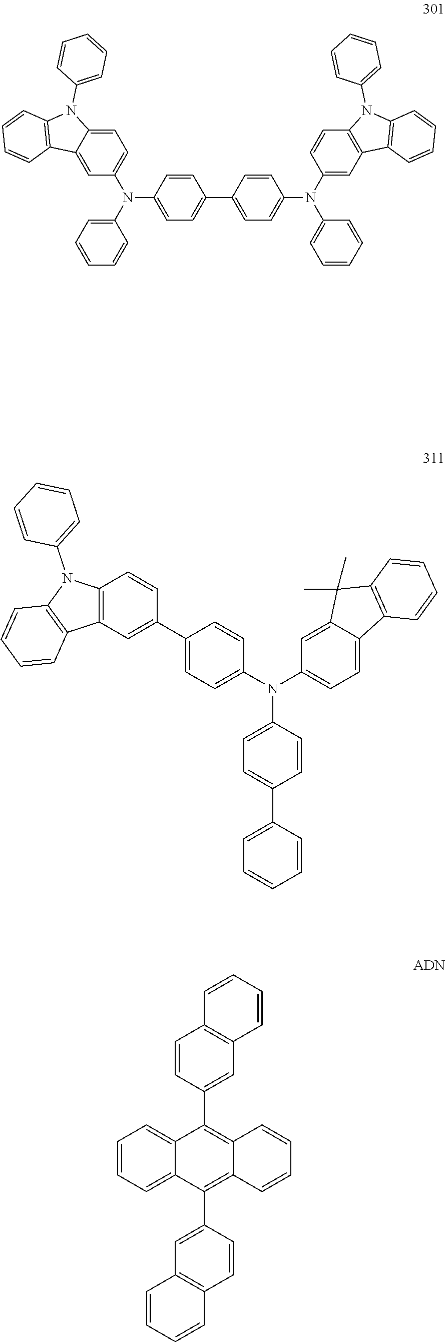

In some embodiments, 9,10-di-naphthalene-2-yl-anthracene (ADN), which is a known blue fluorescent host, and Compound 14, which was used as a blue fluorescent dopant, were co-deposited on the hole transport layer at a weight ratio of 98:2 to form an emission layer having a thickness of 300 Å.

Subsequently, Alq3 was deposited on the emission layer to form an electron transport layer having a thickness of 300 Å, and then, LiF, which is a halogenated metal, was deposited on the electron transport layer to form an electron injection layer having a thickness of 10 Å, and Al was vacuum deposited to form a cathode having a thickness of 3000 Å, thereby completing manufacturing of an organic light-emitting device.

### Example 2

An organic light-emitting device was manufactured in the same manner as in Example 1, except that in forming the emission layer, Compound 24 was used instead of Compound 14.

### Example 3

An organic light-emitting device was manufactured in the same manner as in Example 1, except that in forming the emission layer, Compound 29 was used instead of Compound 14.

### Example 4

An organic light-emitting device was manufactured in the same manner as in Example 1, except that in forming the emission layer, Compound 31 was used instead of Compound 14.

### Example 5

An organic light-emitting device was manufactured in the same manner as in Example 1, except that in forming the emission layer, Compound 42 was used instead of Compound 14.

### Example 6

An organic light-emitting device was manufactured in the same manner as in Example 1, except that in forming the emission layer, Compound 54 was used instead of Compound 14.

### Example 7

An organic light-emitting device was manufactured in the same manner as in Example 1, except that in forming the emission layer, Compound 59 was used instead of Compound 14.

### Example 8

An organic light-emitting device was manufactured in the same manner as in Example 1, except that in forming the emission layer, Compound 79 was used instead of Compound 14.

### Example 9

An organic light-emitting device was manufactured in the same manner as in Example 1, except that in forming the emission layer, Compound 82 was used instead of Compound 14.

### Comparative Example 1

An organic light-emitting device was manufactured in the same manner as in Example 1, except that in forming the emission layer, N,N,N′,N′-tetraphenyl-pyrene-1,6-diamine (TPD), which is a known compound, was used as a dopant.

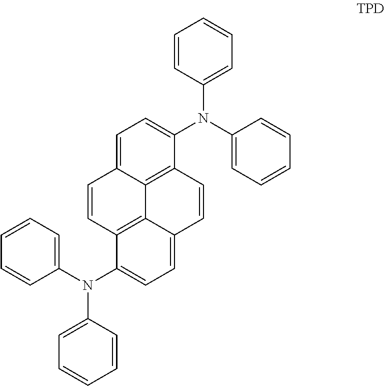 [SMILES: c1ccc(N(c2ccccc2)c2ccc3ccc4c(N(c5ccccc5)c5ccccc5)ccc5ccc2c3c54)cc1]

Results of Comparative Examples and Examples are shown in Table 1.

TABLE 1

| | | Driving | Current | | | | |
|---|---|---|---|---|---|---|---|
| | | voltage | density | Brightness | Efficiency | Emission | Half lifespan (hr |
| | Dopant | (V) | (mA/cm²) | (cd/m²) | (cd/A) | color | @ 100 mA/cm²) |
| Ex. 1 | Compound 14 | 6.94 | 50 | 3,160 | 6.32 | Blue | 346 hr |
| Ex. 2 | Compound 24 | 6.92 | 50 | 3,185 | 6.37 | Blue | 352 hr |
| Ex. 3 | Compound 29 | 6.95 | 50 | 3,155 | 6.31 | Blue | 376 hr |
| Ex. 4 | Compound 31 | 6.91 | 50 | 3,210 | 6.42 | Blue | 432 hr |
| Ex. 5 | Compound 42 | 6.92 | 50 | 3,245 | 6.49 | Blue | 322 hr |
| Ex. 6 | Compound 54 | 6.90 | 50 | 3,260 | 6.52 | Blue | 384 hr |
| Ex. 7 | Compound 59 | 6.93 | 50 | 3,290 | 6.58 | Blue | 364 hr |
| Ex. 8 | Compound 79 | 6.94 | 50 | 3,305 | 6.61 | Blue | 411 hr |
| Ex. 9 | Compound 82 | 6.92 | 50 | 3,295 | 6.59 | Blue | 379 hr |
| Comparative | TPD | 6.96 | 50 | 2,730 | 5.46 | Blue | 248 hr |
| Ex. 1 | | | | | | | |

### Example 10

An organic light-emitting device was manufactured in the same manner as in Example 1, except that in forming an emission layer, as a host for the emission layer, Compound H9 of Formula 2 was used instead of ADN, which is a known compound, and Compound 29 was used as a dopant for the emission layer.

### Example 11

An organic light-emitting device was manufactured in the same manner as in Example 10, except that in forming the emission layer, as a dopant, Compound 42 was used instead of Compound 29.

### Example 12

An organic light-emitting device was manufactured in the same manner as in Example 10, except that in forming the emission layer, as a dopant, Compound 54 was used instead of Compound 29.

### Example 13

An organic light-emitting device was manufactured in the same manner as in Example 10, except that in forming the emission layer, as a dopant, Compound 79 was used instead of Compound 29.

### Example 14

An organic light-emitting device was manufactured in the same manner as in Example 10, except that in forming the emission layer, as a dopant, Compound 82 was used instead of Compound 29.

### Example 15

An organic light-emitting device was manufactured in the same manner as in Example 10, except that in forming an emission layer, as a host for the emission layer, Compound H45 was used instead of Compound H9 and Compound 24 was used as a dopant.

### Example 16

An organic light-emitting device was manufactured in the same manner as in Example 15, except that in forming the emission layer, as a dopant, Compound 29 was used instead of Compound 24.

### Example 17

An organic light-emitting device was manufactured in the same manner as in Example 15, except that in forming the emission layer, as a dopant, Compound 31 was used instead of Compound 24.

### Example 18

An organic light-emitting device was manufactured in the same manner as in Example 15, except that in forming the emission layer, as a dopant, Compound 42 was used instead of Compound 24.

### Example 19

An organic light-emitting device was manufactured in the same manner as in Example 15, except that in forming the emission layer, as a dopant, Compound 54 was used instead of Compound 24.

### Example 20

An organic light-emitting device was manufactured in the same manner as in Example 15, except that in forming the emission layer, as a dopant, Compound 59 was used instead of Compound 24.

### Example 21

An organic light-emitting device was manufactured in the same manner as in Example 15, except that in forming the emission layer, as a dopant, Compound 79 was used instead of Compound 24.

### Example 22

An organic light-emitting device was manufactured in the same manner as in Example 10, except that in forming an emission layer, as a host for the emission layer, Compound H60 was used instead of Compound H9 and Compound 31 was used as a dopant.

### Example 23

An organic light-emitting device was manufactured in the same manner as in Example 22, except that in forming the emission layer, as a dopant, Compound 42 was used instead of Compound 31.

### Example 24

An organic light-emitting device was manufactured in the same manner as in Example 22, except that in forming the emission layer, as a dopant, Compound 54 was used instead of Compound 31.

### Example 25

An organic light-emitting device was manufactured in the same manner as in Example 22, except that in forming the emission layer, as a dopant, Compound 59 was used instead of Compound 31.

### Example 26

An organic light-emitting device was manufactured in the same manner as in Example 22, except that in forming the emission layer, as a dopant, Compound 79 was used instead of Compound 31.

### Example 27

An organic light-emitting device was manufactured in the same manner as in Example 22, except that in forming the emission layer, as a dopant, Compound 82 was used instead of Compound 31.

### Comparative Example 2

An organic light-emitting device was manufactured in the same manner as in Example 1, except that in forming an emission layer, as a host for the emission layer, Compound H9 of Formula 2 was used instead of ADN, which is a known compound, and TPD, which is a known compound, was used as a dopant for the emission layer.

Results of Comparative Examples and Examples are shown in Table 2.

TABLE 2

| | | | | Current | | | | |
|---|---|---|---|---|---|---|---|---|
| | | | Driving | density | Brightness | Efficiency | Emission | Half lifespan (hr |
| | Host | Dopant | voltage (V) | (mA/cm²) | (cd/m²) | (cd/A) | color | @ 100 mA/cm²) |
| Ex. 10 | Compound H9 | Compound 29 | 6.65 | 50 | 3,295 | 6.59 | Blue | 457 hr |
| Ex. 11 | Compound H9 | Compound 42 | 6.66 | 50 | 3,305 | 6.61 | Blue | 438 hr |
| Ex. 12 | Compound H9 | Compound 54 | 6.64 | 50 | 3,355 | 6.71 | Blue | 469 hr |
| Ex. 13 | Compound H9 | Compound 79 | 6.66 | 50 | 3,365 | 6.73 | Blue | 488 hr |
| Ex. 14 | Compound H9 | Compound 82 | 6.65 | 50 | 3,320 | 6.64 | Blue | 476 hr |
| Ex. 15 | Compound H45 | Compound 24 | 6.63 | 50 | 3,290 | 6.58 | Blue | 472 hr |
| Ex. 16 | Compound H45 | Compound 29 | 6.64 | 50 | 3,320 | 6.64 | Blue | 496 hr |
| Ex. 17 | Compound H45 | Compound 31 | 6.62 | 50 | 3,375 | 6.75 | Blue | 533 hr |
| Ex. 18 | Compound H45 | Compound 42 | 6.64 | 50 | 3,360 | 6.72 | Blue | 440 hr |
| Ex. 19 | Compound H45 | Compound 54 | 6.63 | 50 | 3,380 | 6.76 | Blue | 502 hr |
| Ex. 20 | Compound H45 | Compound 59 | 6.64 | 50 | 3,405 | 6.81 | Blue | 498 hr |
| Ex. 21 | Compound H45 | Compound 79 | 6.62 | 50 | 3,395 | 6.79 | Blue | 516 hr |
| Ex. 22 | Compound H60 | Compound 31 | 6.65 | 50 | 3,360 | 6.72 | Blue | 413 hr |
| Ex. 23 | Compound H60 | Compound 42 | 6.64 | 50 | 3,355 | 6.71 | Blue | 398 hr |
| Ex. 24 | Compound H60 | Compound 54 | 6.63 | 50 | 3,385 | 6.77 | Blue | 431 hr |
| Ex. 25 | Compound H60 | Compound 59 | 6.65 | 50 | 3,390 | 6.78 | Blue | 448 hr |
| Ex. 26 | Compound H60 | Compound 79 | 6.64 | 50 | 3,380 | 6.76 | Blue | 467 hr |
| Ex. 27 | Compound H60 | Compound 82 | 6.63 | 50 | 3,345 | 6.69 | Blue | 453 hr |
| Comparative | ADN | TPD | 6.96 | 50 | 2,730 | 5.46 | Blue | 248 hr |
| Ex. 1 | | | | | | | | |
| Comparative | H9 | TPD | 6.73 | 50 | 2,835 | 5.67 | Blue | 384 hr |
| Ex. 2 | | | | | | | | |

When compounds having the structure of Formula 1 are used as a dopant for an emission layer of a blue light-emitting device, compared to known compounds, high efficiency and long lifespan may be obtained.

Also, when compounds having the structure of Formula 2 are simultaneously used as a host for an emission layer, the efficiency may be further increased.

Compounds represented by Formula 1 have excellent luminescent characteristics and material stabilities and are suitable for use as a luminescent dopant material. An organic light-emitting device manufactured using such compounds has high efficiency, low voltage, high brightness, and a long lifespan.

It should be understood that the exemplary embodiments described therein should be considered in a descriptive sense only and not for purposes of limitation. Descriptions of features or aspects within each embodiment should typically be considered as available for other similar features or aspects in other embodiments.

What is claimed is:

1. A compound represented by Formula 1: 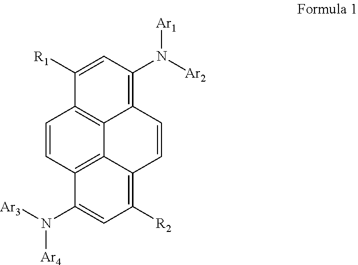
wherein in Formula 1,
Ar₁ to Ar₄ are each independently a C₆ to C₆₀ substituted or unsubstituted aryl group, a C₁ to C₆₀ substituted or unsubstituted heteroaryl group, or a C₆ to C₆₀ substituted or unsubstituted condensed polycyclic group, and at least one of Ar₁ to Ar₄ is represented by Formula I-a: 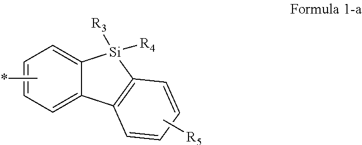
wherein in Formulae 1 and 1-a, R₁ to R₅ are each independently a hydrogen, a deuterium, a substituted or unsubstituted a C₁ to C₃₀ alkylsilyl group, a substituted or unsubstituted a C₆ to C₃₀ arylsilyl group, a substituted or unsubstituted a C₁ to C₃₀ alkyl group, a substituted or unsubstituted a C₆ to C₃₀ aryl group, a substituted or unsubstituted a C₁ to C₃₀ heteroaryl group, or a substituted or unsubstituted a C₆ to C₃₀ condensed polycyclic group, and
* indicates an attachment point.

2. The compound of claim 1, wherein
Ar₁ to Ar₄ are each independently Formula 1-a, or any one of Formulae 2a to 2c: 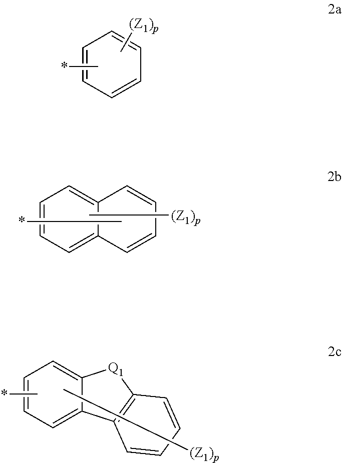
wherein in Formulae 2a to 2c,
Q₁ is —C(R₃₁)(R₃₂)—, —S—, or —O—;
Z₁, R₃₁, and R₃₂ are each independently, a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, —SiR₄₁R₄₂R₄₃, a halogen group, a cyano group, a nitro group, a hydroxyl group, or a carboxyl group;
R₄₁, R₄₂, and R₄₃ are each independently a substituted or unsubstituted C₁ to C₂₀ alkyl group, or a substituted or unsubstituted C₆ to C₂₀ aryl group;
p is an integer of 1 to 7; and
* indicates an attachment point.

3. The compound of claim 1, wherein
R₁ to R₅ are each independently a hydrogen, a deuterium, a methyl group, an isopropyl group, —SiR₄₁R₄₂R₄₃, or Formula 3a: 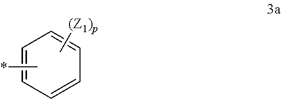
Z₁, R₄₁, R₄₂, and R₄₃ are each independently, a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂0 condensed polycyclic group, a halogen group, a cyano group, a nitro group, a hydroxyl group, or a carboxyl group;
p is an integer of 1 to 5; and
* indicates an attachment point.

4. The compound of claim 1, wherein
the compound of Formula 1 is any one of compounds:

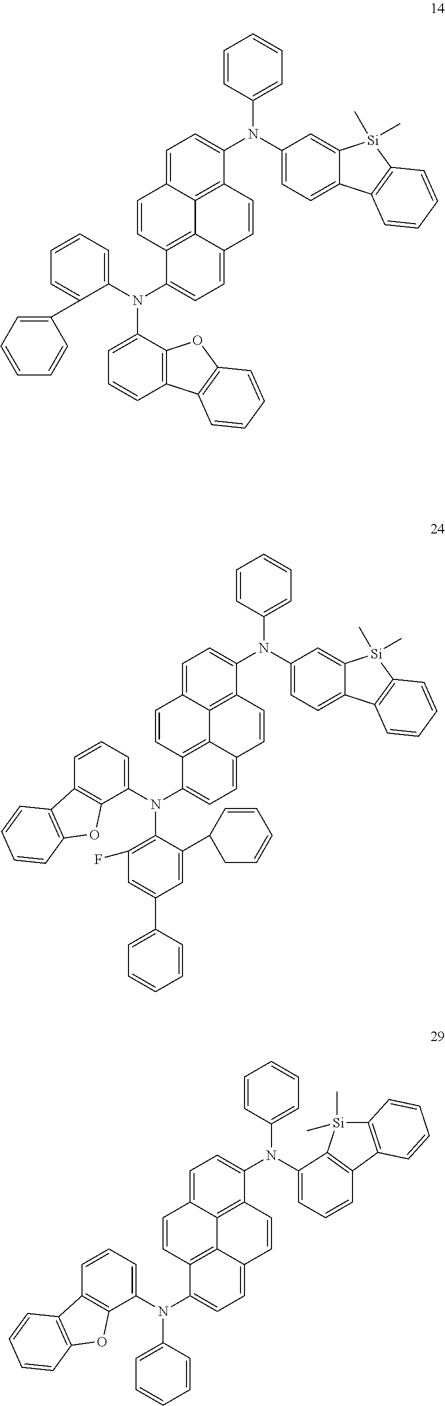 [SMILES: C[Si]1(C)c2ccccc2-c2ccc(N(c3ccccc3)c3ccc4ccc5c(N(c6ccccc6-c6ccccc6)c6cccc7c6oc6ccccc67)ccc6ccc3c4c65)cc21 ; C[Si]1(C)c2ccccc2-c2ccc(N(c3ccccc3)c3ccc4ccc5c(N(c6c(F)cc(-c7ccccc7)cc6C6C=CC=CC6)c6cccc7c6oc6ccccc67)ccc6ccc3c4c65)cc21 ; C[Si]1(C)c2ccccc2-c2cccc(N(c3ccccc3)c3ccc4ccc5c(N(c6ccccc6)c6cccc7c6oc6ccccc67)ccc6ccc3c4c65)c21]

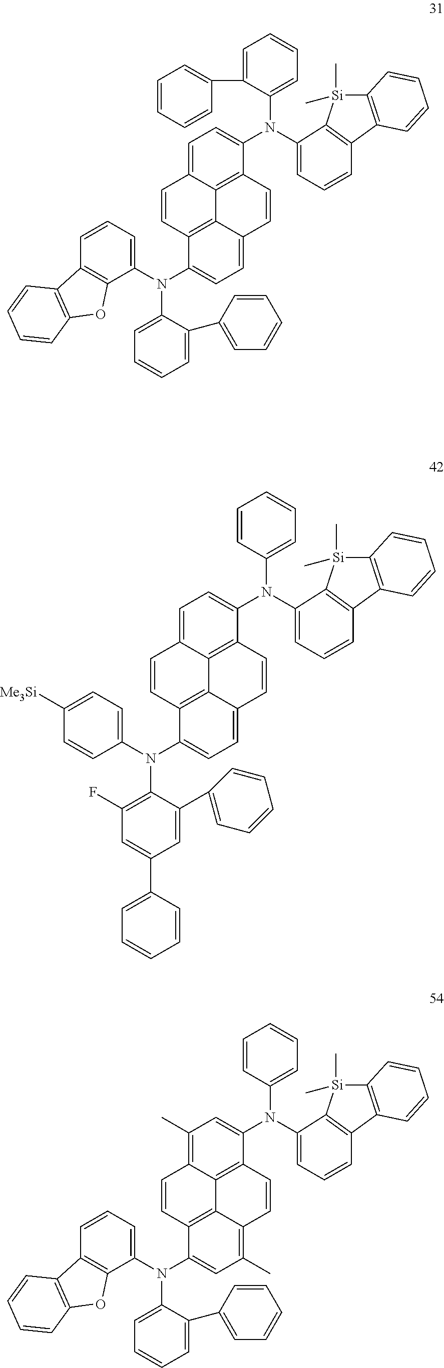 [SMILES: C[Si]1(C)c2ccccc2-c2cccc(N(c3ccccc3-c3ccccc3)c3ccc4ccc5c(N(c6ccccc6-c6ccccc6)c6cccc7c6oc6ccccc67)ccc6ccc3c4c65)c21 ; C[Si](C)(C)c1ccc(N(c2c(F)cc(-c3ccccc3)cc2-c2ccccc2)c2ccc3ccc4c(N(c5ccccc5)c5cccc6c5[Si](C)(C)c5ccccc5-6)ccc5ccc2c3c54)cc1 ; Cc1cc(N(c2ccccc2)c2cccc3c2[Si](C)(C)c2ccccc2-3)c2ccc3c(C)cc(N(c4ccccc4-c4ccccc4)c4cccc5c4oc4ccccc45)c4ccc1c2c34]

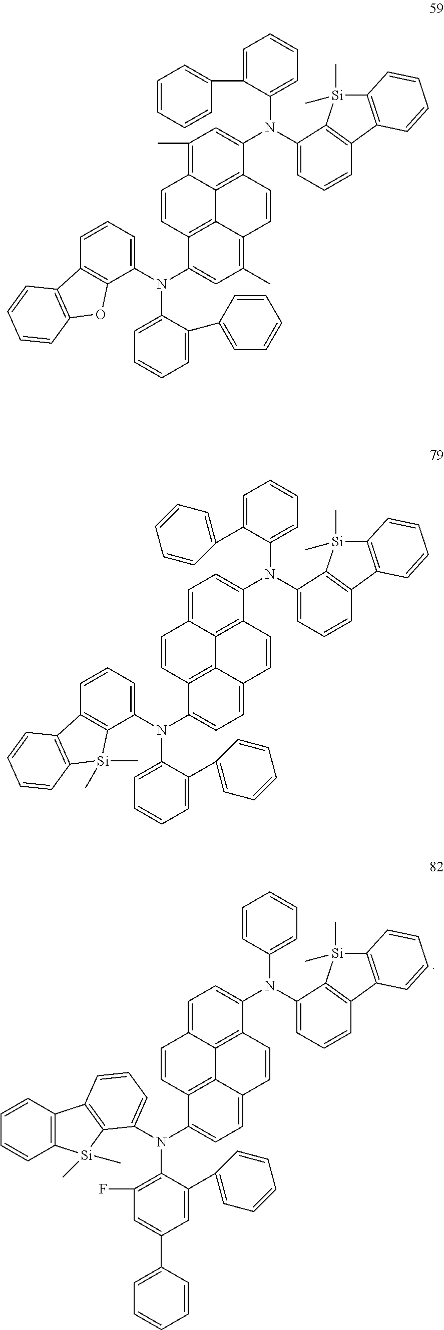 [SMILES: Cc1cc(N(c2ccccc2-c2ccccc2)c2cccc3c2[Si](C)(C)c2ccccc2-3)c2ccc3c(C)cc(N(c4ccccc4-c4ccccc4)c4cccc5c4oc4ccccc45)c4ccc1c2c34 ; C[Si]1(C)c2ccccc2-c2cccc(N(c3ccccc3-c3ccccc3)c3ccc4ccc5c(N(c6ccccc6-c6ccccc6)c6cccc7c6[Si](C)(C)c6ccccc6-7)ccc6ccc3c4c65)c21 ; C[Si]1(C)c2ccccc2-c2cccc(N(c3ccccc3)c3ccc4ccc5c(N(c6cccc7c6[Si](C)(C)c6ccccc6-7)c6c(F)cc(-c7ccccc7)cc6-c6ccccc6)ccc6ccc3c4c65)c21]

5. An organic light-emitting device comprising:
a first electrode;
a second electrode; and
an organic layer disposed between the first electrode and the second electrode,
wherein the organic layer comprises the compound of claim 1.

6. The organic light-emitting device of claim 5, wherein the organic layer is an emission layer.

7. The organic light-emitting device of claim 5, wherein
the organic layer is an emission layer, and the compound is used as a dopant.

8. The organic light-emitting device of claim 5, wherein
the organic layer is an emission layer, and the compound is used as a blue fluorescent dopant.

9. The organic light-emitting device of claim 5, wherein
the organic layer is an emission layer, and the emission layer comprises a compound represented by Formula 2: 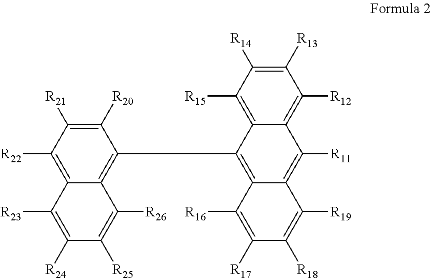
wherein in Formula 2, R₁₁ to R₂₆ are each independently a hydrogen, a deuterium, a substituted or unsubstituted a C₁ to C₃₀ alkylsilyl group, a substituted or unsubstituted a C₆ to C₃₀ arylsilyl group, a substituted or unsubstituted a C₁ to C₃₀ alkyl group, a substituted or unsubstituted a C₆ to C₃₀ aryl group, a substituted or unsubstituted a C₁ to C₃₀ heteroaryl group, or a substituted or unsubstituted a C₆ to C₃₀ condensed polycyclic group.

10. The organic light-emitting device of claim 9, wherein
the compound of Formula 2 is a host.

11. The organic light-emitting device of claim 9, wherein
in Formula 2, R₁₁, R₁₃, and R₂₁ to R₂₃ are each independently a hydrogen, a deuterium, a substituted or unsubstituted C₁ to C₂₀ alkyl group, —SiR₄₁R₄₂R₄₃, or any one of Formulae 4a to 4c: 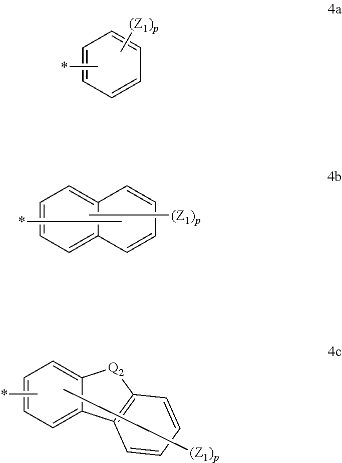
wherein in Formulae 4a to 4c,
Q₂ is —C(R₃₁)(R₃₂)—, —NR₃₃—, —S—, or —O—;
Z₁, R₃₁ to R₃₃, and R₄₁ to R₄₃ are each independently a hydrogen, a deuterium, a substituted or unsubstituted C₁ to C₂₀ alkyl group, a substituted or unsubstituted C₆ to C₂₀ aryl group, a substituted or unsubstituted C₁ to C₂₀ heteroaryl group, a substituted or unsubstituted C₆ to C₂₀ condensed polycyclic group, a substituted or unsubstituted C₁ to C₂₀ alkylsilyl group, a substituted or unsubstituted C₆ to C₂₀ arylsilyl group, a halogen group, a cyano group, a nitro group, a hydroxyl group, or a carboxyl group;
p is an integer of 1 to 7; and
* indicates an attachment point.

12. The organic light-emitting device of claim 9, wherein
R₁₂, R₁₄ to R₂₀, and R₂₄ to R₂₆ in Formula 2 are each independently a hydrogen or a deuterium.

13. The organic light-emitting device of claim 9, wherein
the compound of Formula 2 is one of the compounds illustrated below:

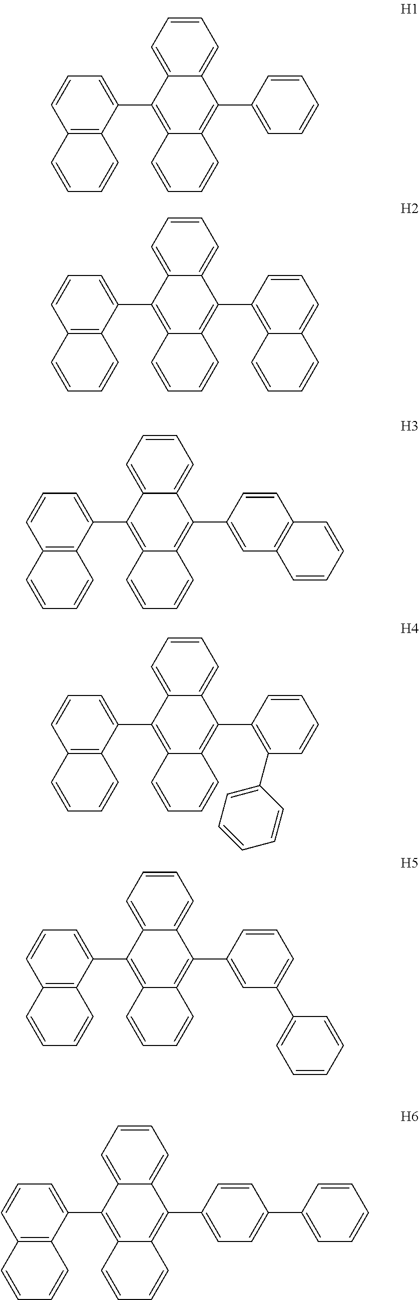

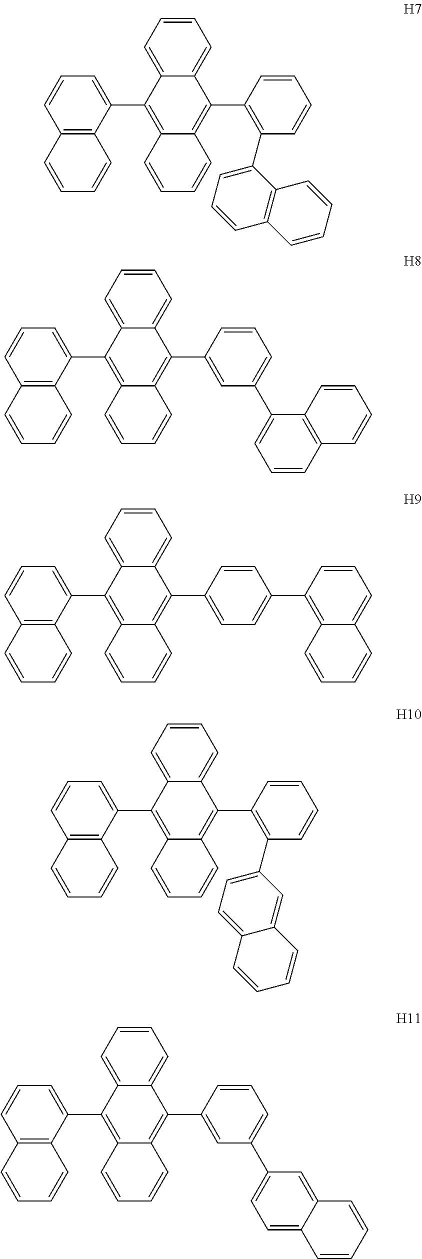

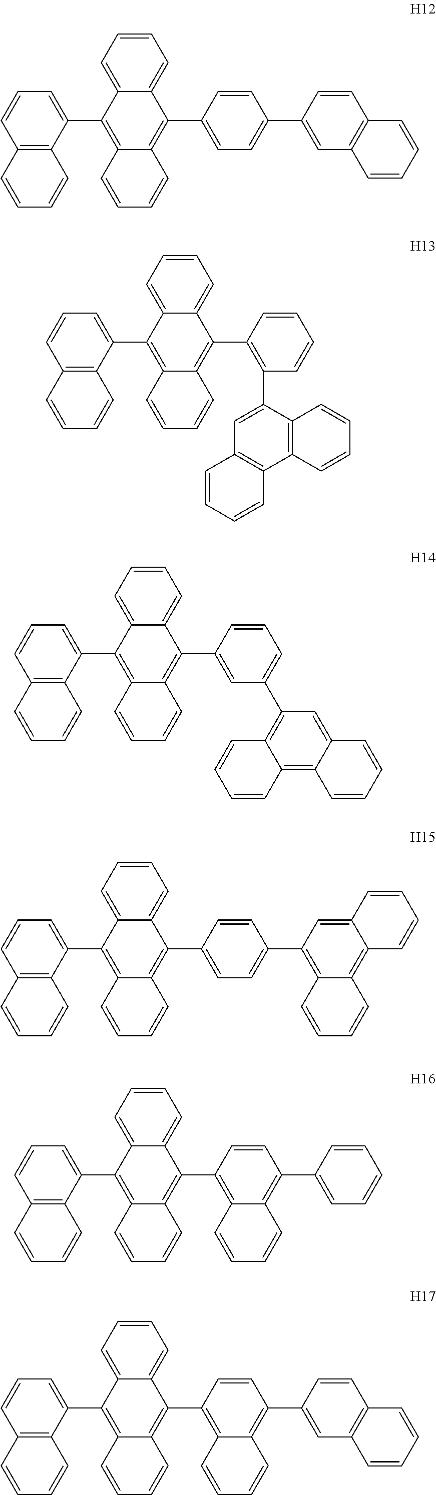

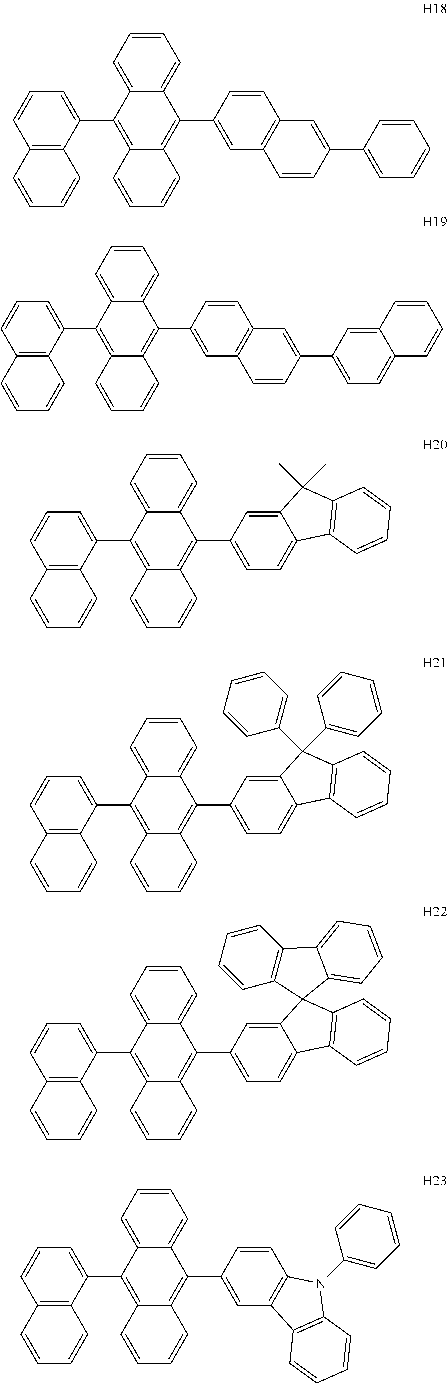

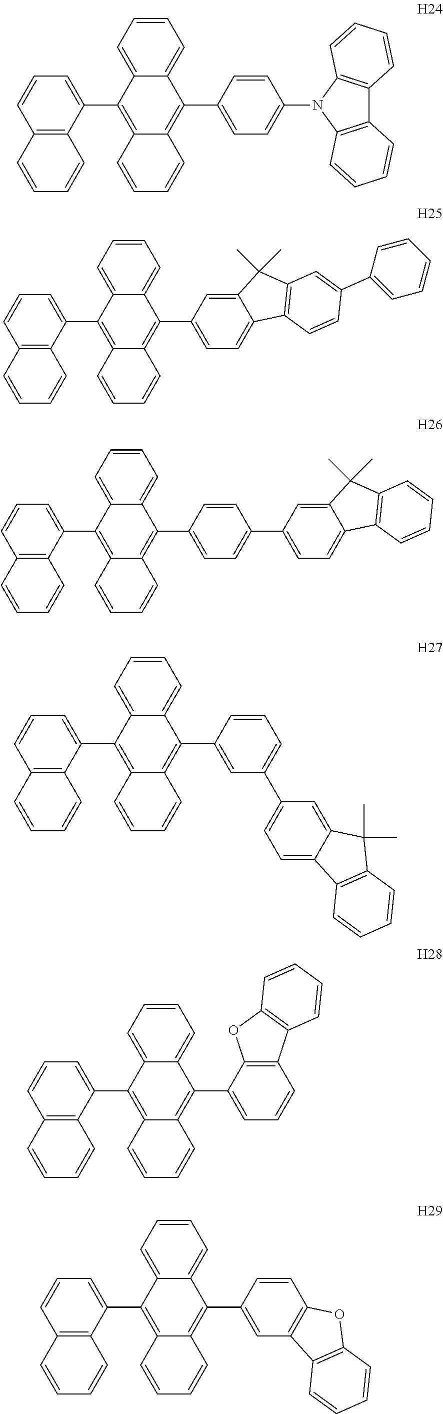

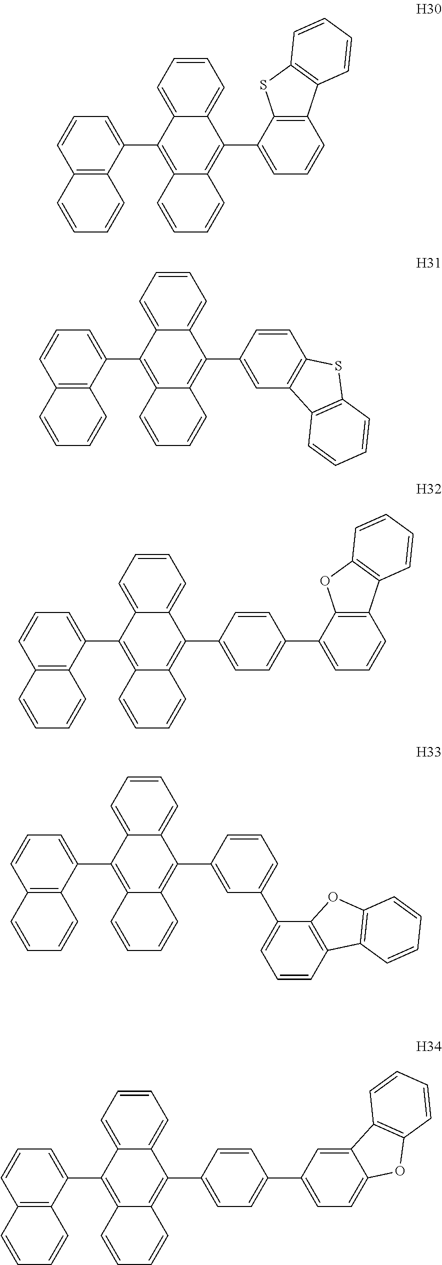

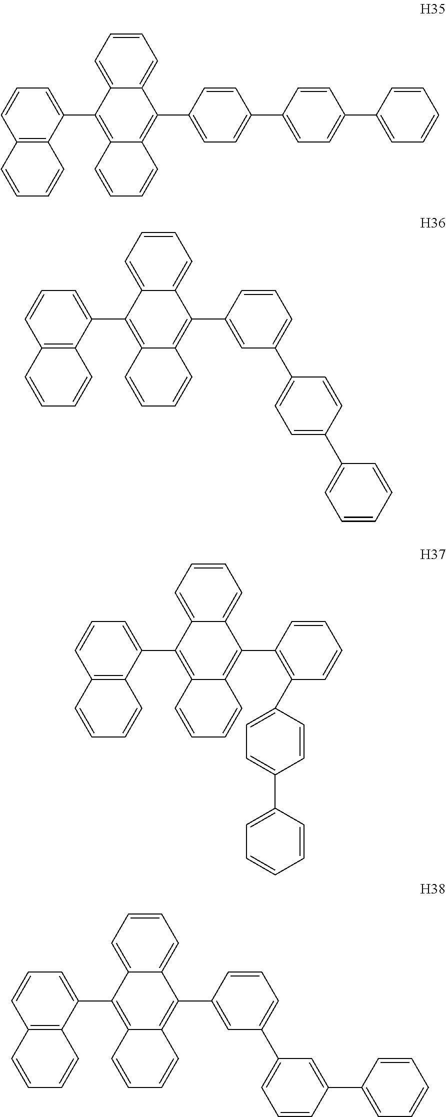

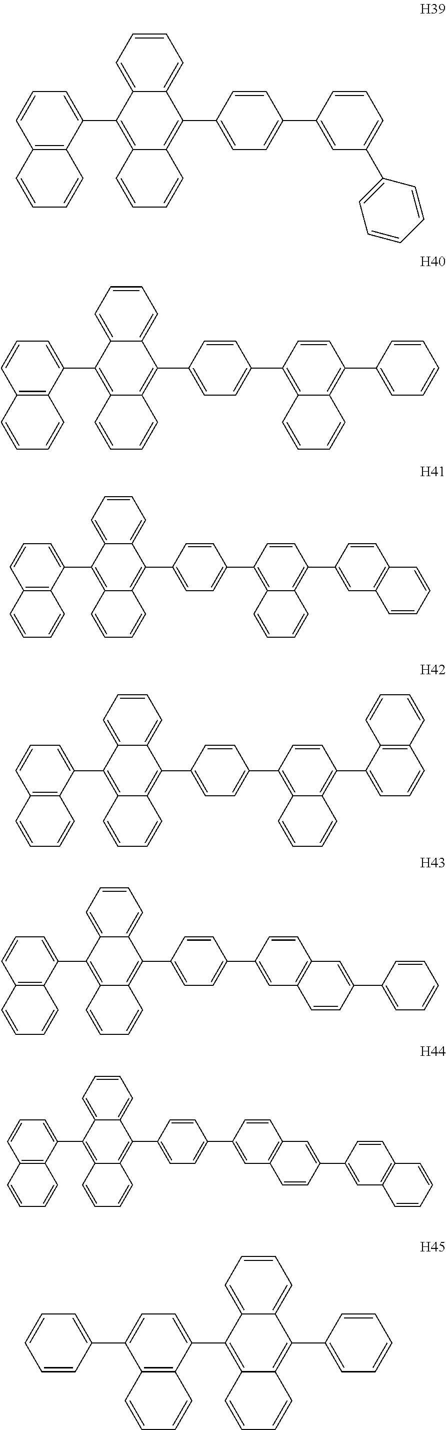

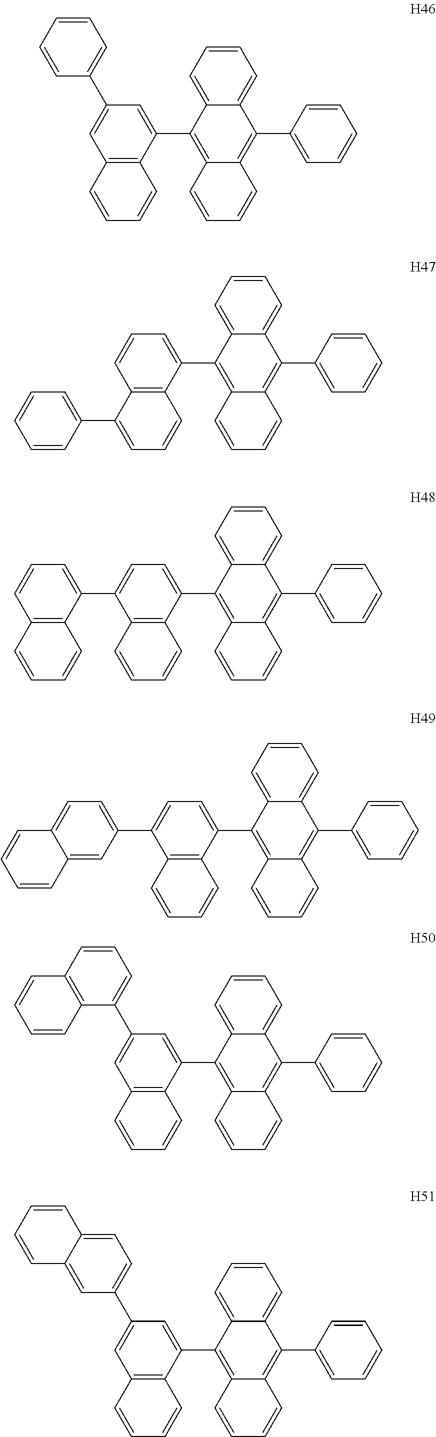

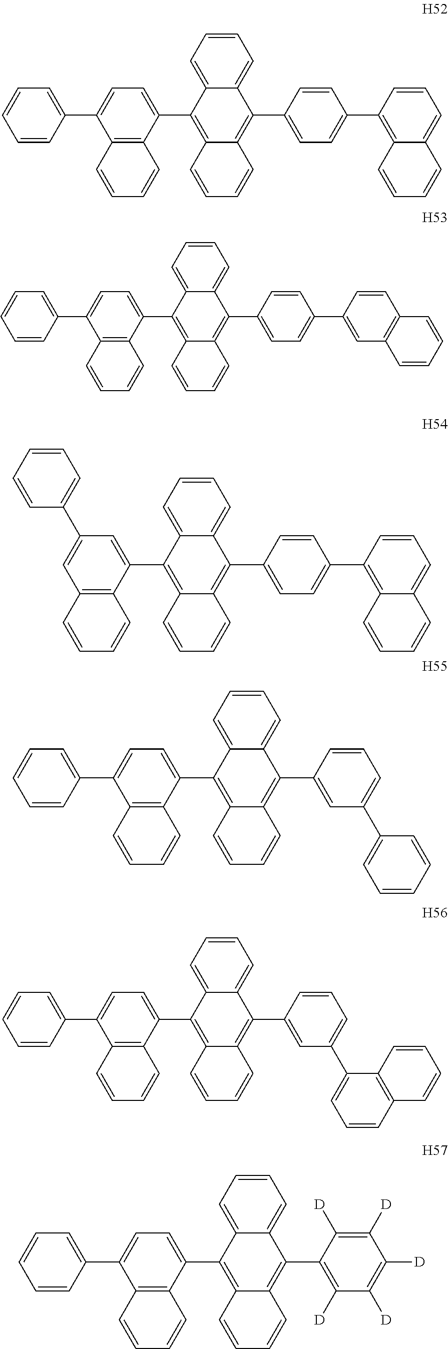

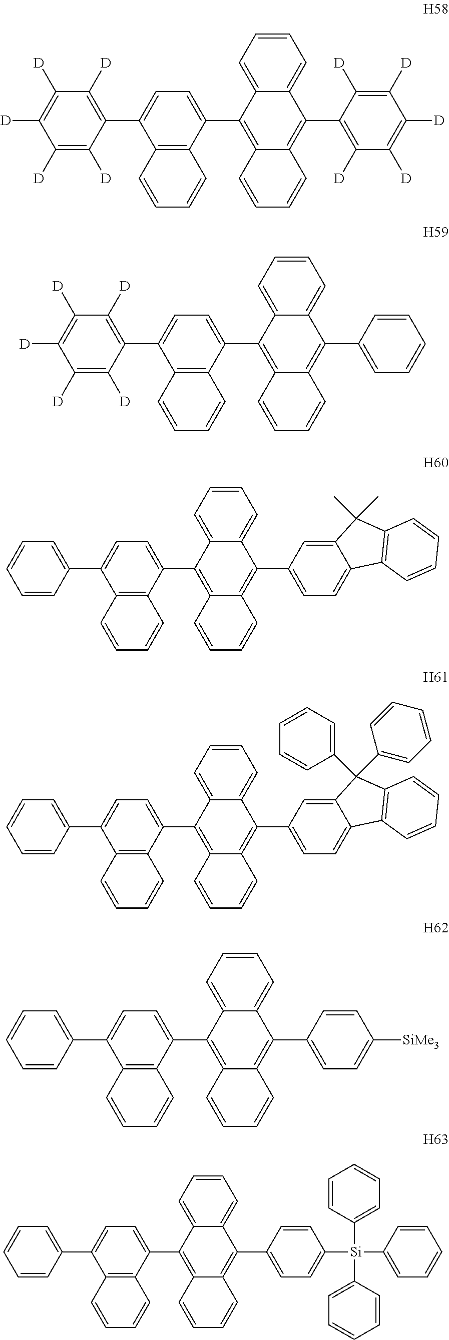

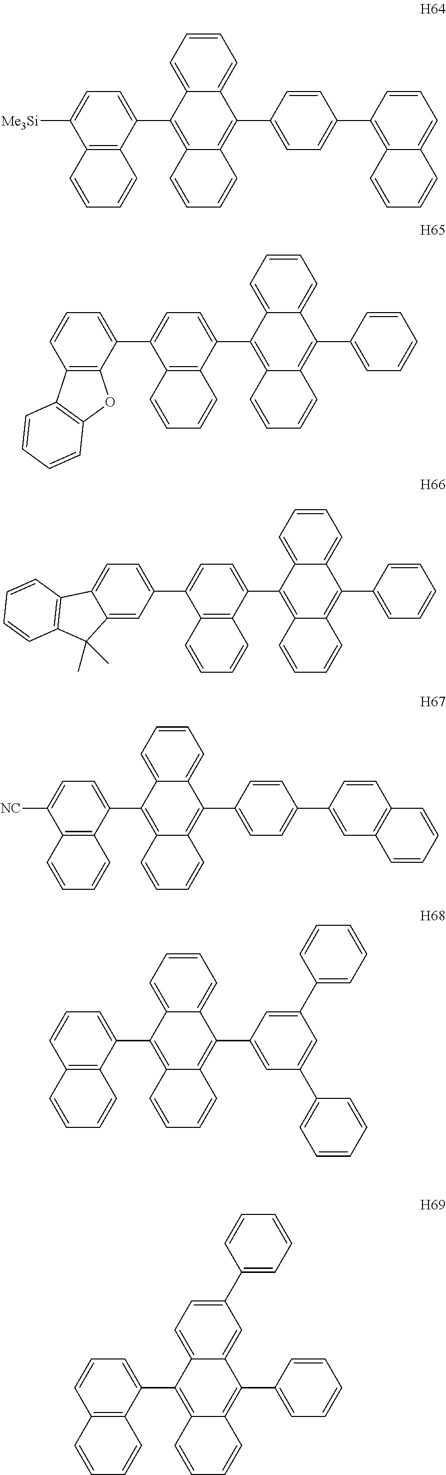

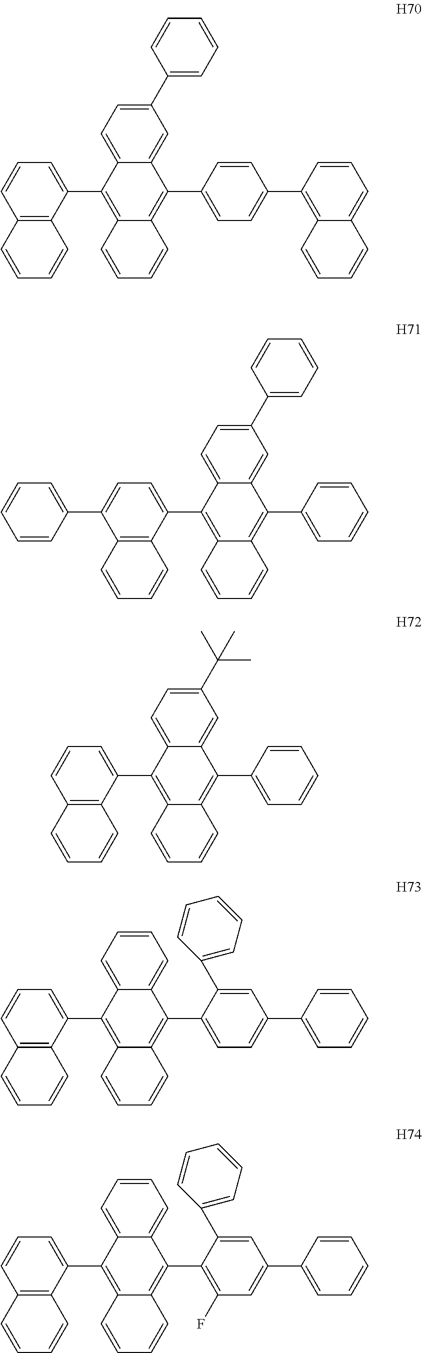

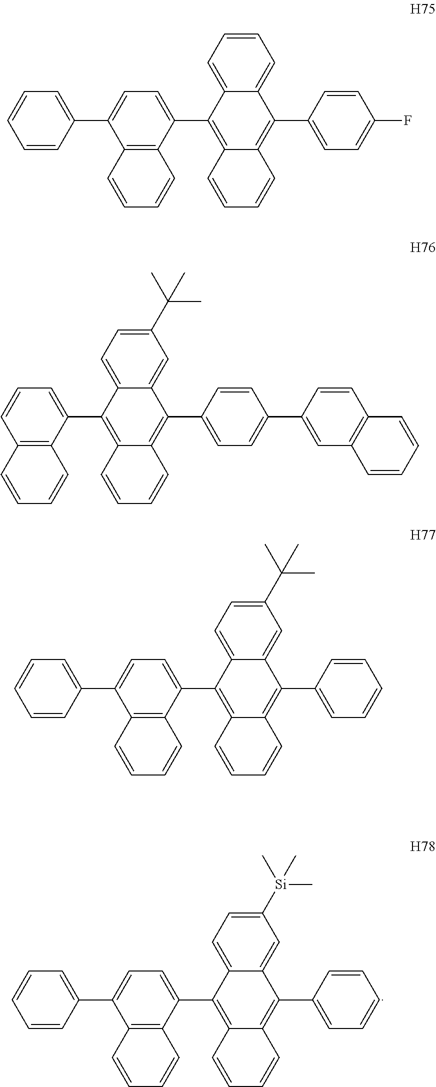

14. The organic light-emitting device of claim 5, wherein
the organic light-emitting device comprises an emission layer, and an electron injection layer, an electron transport layer, a functional layer having an electron injection capability and an electron transportation capability, a hole injection layer, a hole transport layer, or a functional layer having a hole injection capability and a hole transportation capability, and
the emission layer comprises an anthracene-based compound, an arylamine-based compound, or a styryl-based compound.

15. The organic light-emitting device of claim 5, wherein
the organic layer comprises an electron transport layer that comprises a metal complex.

16. The organic light-emitting device of claim 15, wherein
the metal complex is an Li complex.

17. The organic light-emitting device of claim 15, wherein
the metal complex is a lithium quinolate (LiQ).

18. The organic light-emitting device of claim 15, wherein
the metal complex is Compound 203:

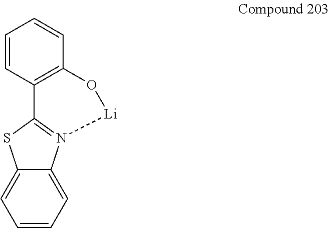

19. The organic light-emitting device of claim 5, wherein
the organic layer is formed by using a wet process.

20. A flat display apparatus comprising the organic light-emitting device of claim 5, wherein the first electrode of the organic light-emitting device is electrically connected to a source electrode or a drain electrode of a thin film transistor.
